(19) United States
(12) Patent Application Publication
(10) Pub. No.: US 2014/0103344 A1
(43) Pub. Date: Apr. 17, 2014

(54) DETECTION OF RECOVERED INTEGRATED CIRCUITS

(71) Applicants: MOHAMMAD TEHRANIPOOR, Mansfield, CT (US); Nicholas Tuzzio, Willington, CT (US); Xuehui Zhang, Storrs, CT (US)

(72) Inventors: MOHAMMAD TEHRANIPOOR, Mansfield, CT (US); Nicholas Tuzzio, Willington, CT (US); Xuehui Zhang, Storrs, CT (US)

(21) Appl. No.: 13/789,172

(22) Filed: Mar. 7, 2013

Related U.S. Application Data
(60) Provisional application No. 61/611,472, filed on Mar. 15, 2012.
(60) Provisional application No. 61/609,820, filed on Mar. 12, 2012.

(51) Int. Cl. G01R 31/28

(52) U.S. Cl. CPC G01R 31/2884
USPC 257/48

(57) ABSTRACT

An apparatus for detection of integrated circuit recovery is disclosed. An example apparatus can comprise a first sensor embedded in an integrated circuit. The example apparatus can comprise a second sensor embedded in the integrated circuit. The example apparatus can comprise a selector unit configured to select one of the first sensor or the second sensor. The example apparatus can also comprise a monitor unit configured to receive output signal from the first sensor and the second sensor and to supply the output signal to an analysis unit.

### RELATED APPLICATION

The present invention claims the priority of and the benefit of the filing date of U.S. Provisional Patent Applications Ser. Nos. 61/609,820, filed Mar. 12, 2012, and 61/611,472, filed Mar. 15, 2012, each of which is incorporated herein in its entirety.

### SUMMARY

In accordance with the purpose(s) of the disclosure, as embodied and broadly described herein, the subject disclosure relates to an apparatus to detect a recovered IC. The apparatus, which can be referred to a die recovery sensor, can be configured to distinguish a recovered IC from a non-used IC. In certain embodiments, the apparatus can comprise a reference ring oscillator (RO) and a stressed ring oscillator. For non-used ICs, the frequency difference (or frequency shift) between the stressed RO and the reference RO can be utilized as a fingerprint of such ICs. The fingerprint can be compared with data indicative of frequency shift among a reference RO and a stressed RO in a circuit under authentication (CUA) and, based on outcome of such comparison, the CUA can be identified as a non-used IC or a recovered IC. In one aspect, statistical data analysis can permit separation of process and temperature variations from aging effects on a DR sensor present in an IC. Results of simulations featuring a DR sensor based on 90 nm technology, and experimental results in manufactured 90-nm test chipsets (referred to as silicon results) can demonstrate the efficacy of the apparatus and related analysis methodology for detection (or identification) of a recovered IC.

In another aspect, the disclosure relates to a novel path-delay fingerprinting technique (e.g., apparatus and/or methodology) to distinguish a recovered IC from a non-used IC. It should be appreciated that due to degradation in the field, the path delay distribution of recovered ICs can be different from such distribution as observed in non-used ICs. For non-used ICs, the delay distribution of paths will be within a certain range. Due to aging effects, such as negative/positive bias temperature instability (NBTI/PBTI) and hot carrier injection (HCl), the path delays in recovered ICs will be larger than those in non-used ICs. For a chip under authentication (CUA), the larger the path delays are, the higher the probability there is that the CUA has been used and is a recovered IC. Statistical data analysis can permit separation of process variations effects from aging effects on path delay and related distributions. Results of simulations of benchmark circuits using 45 nm technology can demonstrate the efficacy of the disclosed technique for identification of a recovered IC. In view that path delay information can be collected (e.g., measured) during manufacturing test process(es), no added hardware circuitry can be necessary for implementation of the disclosed technique. In addition or in the alternative, the disclosed technique can be readily incorporate into conventional industrial design and test flows.

Certain embodiments of the disclosure can provide various advantages over conventional technologies for detection of a recovered IC. For example, one embodiment of the disclosure can mitigate or avoid area overhead, reduce or avoid power consumption, and/or can be resilient to attacks. Additional advantages of the disclosure will be set forth in part in the description which follows, and in part will be apparent from such description and annexed drawings, or may be learned by practice of the disclosure. The advantages of the disclosure can be realized and attained by means of the elements and combinations particularly pointed out in the appended claims. It is to be understood that both the foregoing general description and the following detailed description are exemplary and explanatory only and are not restrictive of the various aspects, features, or advantages of the disclosure.

### BRIEF DESCRIPTION OF THE DRAWINGS

The accompanying drawings and appendices, which are incorporated in and constitute a part of this specification, illustrate several exemplary embodiment of the disclosure and together with the description, serve to explain the principles of the disclosure.

FIG. 1A illustrates an exemplary inverter chain structure in accordance with one or more aspects described herein. FIGS. 1B-1C illustrate performance degradation of exemplary inverter chains in accordance with one or more aspects described herein. FIG. 1D illustrates performance degradation of exemplary chains of NAND gate chains, BUF chains, and INV chains in accordance with one or more aspects described herein.

FIG. 2A illustrates performance degradation of an exemplary inverter chain as a function of time in accordance with one or more aspects described herein. FIG. 2B illustrates frequency of an exemplary inverter chain as a function of temperature in accordance with one or more aspects described herein.

FIGS. 3A-3D illustrate frequency distribution and frequency degradation for exemplary ring oscillators installed at various chipsets in accordance with several aspects described herein.

FIGS. 4A-4C illustrates an exemplary embodiment of an apparatus for detection of a recovered IC in accordance with one or more aspects described herein.

FIG. 5 illustrates an exemplary methodology for detecting a recovered IC in accordance with one or more aspects described herein.

FIGS. 6A-6B illustrate frequency shift distribution for exemplary ROs in accordance with one or more aspects of the disclosure.

FIGS. 7A-7B illustrate frequency shift distribution for exemplary ROs in accordance with one or more aspects of the disclosure.

FIGS. 8A-8B illustrate frequency shift distribution for exemplary ROs in accordance with one or more aspects of the disclosure.

FIG. 9 illustrates an exemplary block diagram of the test board in accordance with one or more aspects described herein.

FIGS. 10A-10G illustrate frequency shift distributions obtained in experiments for exemplary ROs submitted to various aging conditions in accordance with one or more aspects described herein. FIGS. 10E-10G illustrate results for exemplary DR sensors CDR1, CDR2, and CDR3 described herein.

FIG. 11A illustrates exemplary component chains for detection of recovered IC in accordance with one or more aspects described herein. FIG. 11B illustrates path delay degradation for various exemplary component chains in accordance with one or more aspects of the disclosure.

FIG. 12A illustrates path delay degradation as a function of aging in accordance with one or more aspects described herein. FIG. 12B illustrates path delay degradation in accordance with one or more aspects described herein.

FIGS. 13A-13B illustrates path delay degradation distribution for several chipsets in accordance with one or more aspects described herein.

FIG. 14 illustrates an exemplary methodology for path-delay-based detection of a recovered IC in accordance with one or more aspects described herein.

FIG. 15 illustrates an exemplary method for clock sweeping in accordance with one or more aspects described herein.

FIGS. 16A-16C illustrate path delay distribution in accordance with one or more aspects of the disclosure.

FIGS. 17A-17C illustrate path delay distribution in accordance with one or more aspects of the disclosure.

FIGS. 18A-18C illustrates results of principal component analysis (PCA) for detection of a recovered IC in accordance with one or more aspects of the disclosure.

FIGS. 19A-19B illustrates results of PCA for detection of a recovered IC in accordance with one or more aspects of the disclosure.

FIGS. 20A-20B illustrates results of PCA for detection of a recovered IC in accordance with one or more aspects of the disclosure.

FIG. 21A illustrates an exemplary benchmark structure in accordance with one or more aspects described herein. FIG. 21B illustrates leakage current as a function of aging in an IC in accordance with one or more aspects described herein. FIG. 21C illustrates transient current as a function of aging in an IC in accordance with one or more aspects described herein.

FIG. 22 illustrates an exemplary methodology for side-channel-based detection of a recovered IC in accordance with one or more aspects described herein.

FIG. 23 is a block diagram of an exemplary computing environment that can enable various aspects (e.g., circuit design, circuit simulation, detection of IC recovery, or the like) of the disclosure.

FIG. 24 illustrates exemplary methods for comprehensive Trojan detection and prevention.

FIG. 25 illustrates exemplary Trojan detection methods using side channel analysis and circuit delay analysis.

FIG. 26 illustrates exemplary Trojan detection methods using Trojan activation and Trojan isolation techniques.

FIG. 27 illustrates exemplary challenges of IC Identification, IC authentication, and counterfeit IC detection.

FIG. 28 illustrates exemplary design methods for security and trust (DFST) during IC design.

FIG. 29 illustrates exemplary design modification methods for Trojan detection and prevention.

FIG. 30 illustrates exemplary Trojan detection methods using dummy flip-flop, scan flip-flop reordering, on-chip power sensor, and on-chip delay sensor.

FIG. 31 illustrates exemplary impact of a Trojan on a neighboring ring oscillator.

FIG. 32 illustrates exemplary structures of ring oscillator network as power monitors for Trojan detection.

FIG. 33 illustrates exemplary locations of six Trojans inserted into s9234 in an exemplary simulation.

FIG. 34A illustrates an exemplary oscillation cycle distribution of ring oscillator RO8 with Monte Carlo simulation when Trojan T5 is inserted in s9234.

FIG. 34B illustrates an exemplary oscillation cycle distribution of ring oscillator RO8 with Monte Carlo simulation without Trojan T5.

FIG. 34C illustrates an exemplary cycle count distribution of ring oscillator RO8 with Monte Carlo simulation when Trojan T5 is inserted in s9234.

FIG. 34D illustrates an exemplary oscillation cycle distribution of ring oscillator RO5 with Monte Carlo simulation when Trojan T5 is inserted in s9234.

FIG. 34E illustrates an exemplary oscillation cycle distribution of ring oscillator RO5 with Monte Carlo simulation without Trojan T5.

FIG. 34F illustrates an exemplary cycle count distribution of ring oscillator RO5 with Monte Carlo simulation when Trojan T5 is inserted in s9234.

FIG. 34G illustrates an exemplary oscillation cycle distribution of ring oscillator RO1 with Monte Carlo simulation when Trojan T5 is inserted in s9234.

FIG. 34H illustrates an exemplary oscillation cycle distribution of ring oscillator RO1 with Monte Carlo simulation without Trojan T5.

FIG. 34I illustrates an exemplary cycle count distribution of ring oscillator RO1 with Monte Carlo simulation when Trojan T5 is inserted in s9234.

FIG. 34J illustrates an exemplary oscillation cycle distribution of ring oscillator RO12 with Monte Carlo simulation when Trojan T5 is inserted in s9234.

FIG. 34K illustrates an exemplary oscillation cycle distribution of ring oscillator RO12 with Monte Carlo simulation without Trojan T5.

FIG. 34L illustrates an exemplary cycle count distribution of ring oscillator RO12 with Monte Carlo simulation when Trojan T5 is inserted in s9234.

FIG. 35 illustrates an exemplary power signature using principal component analysis for Trojan-free ICs and Trojan-inserted ICs with Trojan T5.

FIG. 36A illustrates an exemplary power signature with advanced outlier data analysis from IC simulation for T1.

FIG. 36B illustrates an exemplary power signature with advanced outlier data analysis from IC simulation for T2.

FIG. 36C illustrates an exemplary power signature with advanced outlier data analysis from IC simulation for T3.

FIG. 36D illustrates an exemplary power signature with advanced outlier data analysis from IC simulation for T4.

FIG. 36E illustrates an exemplary power signature with advanced outlier data analysis from IC simulation for T5.

FIG. 36F illustrates an exemplary power signature with advanced outlier data analysis from IC simulation for T6.

FIG. 37 illustrates an exemplary AES layout after placement on FPGA.

FIG. 38A illustrates an exemplary power signature with advanced outlier data analysis from FPGA implementation for T11.

FIG. 38B illustrates an exemplary power signature with advanced outlier data analysis from FPGA implementation for T12.

FIG. 38C illustrates an exemplary power signature with advanced outlier data analysis from FPGA implementation for T13.

FIG. 38D illustrates an exemplary power signature with advanced outlier data analysis from FPGA implementation for T14.

FIG. 38E illustrates an exemplary power signature with advanced outlier data analysis from FPGA implementation for T15.

FIG. 38F illustrates an exemplary power signature with advanced outlier data analysis from FPGA implementation for T16.

FIG. 39 illustrates exemplary Trojan location analysis with advanced outlier data analysis from Xilinx 90 nm FPGA.

FIG. 40A illustrates exemplary Trojan location analysis with advanced outlier data analysis from Xilinx 45 nm FPGA.

FIG. 40B further illustrates exemplary Trojan location analysis with advanced outlier data analysis from Xilinx 45 nm FPGA.

### DETAILED DESCRIPTION

The disclosure can be understood more readily by reference to the following detailed description of exemplary embodiments of the disclosure and the Examples included therein and to the Figures and their previous and following description.

Before the present articles, devices, apparatuses, systems, and/or methods are disclosed and described, it is to be understood that the subject disclosure is not limited to specific synthetic methods, specific materials and material combinations, or to particular shapes or morphologies, as such may, of course, vary. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Thus, for example, reference to “an integrated circuit” refers to a single integrated circuit or to combinations of two or more integrated circuits, reference to “ring oscillator” includes mixtures of two or more ring oscillators, which can be coupled either directly or indirectly, reference to “a ring oscillator stage” refers to a single ring oscillator stage or several or to two or more such stages, and the like.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

In the subject disclosure and in the claims which follow, reference will be made to a number of terms which shall be defined to have the following meanings: “Optional” or “optionally” means that the subsequently described event or circumstance may or may not occur, and that the description includes instances where said event or circumstance occurs and instances where it does not.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Throughout the description and claims of the subject specification, the word “comprise” and variations of the word, such as “comprising” and “comprises,” means “including but not limited to,” and is not intended to exclude, for example, other additives, components, integers, steps, acts, and so forth. In addition the terms “including” and “having” are employed in the subject disclosure in the same manner as the term “comprising.” “Exemplary” means “an example of” and is not intended to convey an indication of a preferred or ideal embodiment. “Such as” is not used in a restrictive sense, but for explanatory purposes.

Reference will now be made in detail to several exemplary embodiments of a phase-change oscillator and pulse generator in accordance with aspects of the subject disclosure. Wherever possible, the same reference numbers are used throughout the drawings to refer to the same or like parts.

As employed in this specification and annexed drawings, the terms “unit,” “component,” “interface,” “system,” “platform,” and the like are intended to include a computer-related entity or an entity related to an operational apparatus with one or more specific functionalities, wherein the computer-related entity or the entity related to the operational apparatus can be either hardware, a combination of hardware and software, software, or software in execution. One or more of such entities are also referred to as “functional elements.” As an example, a unit may be, but is not limited to being, a process running on a processor, a processor, an object, an executable computer program, a thread of execution, a program, a memory (e.g., a hard disc drive), and/or a computer. As another example, a unit can be an apparatus with specific functionality provided by mechanical parts operated by electric or electronic circuitry which is operated by a software or a firmware application executed by a processor, wherein the processor can be internal or external to the apparatus and executes at least a part of the software or firmware application. In addition or in the alternative, a unit can provide specific functionality based on physical structure or specific arrangement of hardware elements. As yet another example, a unit can be an apparatus that provides specific functionality through electronic functional elements without mechanical parts, the electronic functional elements can include a processor therein to execute software or firmware that provides at least in part the functionality of the electronic functional elements. An illustration of such apparatus can be control circuitry, such as a field-programmable gate array (FPGA) or a programmable logic controller. The foregoing example and related illustrations are but a few examples and are not intended to be limiting. Moreover, while such illustrations are presented for a unit, the foregoing examples also apply to a component, a system, a platform, and the like. It is noted that in certain embodiments, or in connection with certain aspects or features thereof, the terms “unit,” “component,” “system,” “interface,” “platform” can be utilized interchangeably.

The disclosure identifies and addresses, in one aspect, the issue of counterfeiting and recovery of integrated circuits. The counterfeiting of integrated circuits (ICs) has been on the rise, potentially impacting the security and reliability of a wide variety of electronic systems. The counterfeiting and recycling of integrated circuits (ICs) have become major problems in recent years, potentially impacting the reliability and security of electronic systems bound for military, financial, or other critical applications. With identical specification, functionality, and packaging, it is extremely difficult to distinguish recovered ICs from unused ICs.

A counterfeit component is defined as an electronic part that is not genuine because (i) it is an unauthorized copy; (ii) it does not conform to original component manufacturers design, model, and/or performance; (iii) it is not produced by the original component manufacturers or is produced by unauthorized contractors; (iv) it is an off-specification, defective, or used original component manufacturers product sold as “new” or working; and/or (v) it has incorrect or false markings and/or documentation.

Certain data suggest that ICs in category (iv) may account for 80 to 90% of all counterfeits being sold worldwide. In addition, the Office of Technology Evaluation, part of the U.S. Department of Commerce, reported over 5,000 incidents involving the re-sale of used or defective ICs in 2008 alone. Based on the available data, it is likely that the intentional sale of used or defective chips in the semiconductor market may have accounted for between $9 billion and $15 billion of all semiconductor sales in 2005 alone. Other data suggest an increase in such illicit sale activity.

The number of microcircuit-related counterfeiting incidents reported by component manufacturers more than doubled over the period from 2005 to 2008 [1]. One subset of these counterfeits whose growth has been particularly fast are the “recovered” or “recycled” ICs. Such recycled, or recovered, ICs can enter the market when electronic “recyclers” divert scrapped circuit boards away from their designated place of disposal for the purposes of removing and reselling the ICs on those boards. In the subject specification and annexed drawings, such used or defective ICs are referred to as “recycled” or “recovered” ICs/dies—ICs which have been removed from their original boards for the purpose of illicit resale. In addition, in the subject disclosure, the terms “recovered IC” and “recovered die” are used interchangeably unless context precludes clarity. It is vital that recovered ICs are prevented from entering critical infrastructure, aerospace, medical, and defense supply chains, as their previous use will result in them failing sooner and less predictably than the ICs they are meant to mimic. It is estimated that recovered ICs account for 80 to 90% of all counterfeits sold worldwide.

The growth of this type of counterfeit is worrisome for at least the following reasons: the reliability and security concerns that these recovered ICs present, and the difficulties involved with detecting them. Recovered ICs typically are less reliable than their non-used counterparts. The stresses of the recovery process and the previous usage of the IC in the field will result in recovered ICs having reduced lifetimes, causing them to act like ticking time bombs in the systems using them. Previous usage of the IC can result in degradation of performance-related parameters of the IC, causing recovered ICs to operate at lower frequencies or with more leakage current than non-used ICs. Recovered ICs may also have been further tampered with during the recycling process, and represent a general reliability and security risk.

These recovered ICs can be classified into two categories: partially recovered ICs and fully recovered ICs. Partially recovered ICs will have same external appearance as the IC they are meant to mimic, but do not contain the correct die internally—they were removed from their original board and remarked as a different IC. As such, decaping of randomly selected chips and careful inspection are effective at detecting partially recovered ICs. The more difficult class of recovered IC to detect would be the fully recovered ICs. These ICs have the original appearance, functionality, and markings as the devices they are meant to mimic, but because they were recovered from a scrapped circuit board, they have been used for a period of time before they were resold. Even the best visual inspection techniques will have a difficult time identifying these fully recovered ICs with certainty. Additionally, because fully recovered ICs contain the original, correct die internally, decap technologies will provide no assistance in their detection. It can be advantageous that recovered ICs are detected before utilization thereof as recovered ICs can cause premature and unpredictable device failure in the field.

Some recovered ICs may be detected through careful visual inspection, decaping, or X-ray photography, since the markings or parts of the package may have been damaged during the refining process. However, most recovered ICs are refined by professional remarking, packaging, and cleanup processes. It is very difficult to identify them, since they have the same appearance and functionality as their non-used counterparts. Silicon physical unclonable functions (PUFs) have been developed to generate unique identifiers for each IC based on process variations. Passive metering approaches uniquely identify each IC and register the IC using challenge-response pairs. Active metering approaches lock each IC until it is unlocked by the IP holder. Although extensive research exists in the domain of counterfeit detection and IC metering, no research has yet to address the issue of recovered ICs.

As discussed in greater detail below, one or more embodiments of devices, apparatuses, systems, or methods of the disclosure relate, in one aspect, to an apparatus to detect a recovered IC. The apparatus, which can be referred to a die recovery sensor, can be configured to distinguish a recovered IC from a non-used IC. In certain embodiments, the apparatus can comprise a reference ring oscillator (RO) and a stressed ring oscillator. For non-used ICs, the frequency difference (or frequency shift) between the stressed RO and the reference RO can be utilized as a fingerprint of such ICs. The fingerprint can be compared with data indicative of frequency shift among a reference RO and a stressed RO in a circuit under authentication (CUA) and, based on outcome of such comparison, the CUA can be identified as a non-used IC or a recovered IC. In one aspect, statistical data analysis can permit separation of process and temperature variations from aging effects on a DR sensor present in an IC. Results of simulations featuring a DR sensor based on 90 nm technology, and experimental results in manufactured 90-nm test chipsets (referred to as silicon results) can demonstrate the efficacy of the apparatus and related analysis methodology for detection (or identification) of a recovered IC.

In another aspect, the disclosure relates to a novel path-delay fingerprinting technique (e.g., apparatus and/or methodology) to distinguish a recovered IC from a non-used IC. It should be appreciated that due to degradation in the field, the path delay distribution of recovered ICs can be different from such distribution as observed in non-used ICs. Statistical data analysis can permit separation of process variations effects from aging effects on path delay and related distributions. Results of simulations of benchmark circuits using 45 nm technology can demonstrate the efficacy of the disclosed technique for identification of a recovered IC.

In yet another aspect, the disclosure relates to novel methodologies for analyzing circuit parameters, such as leakage current, transient current, and performance (e.g., switching frequency), to distinguish recovered ICs from non-used ICs. When a circuit is used in the field, even for a very short period of time, the specification of the IC can change. For instance, an integrated circuit can ages when used in the field, resulting in degradation in performance: Threshold voltage of gates and/or transistors can change due to effects such as NBTI and HCl. As described herein, a novel path delay analysis technique is developed and implemented to distinguish recovered ICs and non-used ICs. Path delay distribution of a recovered IC can be different from that of a non-used IC due primarily to aging of the IC in the field. In certain embodiments, simulation results from HSPICE using 90 nm technology can demonstrate the efficacy of various aspects of embodiments of the disclosure.

As described herein, an IC can age functionally in response to operation in functional mode and path delay can increase as the IC operates for a longer period in the field. In one aspect, a path-delay fingerprint from a set of sample non-used ICs can be generated. In certain implementations, a specific portion (e.g., top 10%) of critical paths in a design can be selected to be measured in test mode. Size of the portion of selected paths can be adjusted based on size of the IC). Principal components analysis (PCA) can be utilized for statistical analysis on measured path delays. In one aspect, a convex hull can be obtained from the first three principal components from the fresh ICs. When path delay of a CUA is beyond the fingerprint of non-used ICs, the CUA can be deemed to be a recovered IC.

In still another aspect, IC recovery detection can be effected using embedded sensors. The sensors can comprise substantially any sensors that can exhibit performance aging (or degradation, for example). For example, the sensors can probe current leakage, current transient, and the like. The sensors that can be embedded in an IC to permit detection of IC recovery can comprise one or more of buffer chains, inverter chains, flip-flop chains, or the like. In one embodiment, a novel and light-weight die recovery (DR) sensor (also referred to as a combating die recovery (CDR) sensor) to permit detection of recovered ICs in the field. The CDR sensor is composed of a reference ring oscillator (Reference RO) and a stressed ring oscillator (Stressed RO). In certain scenarios, the Stressed RO can be designed to age at a high rate while the Reference RO is gated off from the power supply during the stress phase (e.g., in operation mode) and thus the Reference RO can avoid stress effects. In one aspect, the frequency difference between the Stress RO and the Reference RO can reveal, or indicate, aging level of the chipset under authentication (CUA). For instance, the frequency shift between the Reference RO and the Stress RO can be indicative of a time interval the CUA has operated in functional mode. Larger frequency shifts can be indicative, with a higher probability, that the CUA is a recovered IC. In one aspect, through judicious placement of the Reference RO and the Stressed RO, the impact of intra-die process variations can mitigated (e.g., minimized or avoided). In another aspect, data analysis can permit distinguishing a frequency shift caused by aging from shifts in frequency due to temperature and inter-die process variations. Thus, the data analysis can permit identification of a recovered IC.

In certain scenarios, a DR sensor disclosed can present a small area overhead and is resilient to removal and tampering attacks. The outright removal or disconnection of the DR sensor from the circuit would easily be detected when the sensor fails to report reasonable values. It should be appreciated that, tampering attacks in which an attacker can attempt to modify the DR sensor in a manner that the DR sensor can report incorrect values may be devised in certain scenarios. For ICs where additional security and confidence are required, alterations can be implemented to mitigate such type of attacks. In certain scenarios, the DR sensor may be obfuscated inside the IC by spreading out the gates of the sensor over a wider area. Such modification can make it more difficult for an attacker to analyze the IC, thus rendering the DR sensor more resilient to tampering or unintended modification. Additional modifications for improved security can be implemented.

### A. Aging Effects

Aging effects of NBTI and HCl may cause parametric shifts and circuit failures, as demonstrated by reliability models available in the art. In one aspect, NBTI can increase the absolute value of the PMOS threshold voltage, resulting in reduced transistor current and increased gate delay. In another aspect, HCl can create traps at the silicon substrate/gate dielectric interface, and can create dielectric bulk traps, and therefore impacts device operational parameters. Since recovered ICs generally have been impacted by such aging effects, circuit parameters of recovered ICs generally are different from those of non-used ICs. In scenarios in which a fast-aging sensor can be embedded into an integrated circuit to permit detection of aging period of the circuit, then a determination as to whether the IC is recovered or not can be made.

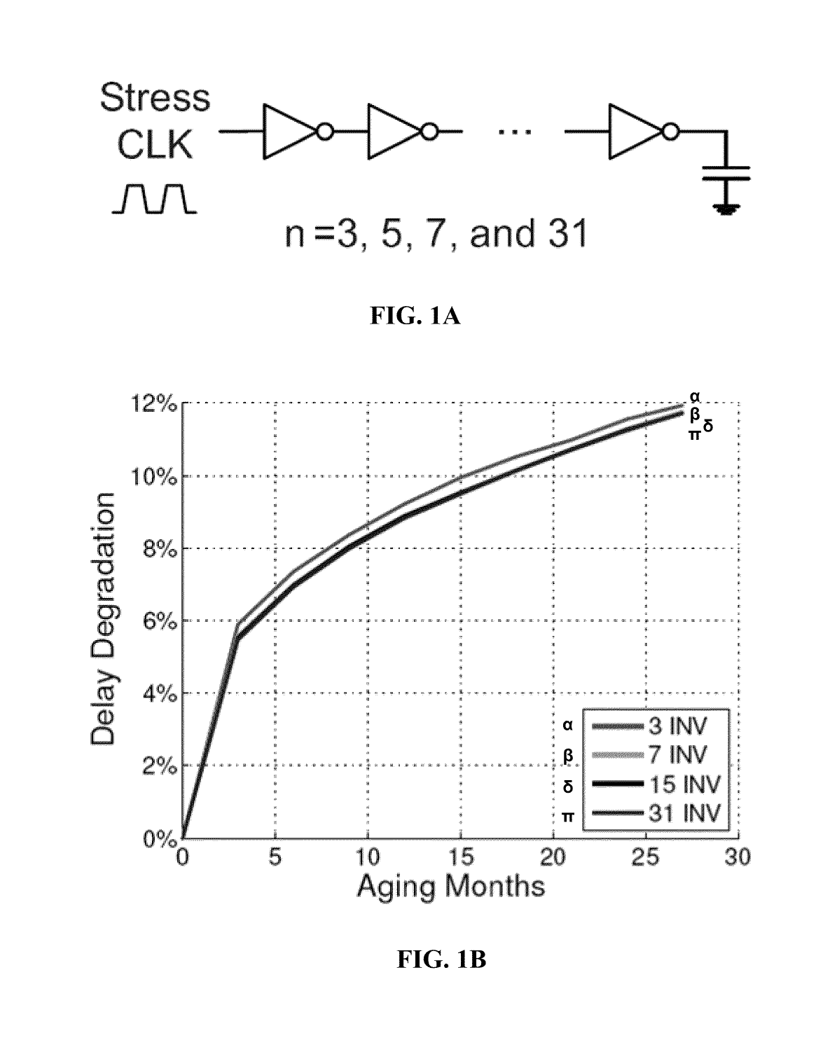

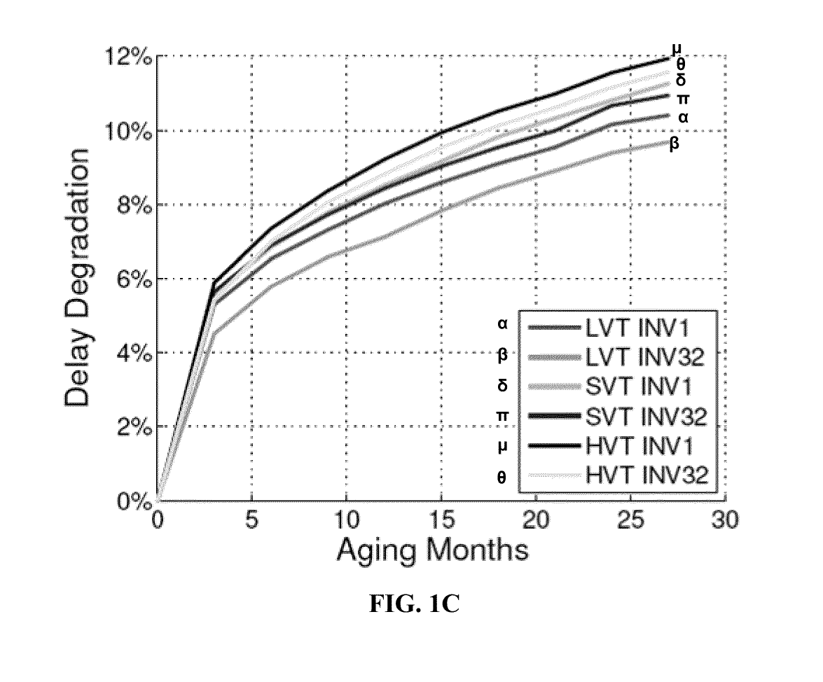

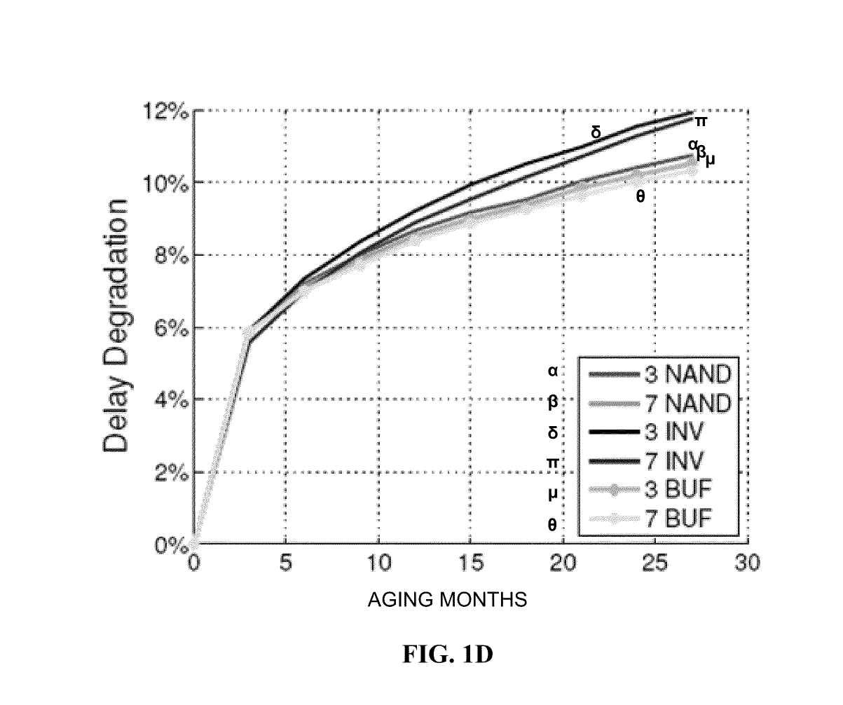

To assess the effects of aging on performance of an integrated circuit, several different inverter chains can be simulated using Synopsys 90 nm technology. In one aspect, the delay of such inverter chains can represent the performance of the integrated circuit. The simulation was conducted using HSPICE MOSRA with combined NBTI and HCl aging effects at room temperature (e.g., about 25° C.). FIG. 1(a) illustrates the basic structure of the inverter chains with the same capacitance load and the same stress originating from a 500 MHz clock signal (or clock). In certain embodiments, the chains can comprise 3, 7, 15, and 31 standard threshold voltage (SVT) inverters. FIG. 1(b) presents the delay degradation of inverter chains under clock stress for up to 27 months. It can be appreciated that the number of inverters does not have a significant impact on the degradation of these chains since the inverters can receive the same stress, and each inverter's speed degrades at the same rate. In certain scenarios, aging effects can be dependent on device's threshold voltage. Three different threshold voltage models can be available for implementation in a simulation platform, such as Synopsys 90 nm technology: (1) SVT, (2) low threshold voltage (LVT), and (3) high threshold voltage (HVT). In one implementation, a 3-inverter chain can be simulated using such threshold voltages and two different size inverters (e.g., INVX1 and INVX32). As illustrated in FIG. 1(c), a chain having HVT inverters can experience more degradation than chains having SVT and/or LVT inverters. In one aspect, the INVX1 inverter chain can have a larger degradation than the INVX32 inverter chain.

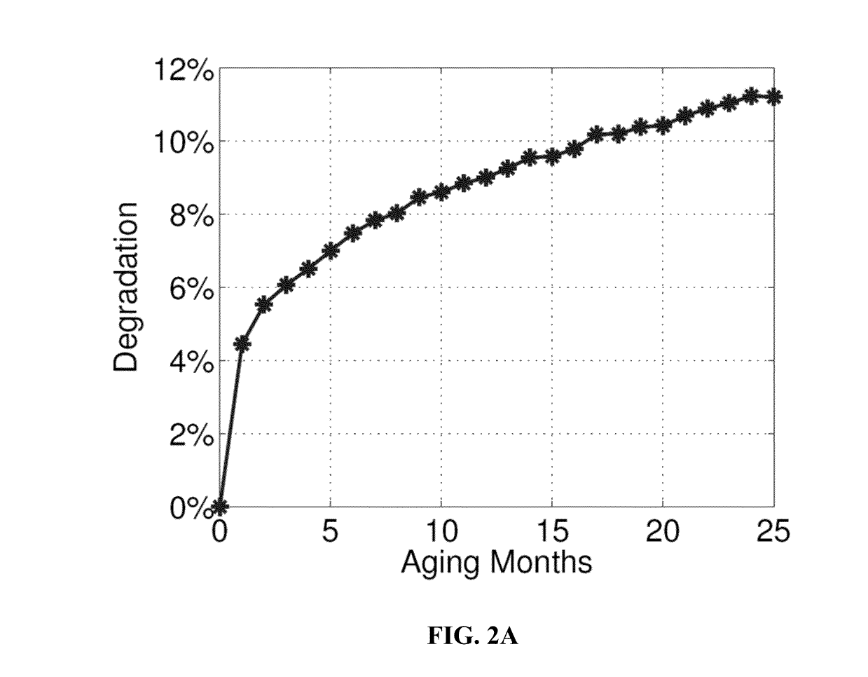

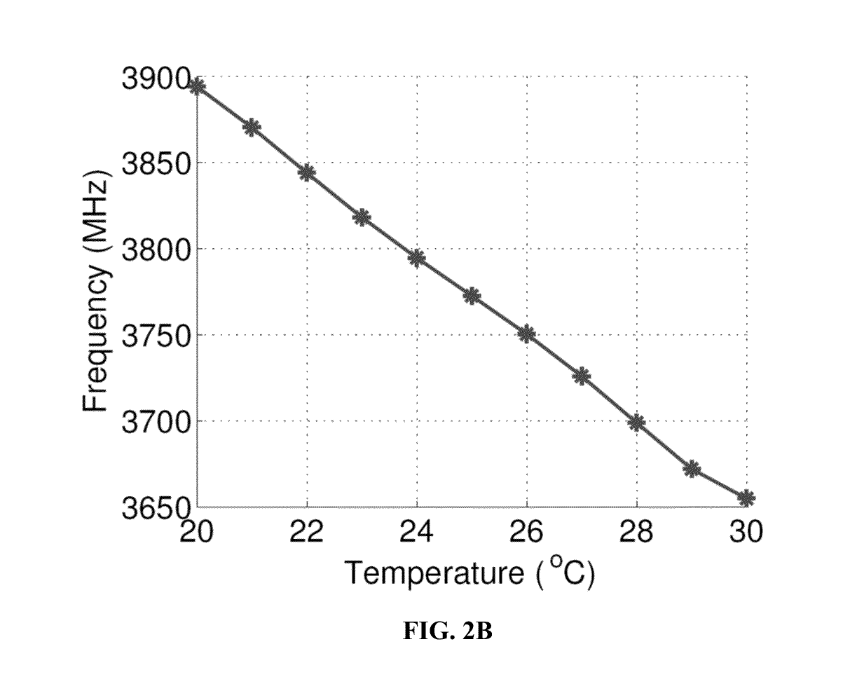

In certain embodiments, as illustrated in FIG. 1(d), NAND and buffer (BUF) gate chains with HVT were also simulated at 25° C. with a 500 Mhz clock stress. In one aspect, the basic structure of these chains is the same as the inverter chains. A NAND gate will function as an inverter when its two inputs are connected together. FIG. 2 shows the simulation results. From the figure, it can be appreciated that the gate type does not impact the aging speed significantly. However, the inverter chain ages slightly faster than the others while NAND gate chain and BUF chain age at almost the same speed. The difference in the amount of aging depends on the structure of gates. Therefore, inverters (INVX1) with HVT will be used to create the ring oscillators used to detect recovered ICs in our simulation analysis.

FIG. 2(a) illustrates frequency degradation of a ring oscillator in accordance with one or more aspects of the disclosure. In one aspect, frequency degradation of an exemplary 5-stage ring oscillator having HVT inverters after aging for 25 months is illustrated. The frequency of the RO in a recovered IC can be smaller than in a non-used IC. If there are no environmental or process variations, identification of recovered ICs can be readily accomplished by measuring frequency of an RO embedded in the circuit. However, variations can have a significant impact on the frequency of ROs. As illustrated in FIG. 2(b), frequency of the 5-stage RO can decrease as temperature is increased, and that frequency variation can be substantive.

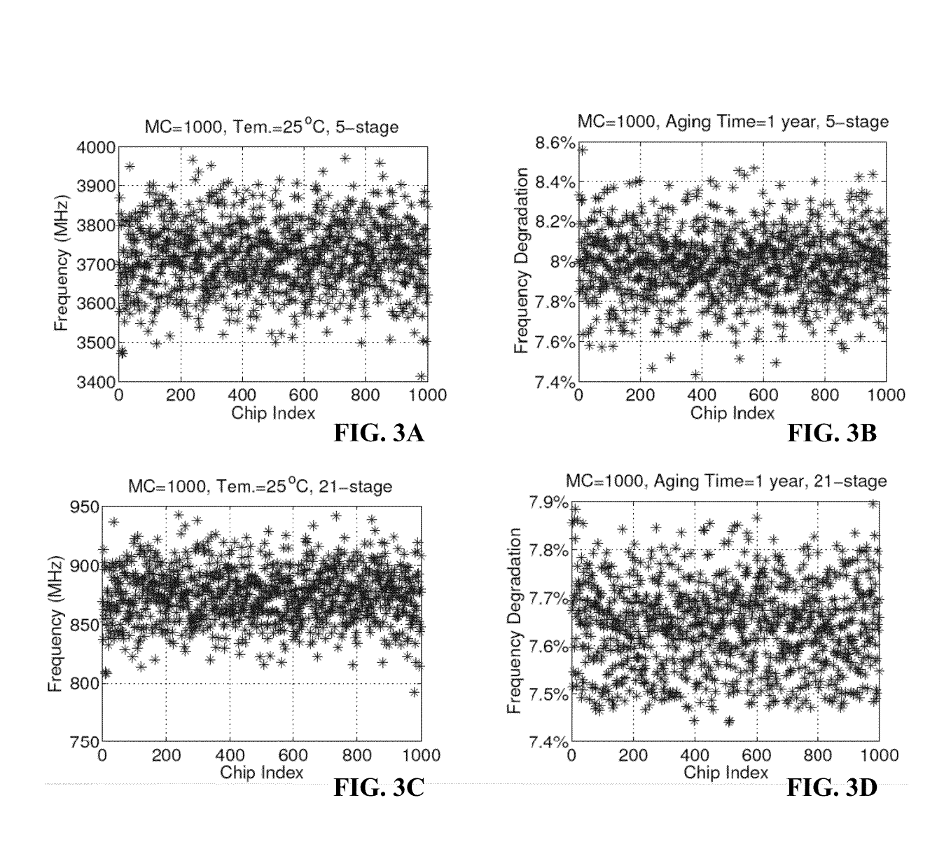

In one aspect, results from 1000 Monte Carlo (MC) simulations of a 5-stage RO are illustrated in FIG. 3(a), at a temperature of 25° C. with 2% Tox, 5% Vth, and 5% L inter-die variation and 1% Tox, 5% Vth, and 5% L intra-die variations. Each MC simulation represents a specific chipset. It can be appreciated that the frequency of the RO can vary as much as 20% under process variations. In addition, as illustrated in FIG. 3(b), process variations can impact aging rate of the RO. The frequency degradation of the 1000 chipsets can vary around 8% (7.4%-8.6%) for a one-year aging period. Such frequency shift can be caused by aging effects in recovered ICs and can permit, at least in part, separating the aging effects from those caused by process variations in non-used ICs. Accordingly, in certain embodiments, monitoring and/or analysis of frequency shift of an RO can permit, at least in part, detection of recovered ICs.

In one aspect, with a fixed stress, number of inverters in an inverter chain does not have a significant impact on delay degradation of the chain. Yet, the frequency of an RO can be related to the number of inverters, f=1/(2×n×t_{d}), where n is number of stages in the RO and t_{d} is the delay of an inverters. FIG. 3(c) illustrates frequency shift of a 21-stage RO having HVT inverters. Frequency degradation for such RO is illustrated in FIG. 3(d). Comparing the frequency degradation of the 5-stage and 21-stage ROs, it can be appreciated that the 5-stage RO exhibits slightly more degradation due to having an oscillation frequency that is higher than that of the 21-stage RO. In one aspect, such higher frequency in a 5-stage RO can introduce manageable design complexities, such as causing a chipset design to include a fast counter.

### B. Die Recovery Sensor

As described herein, recovered ICs typically have experienced aging—since they were removed from waste electronic boards and resold into the market—and thus aging effects may have slowed down the frequency of RO(s) embedded into such ICs. With an embedded RO, a recovered IC can be identified based on frequency or frequency shifts of the embedded RO. In one aspect, frequency of the embedded RO can be smaller than frequency of the RO in the non-used IC prior to recovery. Yet, there are several parameters that can impact the frequency of an RO, such as temperature and process variations. In one embodiment, an apparatus for IC recovery detection can utilize a Reference RO and a Stressed RO to separate aging effects from process/environmental variations. The apparatus can be referred to as a die recovery (DR) sensor.

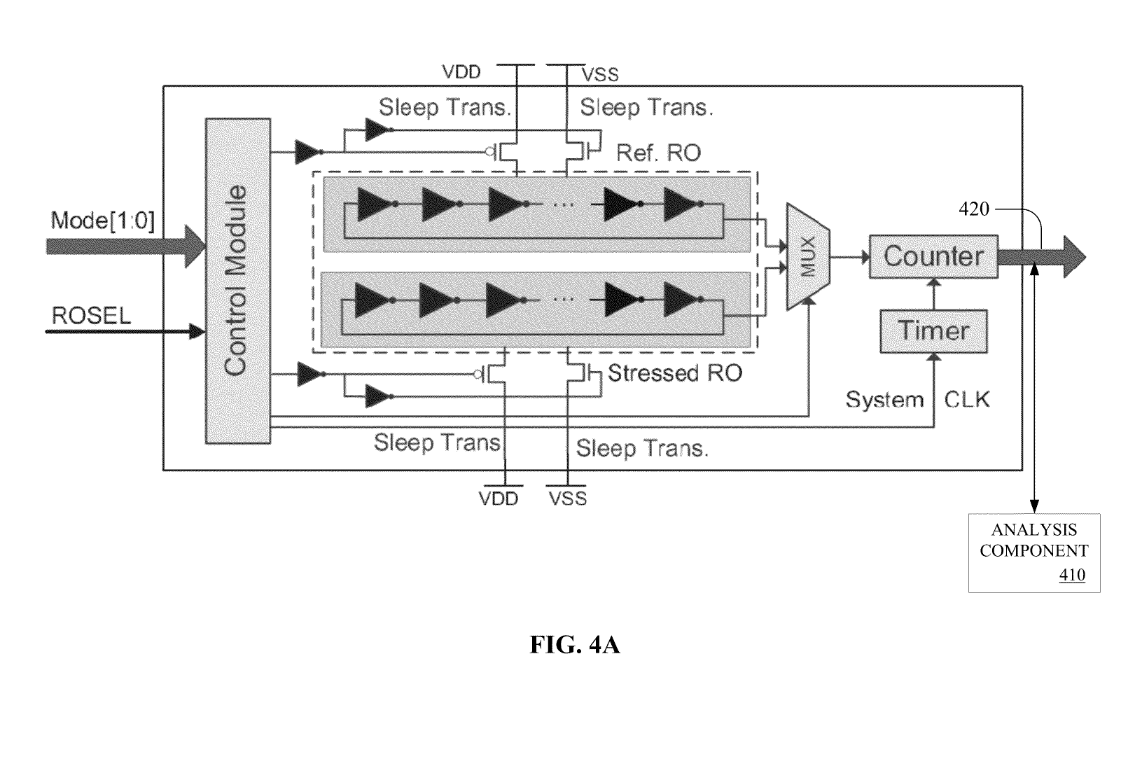

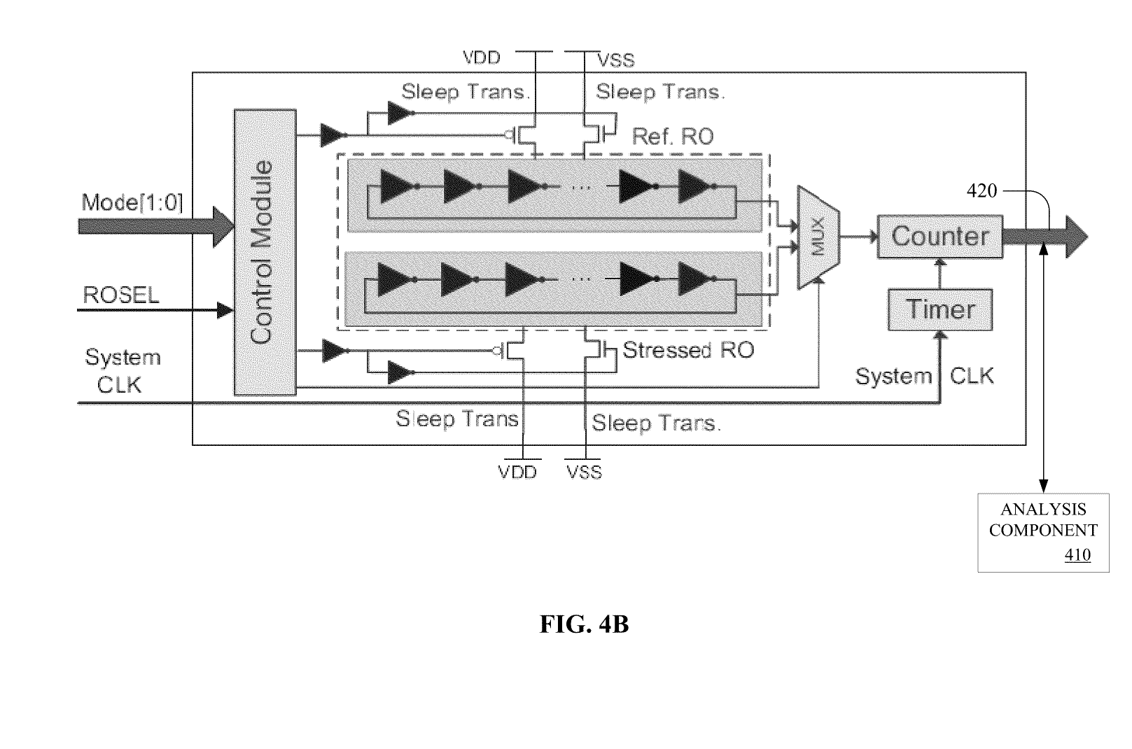

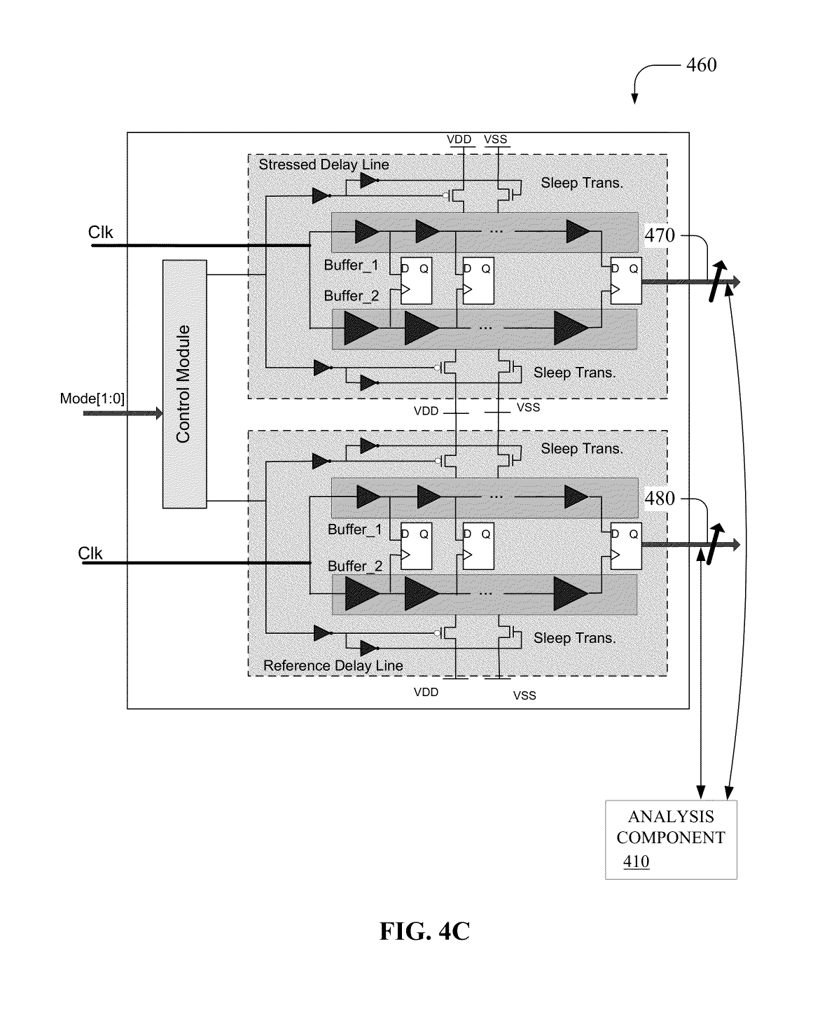

FIGS. 4(a)-4(c) illustrate exemplary embodiments of an apparatus for IC recovery detection in accordance with one or more aspects of the disclosure. In the illustrated embodiment, the apparatus comprises a control module, a Reference RO, a Stressed RO, a multiplexer (MUX), a timer, and a counter. The counter can measure the cycle count of the two ROs during a time period, wherein the time period can be controlled by the timer. A system clock (Clk) signal can be applied to (or injected into) a timer (or timer unit) functionally coupled to the counter (or counter unit). System clock is used in the timer to minimize the measurement period variations due to circuit aging. Output signal of the apparatus (e.g., output signal 420 from the counter) can be supplied to an analysis component 410 that can utilize the output signal, and data conveyed therein, to implement the various methodologies described herein. The multiplexer (MUX) can select which RO is to be measured, and can be controlled by an external signal, referred to as ROSEL, such external signal being, in one embodiment, a primary input of a design that is used to select (or enable) one of the ROs to be measured by the counter. In one aspect, the timer and counter can be enabled to measure ROs' cycle count. In one aspect, the Reference and Stressed ROs can be substantially identical, both such ROs comprising HVT components. It should be appreciated that different ROs can be utilized. For example, in certain embodiments, the inverters illustrated in FIGS. 4(a)-4(b) in the ROs can be replaced by any other types of gates (NAND, NOR, etc) In certain embodiments, a smaller-stage RO can be utilized to account for measurement features, such as speed limit of a counter, of given a technology. For example, within 90 nm technology, a 16-bit counter can operate under frequency of up to 1 GHz. In such scenario, an RO of at least 21 stages may be implemented.

In one aspect, sleep transistors can be utilized to connect one or more inverters in an RO to a power supply line in the apparatus for IC recovery detection (or the DR sensor). In another aspect, PMOS sleep transistors can control connection between VDD and the one or more inverters. In yet another aspect, NMOS sleep transistors can control connection between VSS and the one or more inverters. In one embodiment, the Reference RO and the Stressed RO can operate in one of at least three modes. A Mode signal (which can be a “high” or “low” signal, for example) can control selection of a specific mode of the at least three modes. For example, (i) when the IC is in manufacturing test mode, the Reference RO and Stressed RO can be disconnected from the power supply and experience no aging. Such mode only lasts a short time, depending on the test procedures of the IC. For another example, (ii) when the IC is in normal functional mode, the Reference RO can be disconnected from VDD and VSS, yet the Stressed RO can be gated on and thus can age. In one aspect, the frequency of the Stressed RO can become smaller, whereas the frequency of the Reference RO may not change. It should be appreciated that ICs may spend most of their operational time in such mode. For yet another example, (iii) when the IC is in measurement mode (e.g., when an IC is taken from market and authenticity of the IC is to be verified), both the Reference RO and Stressed RO can be gated on by connecting to the power supply. In one aspect, the timer and counter can be enabled to measure a cycle count of such ROs, and ROSEL signal can select one of the Stressed RO or the Reference RO to measure. In another aspect, other functionality of the IC can remain turned off during operation in one of the foregoing modes.

In one aspect, the inverters of the Reference RO and the Stressed RO can be placed physically next to each other (e.g., as illustrated in FIGS. 4a-4b) and can be designed as a single module, which based on the application, it can be a small module. The process and environmental variations between the Reference RO and the Stressed RO are intended to be small in order to mitigate effects of such variations on the relative frequency shift due to aging. Therefore, for a non-used IC, the frequency difference (or frequency shift) between the Reference RO and the Stressed RO can be within a certain small range. In a recovered IC having an Reference RO and a Stressed RO as described herein, the Stressed RO may have suffered aging from its own oscillation since the chip has been working in normal functional mode for certain time. Yet, the Reference RO may not have experienced as much aging because it was gated off. The frequency shift between the Reference RO and the Stressed RO can increase as such recovered IC operates longer. Such increment can be demonstrated by simulation and experimental results in silicon in accordance with aspects described herein. In scenarion in which the frequency shift among the Stressed RO and the Reference RO is outside of the frequency shift range present in non-used ICs considering process variations, it can be determined with a substantive level of confidence that the chipset under authentication (CUA) is a recovered IC (e.g., recovered from a used board).

In one aspect, area overhead of an apparatus for IC recovery detection in accordance with aspects described herein can be negligible when compared to the area covered by millions of gates present in modern ICs. With a 16-bit counter, the area overhead on the ISCAS′89 benchmark s38417, a DES implementation, and an implementation of the 8051 microprocessor is 0.16%, 0.09%, and 0.006%, respectively. In another aspect, power consumption also can be limited to that consumed by the Stressed RO in the DR sensor. In yet another aspect, the disclosed DR sensor can be resilient to a removal attack and/or tampering attack. For instance, it should be appreciated that it is inherently difficult for a recycler to remove the DR sensor, in view of the expected measurement types expected to be applied to, and related results obtained from, the Stressed RO and the Reference RO. Such removal resilience feature of the DR sensor can permit, at least in part, detection of partially recovered ICs. It also should be appreciated that the Reference RO may not be intentionally aged in order to mask the difference between the Stressed RO and the Reference RO present in the DR sensor in view that the Reference RO cannot be gated on individually. The feature associated with resilience to removal and/or tampering attacks of the CDR sensor can permit detection of partially recovered ICs. It should be appreciated that it is possible to argue that attackers with unlimited resources may be able to remove the chip package, modify the original design, and tamper the CDR sensor. For such ICs where additional security is required, alterations could be made to the DR sensor to prevent these kinds of attacks. The DR sensor could be obfuscated inside the IC by multiplexing functional gates. Such modification can render the DR sensor more resilient to attacks that rely on analysis of the IC, thus rendering the DR sensor more resilient to tampering or modification. Additional modifications for further security also can be implemented.

FIG. 4(c) illustrates an exemplary embodiment of a DR sensor 460 that can utilize two or more buffer-delay-line sensors in accordance with aspects of the subject disclosure. The DR sensor 460 can comprise a control module, a stressed delay line (or a first delay line) and a reference delay line (or a second delay line). In certain implementations, the stressed delay line and the reference delay line can be substantially identical, each of such lines comprising one or more flip-flops and at least two different sizes of buffers. As implemented in other DR sensors of the disclosure, the DR sensor 460 can comprise sleep transistors that can connect the buffers contained in each delay line to a power supply. In one aspect, each of the reference delay line and the stressed delay line can operate in three modes, which can be modes (i) through (iii) described herein. In one aspect, a Mode signal can control selection of a mode of operation (e.g., mode (i), mode (ii), or mode (iii)).

In one aspect, for a non-used IC having DR sensor 460, the difference between the value captured by flip-flops in the reference delay line and in the stressed delay line can be within a specific range. Yet, in a scenario in which the non-used IC is in normal functional mode, the reference delay line can be disconnected from VDD and VSS, but the stressed delay line can be gated on and can age. In one aspect, the delay difference between buffer_{—}1 and buffer_{—}2 in the stressed delay line can increase, whereas such difference in the reference delay line can remain substantially unchanged. Accordingly, output signal from the stressed delay line can be different from output signal from the reference delay line can be different in a used IC than such output signals in a non-used chips. Therefore, in DR sensor 460, output signal or signal indicative of difference thereof can be utilized to detect recovered ICs in accordance with various aspects described herein. For instance, an analysis component (e.g., component 410) can collect output signal 470 and 480 and implement the various methods (e.g., SOA or PCA) in accordance with one or more aspects described herein.

### C. Exemplary Measurement Process

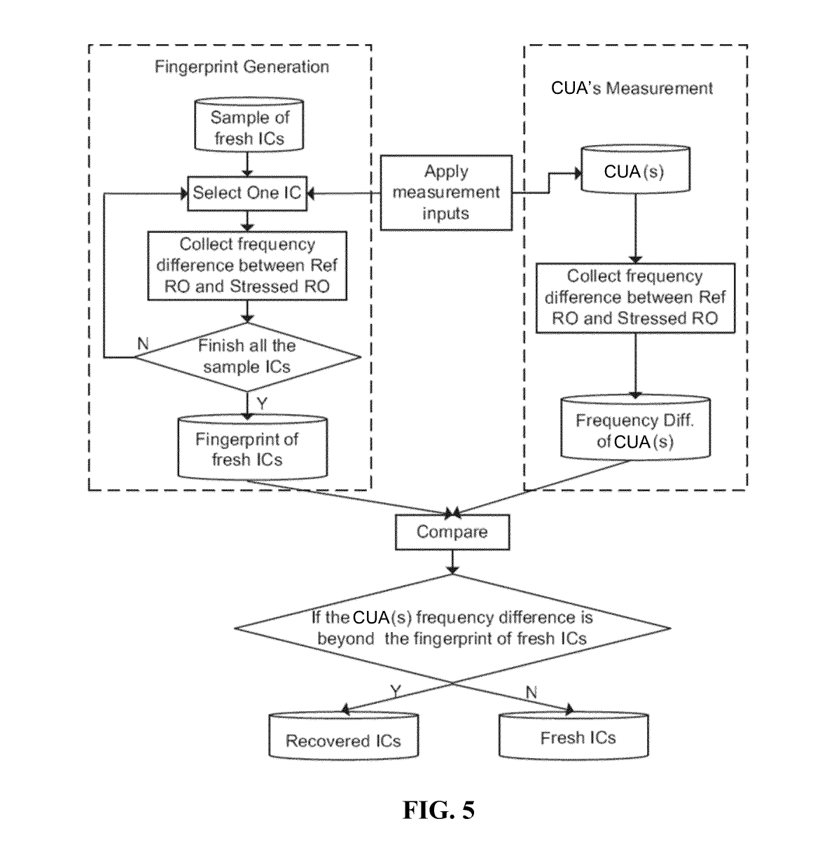

FIG. 5 illustrates an exemplary methodology for identifying recovered ICs in accordance with one or more aspects of the disclosure. As illustrated, the methodology comprises an exemplary method for generating a fingerprint, and exemplary method for probing a chipset under authentication (CUA), and a plurality of actions directed to determining if the CUA is a recovered IC. First, a plurality of non-used ICs can be utilized as sample chipsets to generate a fingerprint. The plurality of non-used ICs can be randomly selected and can comprise chipsets from one or more wafers or one or more lots of wafers. A larger number of items in the plurality of non-used ICs can permit covering a larger space of process variations, thus reducing the probability that two or more non-used ICs with large process variations can be identified as recovered ICs. In one implementation, the plurality of non-used ICs can contain 1000 sample chipsets that are tested through simulation. In one aspect, a frequency of the Reference RO and a frequency of the Stressed RO can be measured. While temperature of the measurement environment is to be maintained stable, with negligible variation, it should be appreciated that temperature variation may not impact the identification results significantly because the Reference RO and the Stressed RO can experience substantially the same environmental temperature.

After each chipset of the plurality of non-used ICs are measured, the frequency difference between the Reference RO and the Stressed RO can be calculated, with f_{diff}=f_{ref}−fₛₜᵣ, where f_{ref} is frequency of the Reference RO and fₛₜᵣ is the frequency of the Stressed RO. In one implementation, for 1000 sample non-used chipsets, the range of f_{diff} can be determined using distribution analysis, thus creating a fingerprint for non-used ICs.

Similarly, for one or more CUAs, a frequency difference between the frequency of the Reference RO and the frequency of the Stressed RO can be generated. Such frequency difference can be compared with the fingerprint for non-used ICs. Upon or after such comparison is performed, it is determined if F_{diff} of a CUA is out of the range of the fingerprint of a non-used IC. In the affirmative case, the CUA has a high probability of being a recovered IC. Otherwise, in the negative case, the CUA can be assumed to be a non-used IC. It should be appreciated that CUAs that have been in operation for a longer time interval can experience a larger, richer set of aging effects, which renders such CUAs easier to identify. In certain embodiments, the methodology for identifying recovered ICs as applied to each CUA in a set of one or more CUAs can be implemented in a very short period of time (e.g., less than a second).

### D. Exemplary Results and Analysis

In one aspect, to assess effectiveness of a DR sensor, the sensor can be modeled and simulated within a 90 nm technology model. The MOSRA from HSPICE can be utilized to simulate and measure the impact of aging on the DR sensor. The nominal supply voltage can be 1.2V. In one aspect, during simulation, in the stress phase, the Reference RO can be gated off and the Stressed RO can be gated on, thus experiencing NBTI and HCl aging. It should be appreciated that stress for the Stressed RO can originate from oscillation of the Stressed RO. In the measurement phase, the Reference RO and the Stressed RO both can be gated on and measured one by one, with each of such ROs being selected via the ROSEL signal. In one implementation, the measurement time can be configured in the timer to be about 100 μs. It should be appreciated that the clock of the counter in the DR sensor can be determined from the RO, thus the cycle count of each RO can be determined by the counter. In one aspect, the frequency of an RO is equal to the cycle count divided by measurement time.

a) Exemplary Stage Analysis of an RO

In certain implementations, DR sensors with 21-stage and 51-stage ROs can be simulated at 25° C. with process variations comprising one or more of 2% Tox variation, 5% Vth variations, and 5% L inter-die, or 1% Tox variation, 5% Vth variation, and 5% L intra-die variation. In one aspect, 1000 chipsets can be generated using Monte Carlo simulation by HSPICE. In such simulations, for example, one or more parameters for transistors in a simulated chipset can be varied either pseudo-randomly or in accordance with a protocol for parameter variation. In another aspect, total aging time can be configured to span 24 months, at intervals of one month.

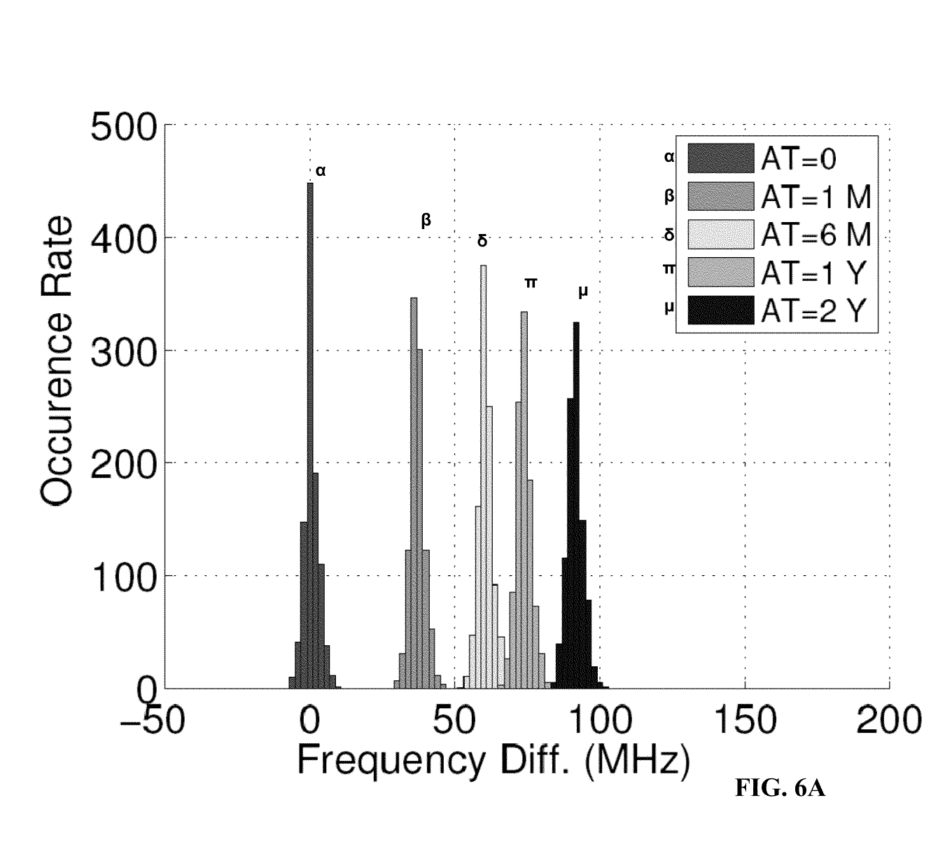

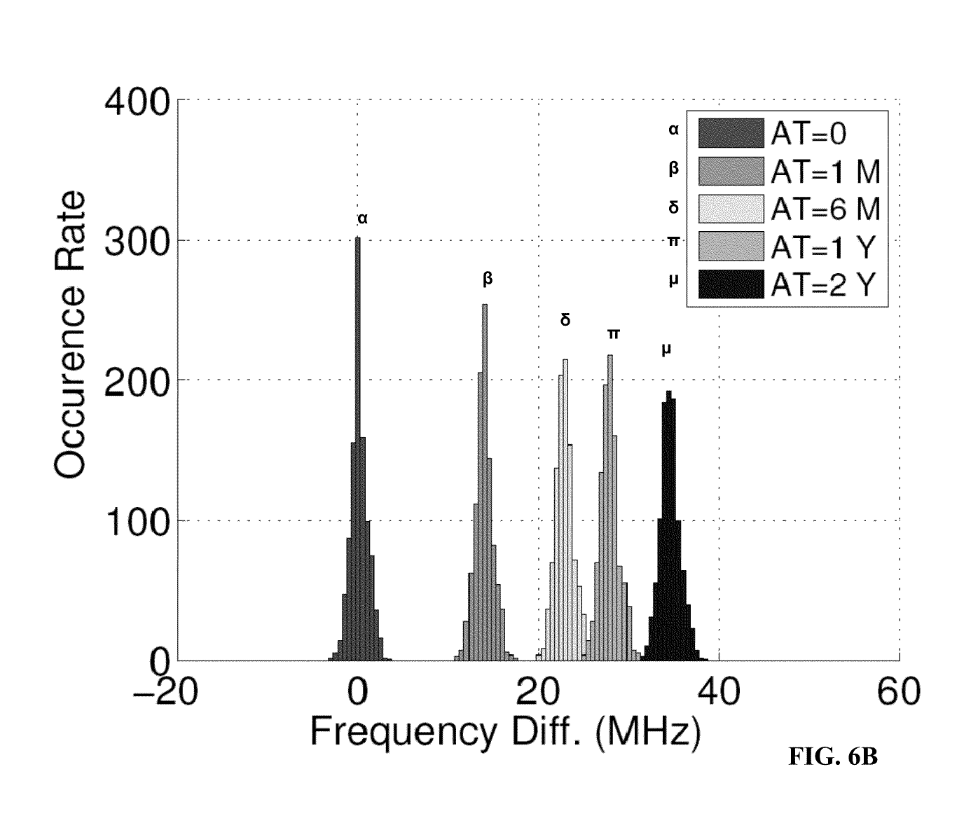

FIG. 6(a) illustrates exemplary results of frequency difference F_{diff} range between a 21-stage Reference RO and a 21-stage Stressed RO in accordance with one or more aspects described herein. Here, AT represents aging time, M represents month, and Y represents years. It can be appreciated, from the exemplary results, that the frequency difference in non-used ICs (AT=0) can be larger or smaller than 0, the frequency difference being dependent on the difference between process variations present in the Reference RO and the Stressed RO. In one aspect, process variations of a CUA can be different from those of the 1000 exemplary non-used ICs. Yet, frequency differences for the CUA present similar (e.g., nearly identical) distribution. As described herein, the range of frequency differences in a plurality of non-used ICs can be utilized as a fingerprint for non-used ICs. As illustrated, it can be appreciated that after being utilized for one month, aging effects applied to the Stressed RO and frequency thereof was reduced. In one aspect, the smallest frequency difference between the Reference RO and the Stressed RO is larger than the largest frequency difference present in the plurality of non-used ICs. Accordingly, rate of detection of a recovered IC for ICs aged for at least about one month can be about 100%. After 6 months, 1 year, and 2 years, the frequency difference between the Reference RO and the Stressed RO monotonously increases. Similarly, the variation of the frequency difference also increases. Without wishing to be bound by theory and/or simulation, such increase can occur because the aging rate can be different from chip to chip due to process variations—certain ICs aged faster and others aged slower.

TABLE I
PROCESS VARIATIONS.

| | Inter-die | | | Intra-die | | |
|---|---|---|---|---|---|---|
| | Vth | L | Tox | Vth | L | Tox |
| PV0 | 5% | 5% | 2% | 5% | 5% | 1% |
| PV1 | 8% | 8% | 3% | 7% | 7% | 2% |
| PV2 | 20% | 20% | 6% | 10% | 10% | 4% |

In one aspect, DR sensors with 51-stage ROs can be implemented using the same temperature and the same process variations as those utilized for 21-stage ROs. FIG. 6(b) illustrates exemplary simulation results of frequency difference distributions in accordance with one or more aspects of the subject disclosure. Comparing FIG. 6(a) and FIG. 6(b), it can be appreciated that the frequency difference between aged and non-used ICs can be smaller for the larger-stage ROs. In addition, the frequency difference variation decreases. It is noted that the frequency difference variation is the broadening of the frequency difference distribution. Thus, the DR sensor can detect recovered ICs that had been used for about one month with a 100% rate of detection. In scenarios in which the DR sensor utilizes large-stage ROs, the absolute value of the frequency difference between the Reference RO and the Stressed RO may be affected, but the rate of detection of a recovered IC may not be affected significantly. In certain embodiments, for different technologies, the stage count of ROs included in a DR sensor can be adjusted based on speed of a counter of the DR sensor. In certain implementations, DR sensors having 21-stage ROs according to 90 nm technology can be utilized for further analysis.

b) Exemplary Analysis of Process Variations and Temperature

Effectiveness of a DR sensor of the disclosure can depend, at least in part, on variation differences between the Reference RO and the Stressed RO included in the DR sensor. In scenarios with lower rates of variation, the DR sensor can identify a recovered IC that aged for a shorter period of time. It should be appreciated that the variations between the Reference RO and the Stressed RO can be determined, at least in part, by intra-die process variations. For instance, a DR sensor having components with small intra-die variations can be more effective than DR sensors having components with large intra-die variation. Table I illustrates different process variation rates that can be utilized to analyze impact thereof on detection of recovered IC. It should be appreciated that transitioning from PV0 to PV2, inter-die and intra-die variations both increase. In one aspect, a DR sensor having 21-stage ROs can be simulated at 25° C. utilizing such process variation rates.

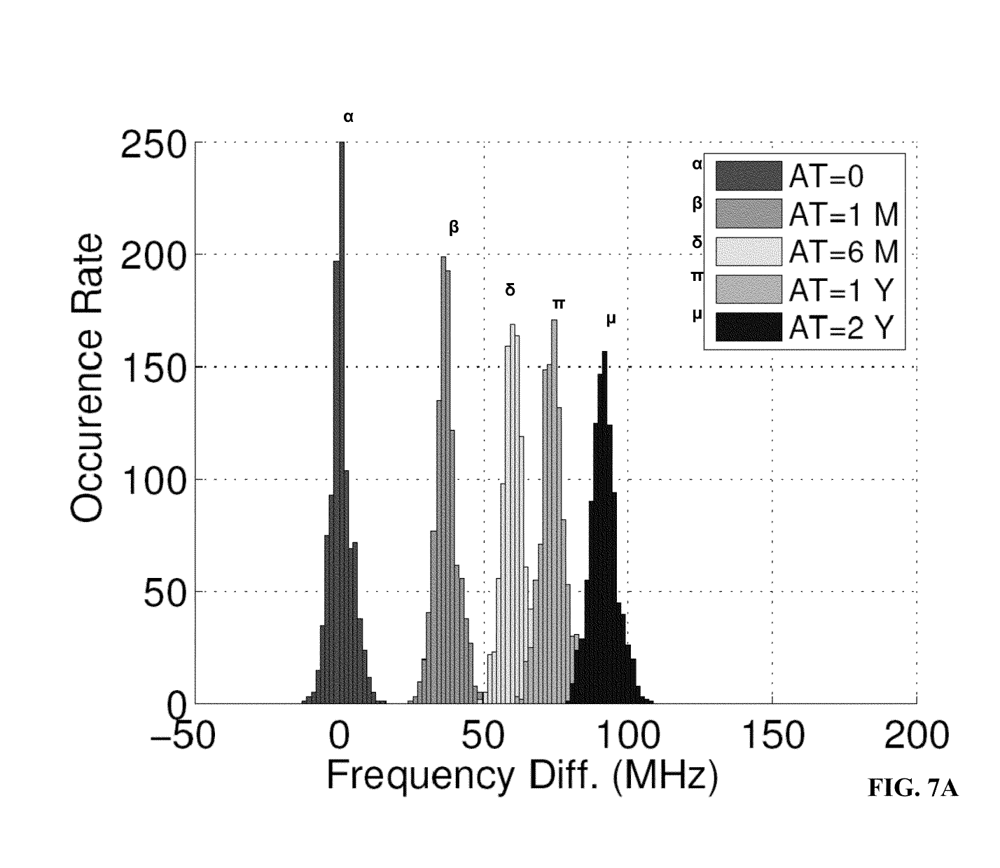

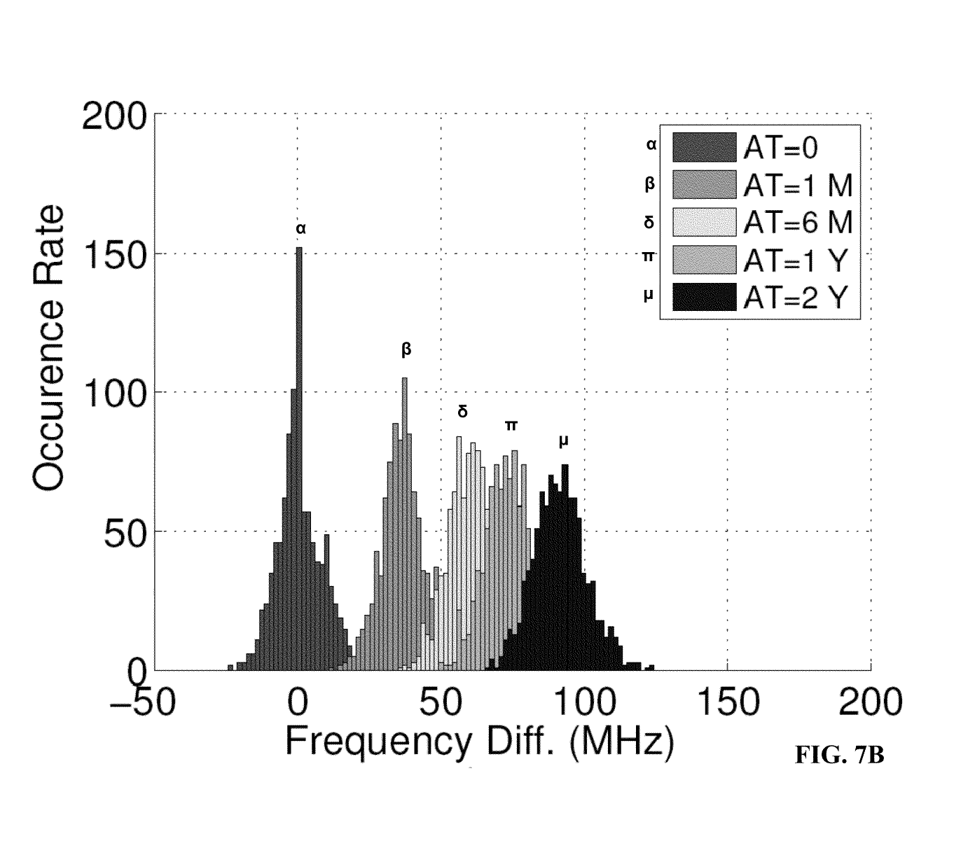

In one embodiment, by designing a DR sensor as a small module (e.g., hard macro), the Reference RO and the Stressed RO can be placed physically close and process variations between such ROs can be minimal. FIG. 7(a) and FIG. 7(b) illustrate, respectively, simulation results of 1000 chipsets with PV1 and PV2. Comparing FIG. 6(a), FIG. 7(a), and FIG. 7(b), it can be appreciated that variation of the frequency differences between the Reference RO and the Stressed RO in non-used ICs can increase with larger process variations. In one aspect, for the 1000 ICs with PV2, the rate of detection of recovered ICs aged for about one month can be less than about 100%. Yet, for recovered ICs that aged for about six months, the rate of detection can be 100%. In another aspect, the DR sensor can identify shorter-aged recovered ICs with smaller intra-die process variations as in PV0, PV1, and PV2.

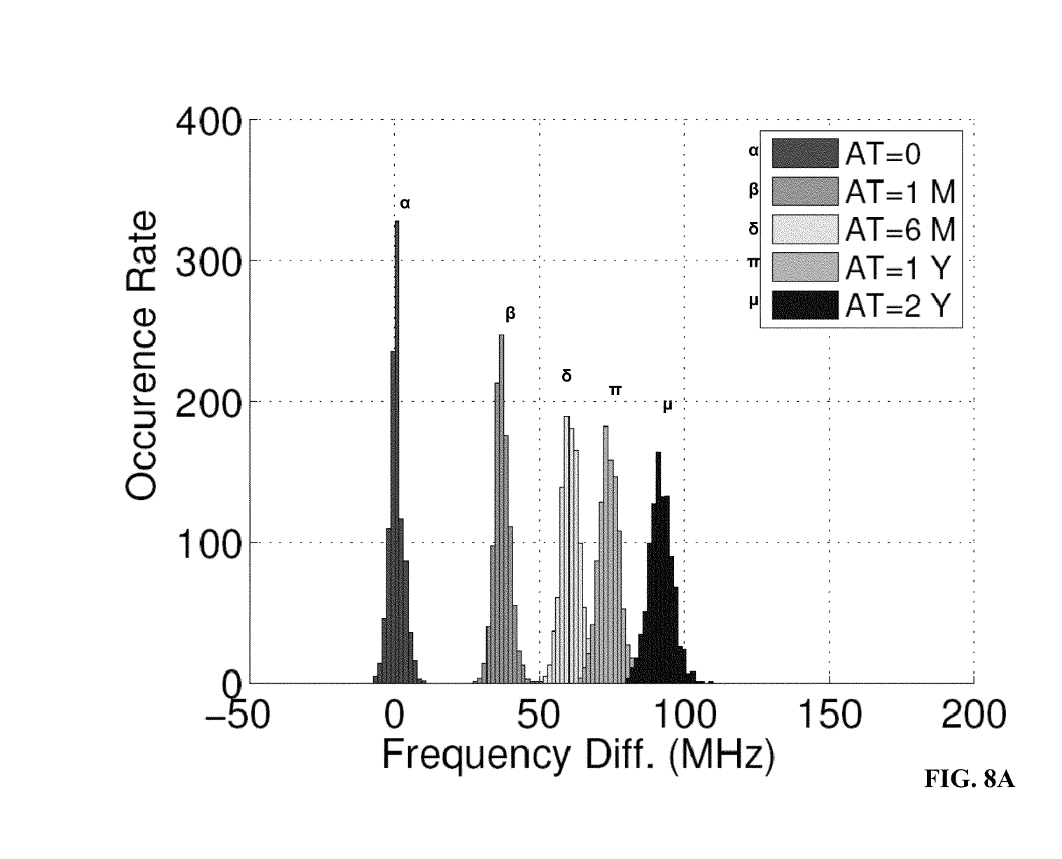

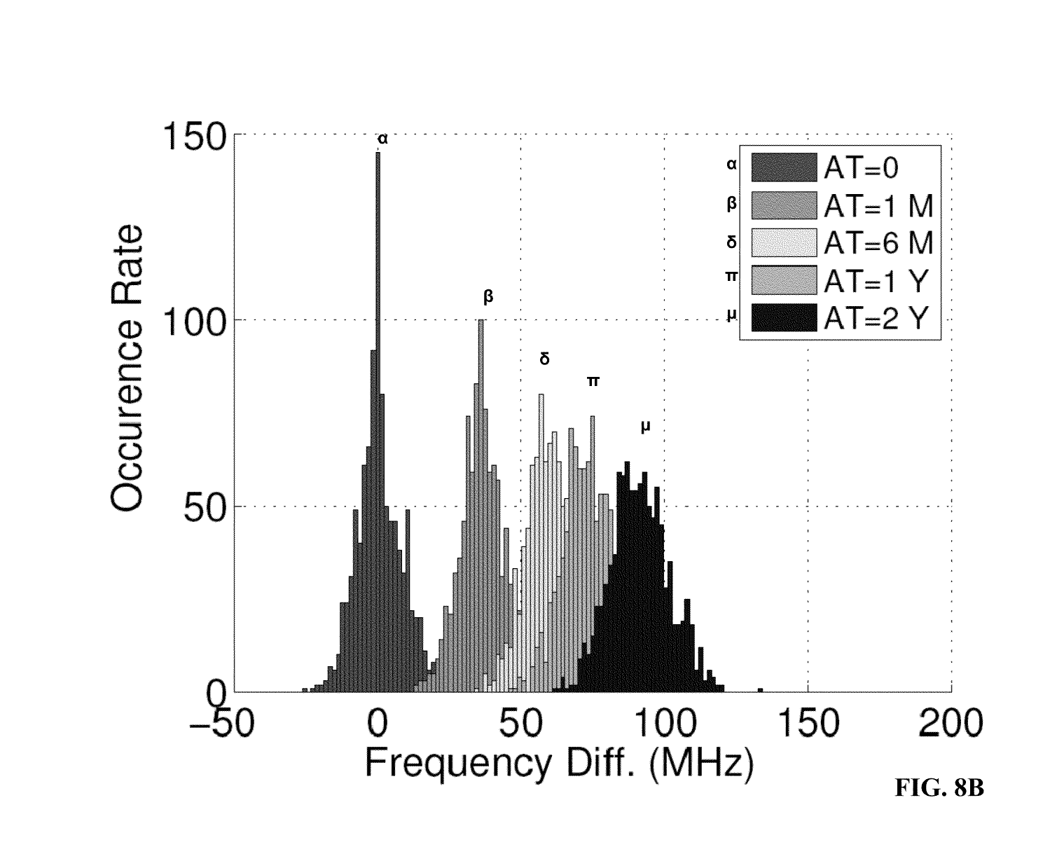

The 1000 circuits generated using Monte Carlo simulations also can be simulated with both process and temperature variations. FIG. 8(a) illustrates the frequency difference occurrence rate (or distribution) between a 21-stage Reference RO and a 21-stage Stressed RO both having process variations PV1 (see, e.g., Table I) and temperature variations of ±10° C. around room temperature. FIG. 8(b) illustrates simulation results with process variations PV2 and temperature variations of ±20° C. around room temperature. The exemplary results presented in FIG. 8(a) and FIG. 7(a) originate from chipsets having the same process variations but different temperature variations. It can be appreciated that the frequency difference variations in FIG. 8(a) can be larger than those illustrated in FIG. 7(a). Likewise, comparison of the exemplary results in FIG. 8(b) and FIG. 7(b) can yield a similar feature. In one aspect, for the 1000 chipsets having PV2 and ±20° C. temperature variations, the rate of detection of recovered ICs aged for about one month can be less than 100%; yet, such rate of detection can be about 100% for recovered ICs aged for six months. Accordingly, a DR sensor of the disclosure can be effective to detect recovered ICs having large process and temperature variations. It should be appreciated that typical authentication scenarios of a CUA may not present such large variations in temperature. In one aspect, temperature difference between a Reference RO and a Stressed RO in a DR sensor can be negligible.

c) Exemplary Silicon Results

In one aspect, a DR sensor in accordance with aspects described herein can be assessed through analysis of test chipsets fabricated using 90 nm technology. For example, an test board can be utilized with an exemplary test chipset to measure the frequency of ROs in the test chipset. The test board can be designed to assess the effects of aging on the frequency of ring oscillators, and can be utilized to demonstrate the detection efficacy of DR sensors disclosed herein. One embodiment of this chipset contains multiple separate ring oscillators using either SVT, HVT, low-leakage SVT (LSVT), low-leakage HVT (LHVT), or design for manufacturability SVT (DSVT) cells. In certain operational scenarios, a single RO in the test chipset can be enabled at a time.

In one aspect, nearly identical ROs having substantially the same cells can be utilized as DR sensors. In one implementation, an RO can be utilized as Stressed ROs, and the another RO can be utilized as a Reference RO. During measurement mode, in one aspect, such ROs can be enabled and the frequency of each ring oscillator can be collected (via a counter, for example) in accordance with one or more aspects described herein. During stress mode, in one aspect, the Stressed RO can be enabled without enabling the Reference RO, allowing the ring oscillators to age under a applied stress. As described herein, the frequency differences between such ROs can be utilized as a fingerprint of non-used ICs. With stress, the frequency differences became larger, and shifted to values beyond the fingerprint of non-used ICs.

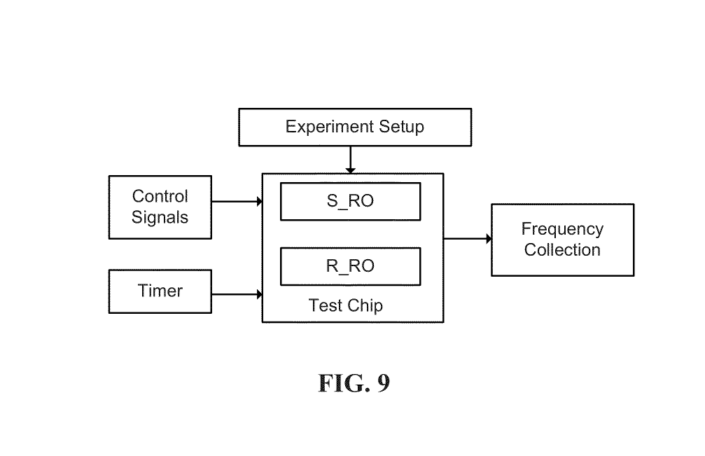

In one embodiment, 15 test chipsets, which can be part of various test boards, can be utilized to represent the impact of process variations and aging. In the test chipset (or test chip), there can be 96 delay chains (see, e.g., FIG. 4C). Such chains can be configured to operate in ring oscillator mode by controlling one or more input signals (or control signals, for example). Control of the input signals can include configuring the input signals in a manner suitable to enable an RO, or to gate off and OR. A first plurality of delay chains of the 96 delay chains can be configured, via control signals, for example, to operate as a stressed RO (S_RO) and a second plurality of delay chains of the 96 delay chains can be configured, via other control signals, for example, to operate as Reference RO (R_RO). Such R_ROs can be gated off and thus may not be submitted to aging effects. In one aspect, components (e.g., delay chains) in the test chipset can be configured to operate as RO and can be enabled by one or more Control Signals (see, e.g., FIG. 9). Such ROs can be utilized as DR sensors and can be submitted to an accelerated aging for 80 hours at 135° C. and an elevated supply voltage (e.g., 1.8 V instead of 1.2V). It should be appreciated that in controlled development scenarios, accelerated aging generally is desirable since aging effects under normal conditions are typically observed after substantive periods (e.g., weeks or months) of operation in functional mode.

Various embodiments of a DR sensor can be formed based at least on different configurations of the 96 delay chains. Each of such configurations can embody a SRO or a R_RO. As an illustration, six of such configurations enable forming three exemplary DR sensors, labeled as CDR1, CDR2, and CDR3, having the exemplary structures presented in the following table:

| | ROs in CDR sensors | | | |
|---|---|---|---|---|
| | Reference | | | Threshold |
| | RO | Stressed RO | RO Structure | Voltage |
| CDR1 | R_RO1 | S_RO1 | 1 NAND + 200 BUFs | SVT |
| CDR2 | R_RO2 | S_RO2 | 1 NAND + 200 BUFs | HVT |
| CDR3 | R_RO3 | S_RO3 | 201 NANDs | HVT |

In one aspect, CDR1 can comprise two nearly identical ROs (R_RO1 and S_RO1) with one SVT NAND gate and 200 SVT BUFs. In another aspect, CDR2 can comprise two identical ROs (R_RO2 and S_RO2) with one HVT NAND gate and 200 HVT BUFs; and CDR3 can comprise ROs (R_RO3 and S_RO3) with 201 HVT NAND gates. In still another aspect, the stage of ROs in the test chip can be 201, whereas the stage of ROs used in Monte Carlo simulation can be smaller (e.g. 21). Here, R_RO1, R_RO2, and R_RO3 are Reference ROs while S_RO1, S_RO2, and S_RO3 are Stressed ROs, respectively. In the implementations in the exemplary test chipset, the gates contained in the ROs in such test chipset are complex gates (BUFs, NANDs, etc.) rather than inverter-based ROs.

As described herein, to reproduce a stress mode scenario for the DR sensor, S_RO1, S_RO2, and S_RO3 can be enabled and can be submitted to accelerated aging for 80 hours at 135° C. with an elevated supply voltage (1.8V instead of 1.2V). One reason to effect accelerated aging is that it takes a long time (usually weeks/months) to observe aging effects under normal conditions. As described herein, the remaining three ROs were gated off and experienced no aging. In authentication mode, all of the ROs can be enabled and the temperature can be reduced to room temperature. With the 15 non-used test chips, the average frequency of ROs is about 7.5 Mhz. A timer unit (or timer, as illustrated in FIG. 9) can be utilized to regulate duty cycle, or working time, of the ROs in test chipset. The measurement temperature can be room temperature (e.g., about 25° C.). A frequency collection unit (represented as frequency collection in FIG. 9) can comprise a counter or any monitoring device suitable for measurement of count cycles in an RO.

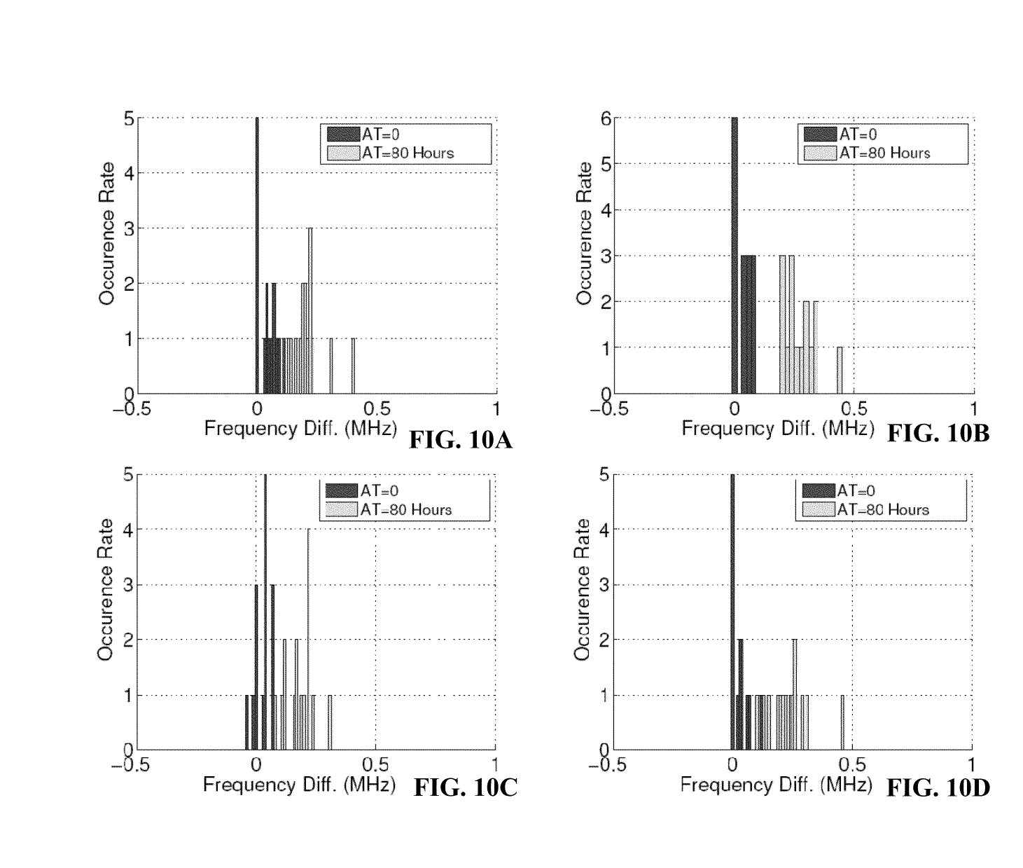

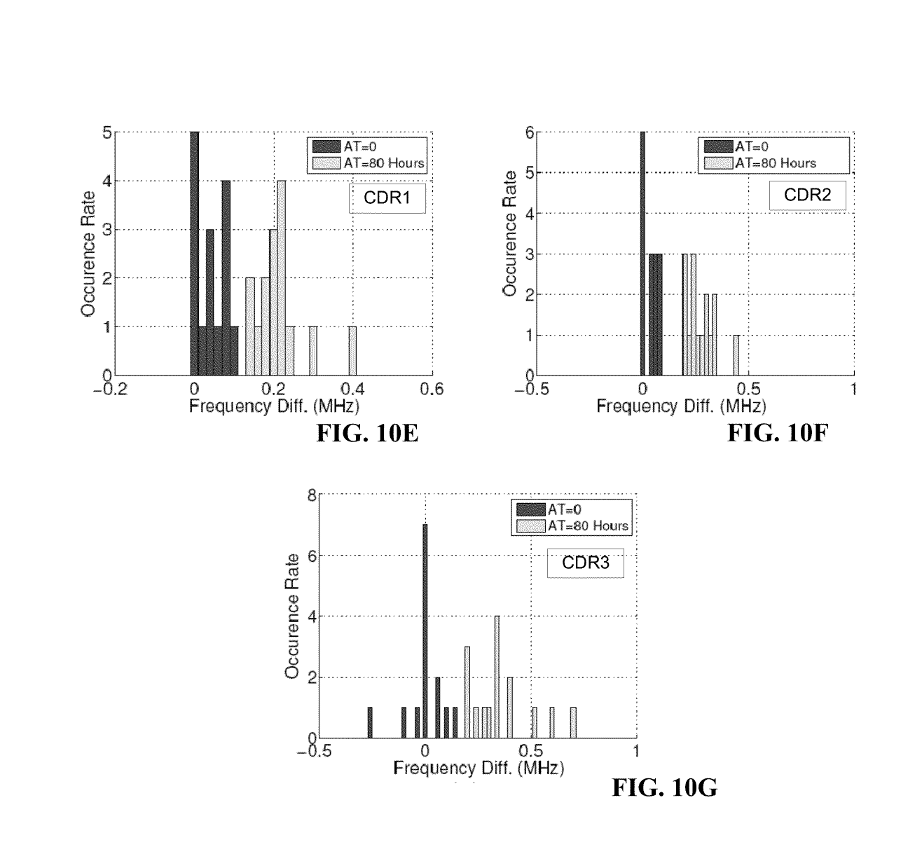

FIGS. 10(a)-10(d) illustrates experimental results of 4 out of 12 ring oscillators for 15 test chipsets. The rate of detection of recovered ICs that aged for about 80 hours using RO1 and RO2 can be about 100% for both ROs, whereas the rate of detection utilizing RO3 and RO4 can be about 86.7% and 80%, respectively. It should be appreciated that when detecting recovered ICs, rate of detection associated with each RO need not be 100%—having one RO that can detect all recovered ICs can be sufficiently effective for detection. It should also be appreciated that in response to increasing stress time, the detection rate using RO3 and RO4 can increase. Here, in one embodiment, the Stressed RO and Reference RO may not be placed in close proximity, thus creating large intra-die variations between them. However, in certain scenarios, for a DR sensor in accordance with the disclosure, it can be advantageous to place both ROs in a single module to reduce the variations between them.

FIGS. 10(e)-10(g) also illustrate experimental results in accordance with one or more aspects described herein. Data utilized to render FIG. 10(a) is the same as data utilized to render FIG. 10(e), and data utilized to render FIG. 10(b) is the same as data utilized to render FIG. 10(f). In one aspect, such results are obtained from CDR1, CDR2 and CDR3 described herein (see, e.g., foregoing Table) when configured in a test chipset board. In FIGS. 10(a)-10(g), red bars illustrate the frequency difference between Reference RO and Stressed RO in each CDR sensor at an initial time in which the test chipset can be deemed to comprise non-used IC(s). The yellow bars illustrate the frequency difference between the two ROs after 80 hours of aging.

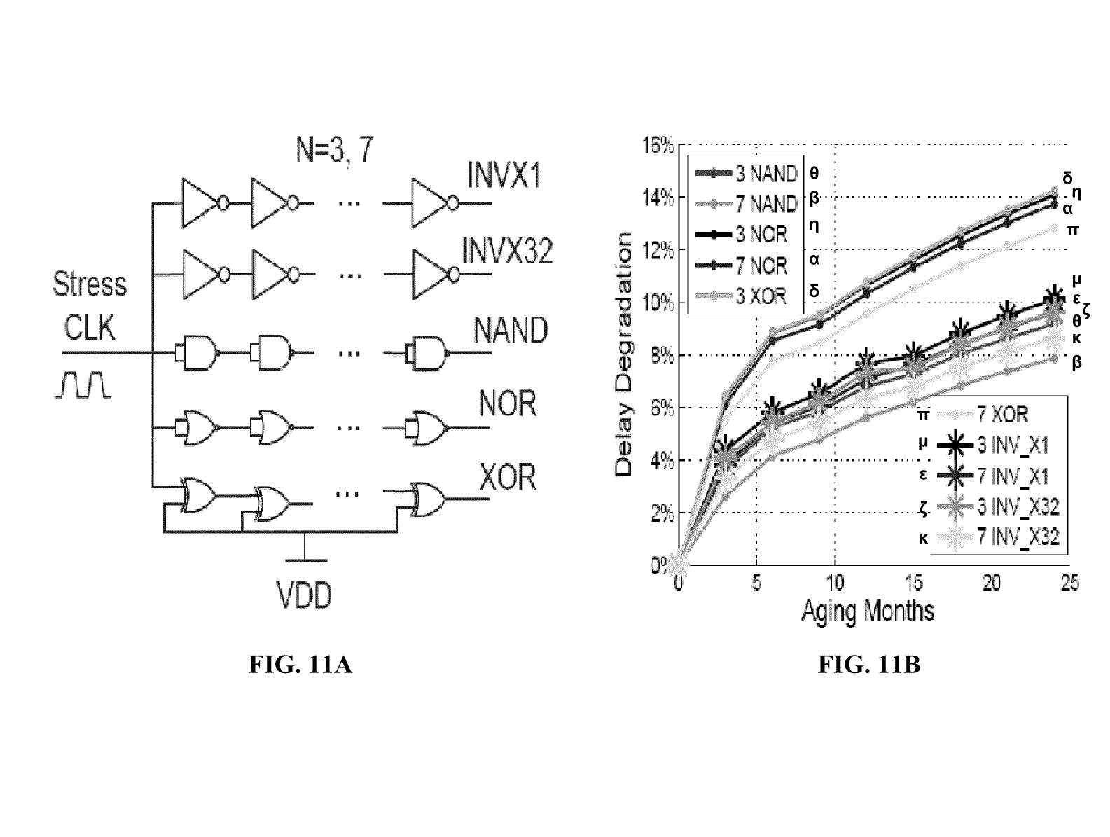

In view that a larger number of stages are utilized in these DR sensors compared to those used in our simulations, the mean frequency of the ROs in test chip and the frequency difference values are very much different from that in simulations. However, despite 201 gates being contained in these ROs, the detection rates of recovered ICs that aged 80 hours using CDR1, CDR2, and CDR3 are all still 100%, which demonstrates that the RO stage count in CDR sensor does not have a significant impact on the sensor's effectiveness in detecting recovered ICs. According to our detailed results, the average frequency degradation of the stressed ROs in CDR1, CDR2 and CDR3 (shown in FIGS. 10(e)-10(g)) is 3.2%, 4.0%, and 3.8%, respectively. Comparing FIG. 10(e) and FIG. 10(f), it can be appreciated that the frequency difference gap between non-used chipsets and aged chipsets in CDR2 can be larger than that in CDR1. Without wishing to be bound by theory and/or simulation, such results can be due to the fact that CDR sensors having HVT gates (e.g., CDR2) can be more effective than those with SVT gates (e.g., CDR1), which is also demonstrated in FIG. 1(c) through simulation results. Comparing detection rates in FIG. 10(f) using CDR2 (composed of HVT buffers) and FIG. 11(g) using CDR3 (composed of HVT NAND gates), it can be appreciated that the gates used in the RO can change the effectiveness of the probed CDR sensor. From the experimental results, it can be appreciated that at the initial time (e.g., time zero), for CDR1 and CDR2, the R_ROs can be faster than S_ROs, whereas such feature is absent for CDR3. Without wishing to be bound by theory or simulation, such discrepancy can be attributed to spatial variations that may exist between ROs that are not located in close proximity, which can render certain ROs faster than others.

### E. Exemplary Path-Delay Degradation Analysis

As described herein, when a chipset is utilized in the field, aging effects can cause one or more of the chipset parameters to shift over time. As an example, NBTI can increase the absolute value of PMOS threshold voltage, thus decreasing transistor current and increasing gate delay. As another example, HCl can create traps at the silicon substrate/gate dielectric interface, as well as dielectric bulk traps, and therefore degrades device characteristics including voltage threshold. While illustrated with silicon, the technique and related embodiments of the disclosure can be applied to chipsets formed on substantially any semiconducting material substrate. It should be appreciated that since recovered ICs may have been impacted by all of these aging effects, the path delay of recovered ICs can be different from those of non-used ICs.

To demonstrate the impact of aging on path delay in ICs, different gate chains were simulated using a 45 nm technology. As described herein, a simulation can be conducted with HSPICE MOSRA in combination with NBTI and/or HCl aging effects at a temperature of 25° C. Standard threshold voltage (SVT) INVX1, INVX32, NAND, NOR, and XOR gate chains of different lengths were simulated for up to 2 years of usage. FIG. 11(a) shows the basic structure of these gate chains, with all chains experiencing stress from a 500 MHz clock. Any other stress could be used in this simulation. FIG. 11(b) presents the delay degradation caused by 2 years of aging. From such figured, it can be appreciated that different gate chains age at slightly different rates, which depends on the structure of the gates. The XOR gate chain has the fastest aging rate amongst these chains. Comparing the delay degradation rates of the INVX1 and INVX32 chains, it can be appreciated that larger gates can age at a lower rate than smaller gates. Comparing 3-stage chains with 7-stage chains (chains using the same gates but different numbers of them), it can be appreciated that chains with fewer gates age slightly faster than those with more gates. In addition, the workload (input value and the switching frequency of each gate) also has a significant impact on the aging rate. ICs may be recovered from different used boards from different users who may have applied different workloads to the IC at different times. It is practically impossible to know the exact input vectors applied by the user.

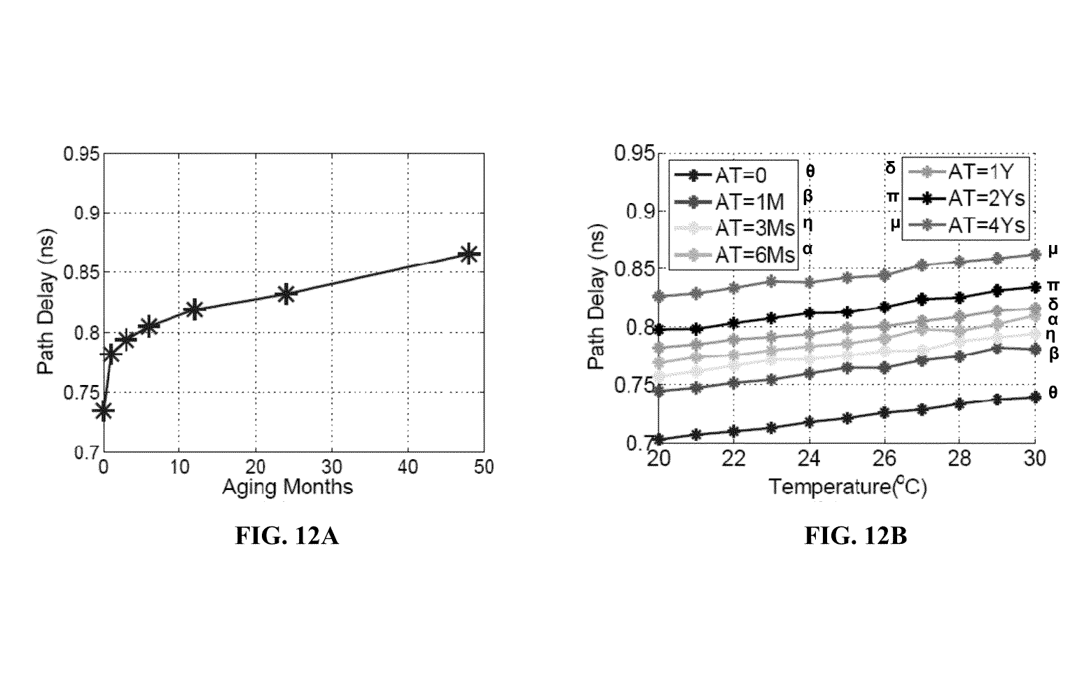

FIG. 12(a) illustrates the delay of a randomly selected critical path Pᵢ from the ISCAS′89 benchmark s38417 with stress from a random workload. The path was aged for 4 years with NBTI and HCl effects at room temperature. From such figure, it can be appreciated that the degradation of path Pᵢ used for 1 year is around 10%. Therefore, if there are no environmental or process variations, recovered ICs can be readily identified by measuring one path delay from the circuit. However, such variations have a significant impact on the path delay. FIG. 12(b) shows the delay of path Pᵢ under different temperatures at different aging times. In the figure, AT represents aging time, M represent months, and Y denotes years. From FIG. 12(b), it can be appreciated that the delay of path Pᵢ increases with temperature.

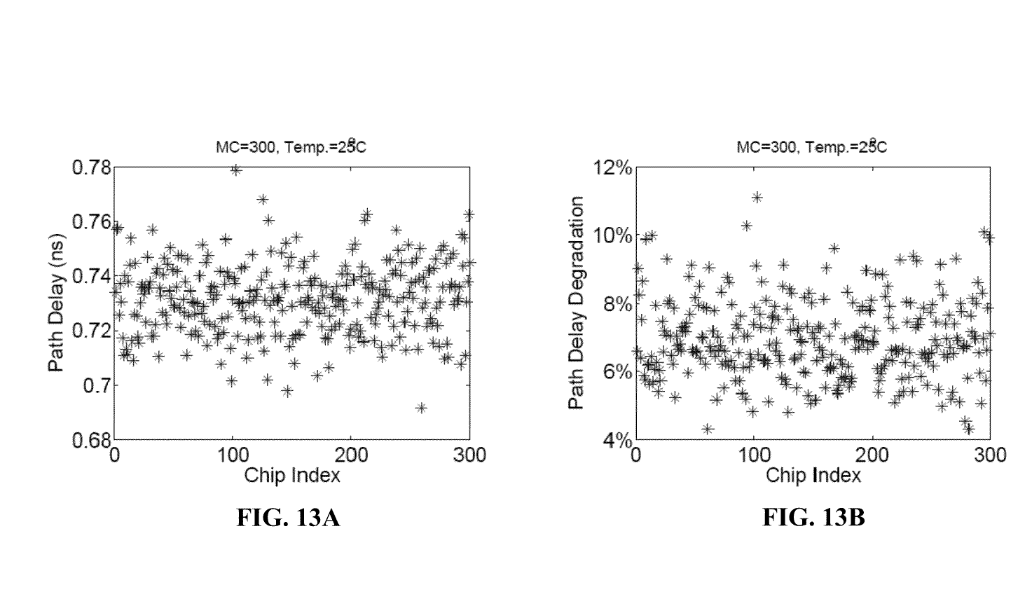

In one aspect, 300 Monte Carlo simulation results of Pᵢ at 25° C. are shown in FIG. 13(a), with 2% Tₒₓ, 5% Vₜₕ, and 5% L inter-die and 1% Tₒₓ, 5% Vₜₕ, and 5% L intra-die process variations. From such results, it can be appreciated that the path delay can vary around 12% due to process variations. In addition, process variations also have a significant impact on the aging rate of path delay, as shown in FIG. 13(b). The path delay degradation of the 300 ICs varied around 8% (4%˜12%) for one year of aging. Thus, path delay shifts caused by aging effects in recovered ICs must be separated from those caused by process variations in non-used ICs in scenarios in which path-delay fingerprints are utilized to identify recovered ICs.

### F. Path-Delay Fingerprinting

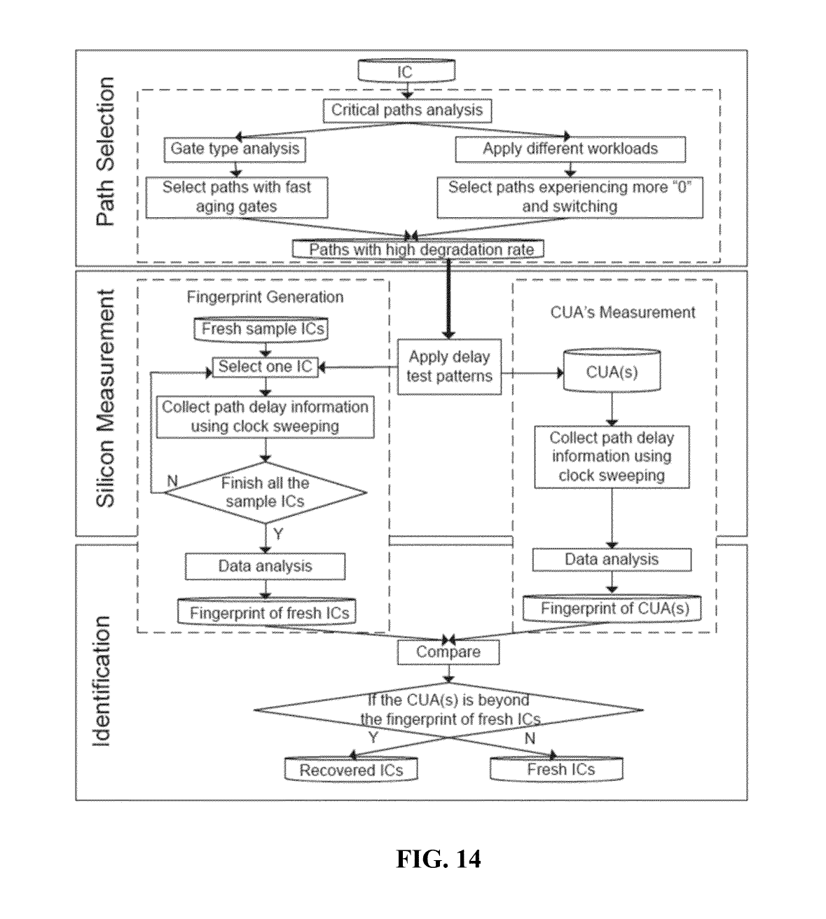

FIG. 14 illustrates an exemplary methodology for fingerprinting an IC and/or identifying recovered ICs using path-delay fingerprints and statistical analysis according to one or more aspects described herein. In one aspect, such methodology can comprise three process stages or steps. First, paths are simulated and selected according to their aging rate. Next, the delay information of these paths are measured by clock sweeping technique in a sample of non-used ICs and in any available CUAs. Finally, statistical analysis is used to decide whether the CUAs are recovered ICs or not.

Step 1. Path Selection:

Due to the large number of critical paths, in this step, paths that age at faster rates can be selected by analyzing the gate types in different paths and simulating the circuit with different workloads. Paths with higher rates of aging are preferred for fingerprint generation, since the differences in the delay of those paths between recovered ICs and non-used ICs can be substantially larger than the differences in paths which age slower. Fingerprints generated by fast-aging paths could help identify recovered ICs used for a shorter time. However, there are several parameters impacting the aging rate of a path, such as the type of gates composing the path and the workload. Based on these parameters, and the observations from simulation shown in FIGS. 11(b), the following rules can be provided to select paths: (i) paths with more fast-aging gates, such as NOR or XOR gates, can be selected, and (ii) paths that experience more zeros and more switching activity can be selected. More zeros in the path can increase the effect of NBTI on the PMOS transistors, and a high switching frequency can increase the HCl effects on gates, increasing the path delay degradation more significantly.

Paths with more fast-aging gates would be identified by analyzing the type of gates composing the paths. However, it is very difficult to identify paths that experience more zeros and more switching activity without knowing the specific workload. Therefore, different workloads (input combinations) can be applied to ICs during logic simulation. For each critical path, the average switching activity and the zeros it has experienced are calculated. Paths with more switching activity and zeros are then selected. These paths, along with those paths composed of the more fast-aging gates, are used to generate fingerprints to identify recovered ICs. The number of selected paths could be adjusted according to the design and its testing procedure. In certain simulations, the top 50 paths with fast-aging gates and the top 50 paths experiencing more switching activity and zeros can be selected.

Step 2. Silicon Measurement:

The second step in FIG. 14 is to collect the selected paths' delay from the ICs. A certain number of random non-used ICs can be selected as sample chips and are used to generate a fingerprint. The larger the number of sample ICs is, the wider of a range of process variations can be included in the fingerprint, thus reducing the probability that non-used ICs with large process variations can be identified as recovered ICs. Path delay information from the non-used ICs can measured by performing various test procedures on the ICs. Test patterns can be generated by automatic test pattern generation (ATPG) before fabrication to detect path delay faults. These patterns can be applied to all non-used ICs using clock sweeping techniques to measure the path delay of the targeted paths.

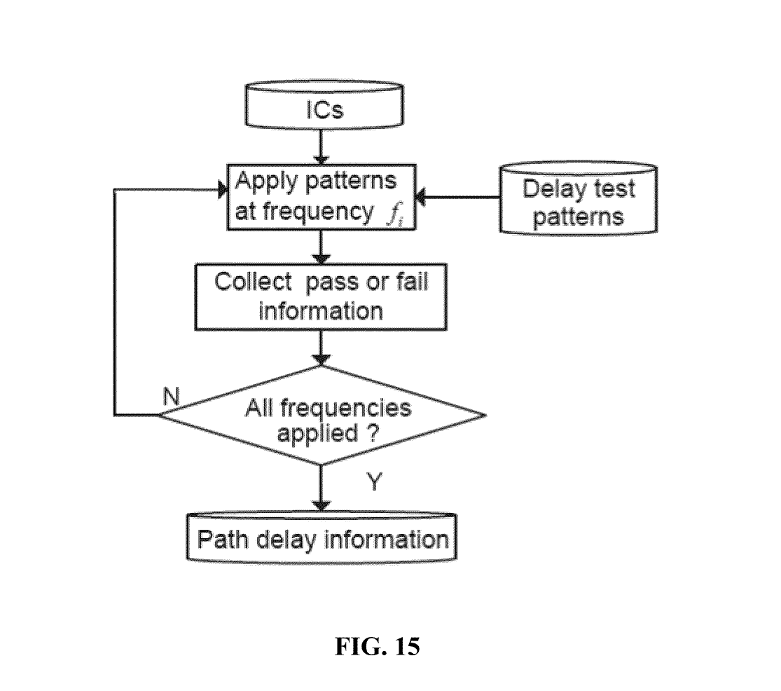

FIG. 15 illustrates the flow of the clock sweeping technique. The path delay test patterns are applied to ICs at different clock frequencies (f₁, f₂, . . . fₙ). Under different frequencies, the paths could pass or fail. If the time period tᵢ of the frequency fᵢ (tᵢ=¹/fᵢ) is larger than the path delay, the path can pass. Otherwise, the path will fail. When a path fails, the largest passing frequency will determine the path delay. The frequency step size (Δf=fᵢ−fᵢ₋₁, which depends on the tester, will determine the accuracy of path delay measurement results of silicon chips. For example, with the Ocelot ZFP tester, the main frequency can be 400 MHz and the frequency step can be 1 MHz. In certain simulations, a 5 MHz step around 1.0 GHz circuit frequency can be utilized for the clock sweeping procedure. Temperature in a measurement environment is to be kept suitably stable (e.g., temperature variations should be constrained). A suitably stable temperature can be achieved via a control unit in a manufacturing test environment.

Step 3. Identification:

Once the path delay in all sample chips are measured, statistical data analysis can be used to generate a fingerprint for non-used ICs. For a circuit under authentication (CUA) taken from the market, the same test patterns can be applied in a near-identical environment. The path delay information of the CUA can be processed by the same statistical data analysis methods. If the fingerprint of the CUA is outside of the range of the fingerprint of non-used ICs, there is a high probability that the CUA is a recovered IC. Otherwise, the CUA is likely a non-used IC. The longer the CUA has been used, the more aging effects it can have experienced, making it easier to identify.

In one aspect, without extra hardware circuitry embedded into the ICs, the disclosed recovered IC identification technique (e.g., methods, apparatus, systems, or combinations thereof) has negligible or absent area overhead and/or power overhead. In another aspect, the disclosed technique can provide negligible test time overhead during manufacturing test on a sample IC, in view that a few patterns can be applied several times at different frequencies. In yet another aspect, the disclosed recovered IC identification technique can be incorporated into a conventional IC design and/or test flow. In still another aspect, the disclosed technique can be resilient to tampering attacks since it can be inherently difficult for recyclers to mask the impact of aging on path-delay fingerprint(s) of a recovered IC during the recycling process.

### G. Exemplary Statistical Data Analysis

In certain embodiments, two statistical data analysis methods can be utilized to distinguish a recovered IC from a non-used IC and, thus, identify or detect the recovered IC. A first method can be an implementation of a simple outlier analysis (SOA), and the second method can be an implementation of a principal component analysis (PCA). When performing the SOA, a single path can be selected from a selected path set, and a path delay range in non-used ICs can be utilized to generate a fingerprint. Process variations of a CUA may or may not be the same as those within a plurality of non-used ICs that serves as a sampling of non-used ICs. The selected path delay of the CUA and sample ICs can follow the same distribution, which can render SOA effective in certain conditions. However, a single-path based analysis may not be effective, due to limited aging information collected during such analysis. In general, an implementation of the SOA can be expected to be effective in distinguishing recovered ICs that have been operated for a long time (e.g., 6 months, 12 months, 18 months, 24 months, 27 months, or the like) from non-used ICs with small process variations, as described herein.

TABLE II
PROCESS VARIATION RATES.

| | Inter-die | | | Intra-die | | |
|---|---|---|---|---|---|---|
| | Vₜₕ | L | Tₒₓ | Vₜₕ | L | Tₒₓ |
| PV0 | 3% | 3% | 2% | 2% | 2% | 1% |
| PV1 | 5% | 5% | 2% | 5% | 5% | 1% |
| PV2 | 8% | 8% | 2% | 7% | 7% | 2% |

To improve effectiveness of the disclosed technique for detection of IC recovery, PCA can be utilized to generate one or more fingerprints to identify recovered IC(s). The path delay information of all selected paths, which may have been measured by clock sweeping, can be processed by PCA. In certain implementations, the top 100 paths with faster aging rates can be selected to generate fingerprints. In one aspect, the first three components (e.g., first component (FC), second component (SC), third component (TC)) of PCA in all non-used ICs can be rendered (e.g., plotted), and a convex hull can be generated for the non-used ICs. In another aspect, path delay information associated with the CUA can be analyzed by a similar process (e.g., the same process) and rendered in an overlapping rendering area. In a scenario in which the CUA is outside of the convex hull generated by the non-used ICs, then it can be determined, with a high probability (e.g., probability greater than 80%), that the CUA is a recovered IC.

### H. Exemplary Results and Analysis

To assess effectiveness of the methodology for detecting, or identifying, a recovered IC according to aspects described herein, such methodology can be implemented using 45 nm technology. HSPICE MOSRA is used to simulate the effects of aging on the path delay of different benchmarks. The supply voltage of the 45 nm technology is 1.1V. Random workloads were applied to select paths in several ISCAS'89 benchmarks. Path delay information was collected using clock sweeping at different aging times. Different process and temperature variations can be simulated to analyze their impact on the efficacy of the exemplary methodology described herein for identification, or detection, of a recovered IC.

a) Exemplary Process and Temperature Analysis

Table II presents three exemplary process variations rates that can be utilized in one or more of the simulations described herein. In one aspect, switching from PV0 to PV2, inter-die and intra-die variations both increase. In another aspect, PV1 represents a realistic rate of process variations that can be available in a foundry. In certain implementations, four sets of Monte Carlo simulation (MCS) can be performed utilizing different ranges of variations, as illustrated in Table III. For each set of MCS, in one aspect, 300 Monte Carlo simulations can be performed to generate 300 chips. During such simulations, in one aspect, the aging effects of NBTI and HCl can be simulated with random stress for the benchmark s38417. From the top 500 critical paths, the paths P₁, P₂, . . . , P₅₀ with fast-aging gates and the paths P₅₁, P₅₂, . . . , P₁₀₀ with more zeros and higher switching activities were selected to generate fingerprints.

TABLE III
SIMULATION SETUP.

| Experiments | Process Variations | Temperature |
|---|---|---|
| MCS1 | PV0 | 25° C. |
| MCS2 | PV1 | 25° C. |
| MCS3 | PV2 | 25° C. |
| MCS4 | PV1 | 25° C. ± 10° C. |

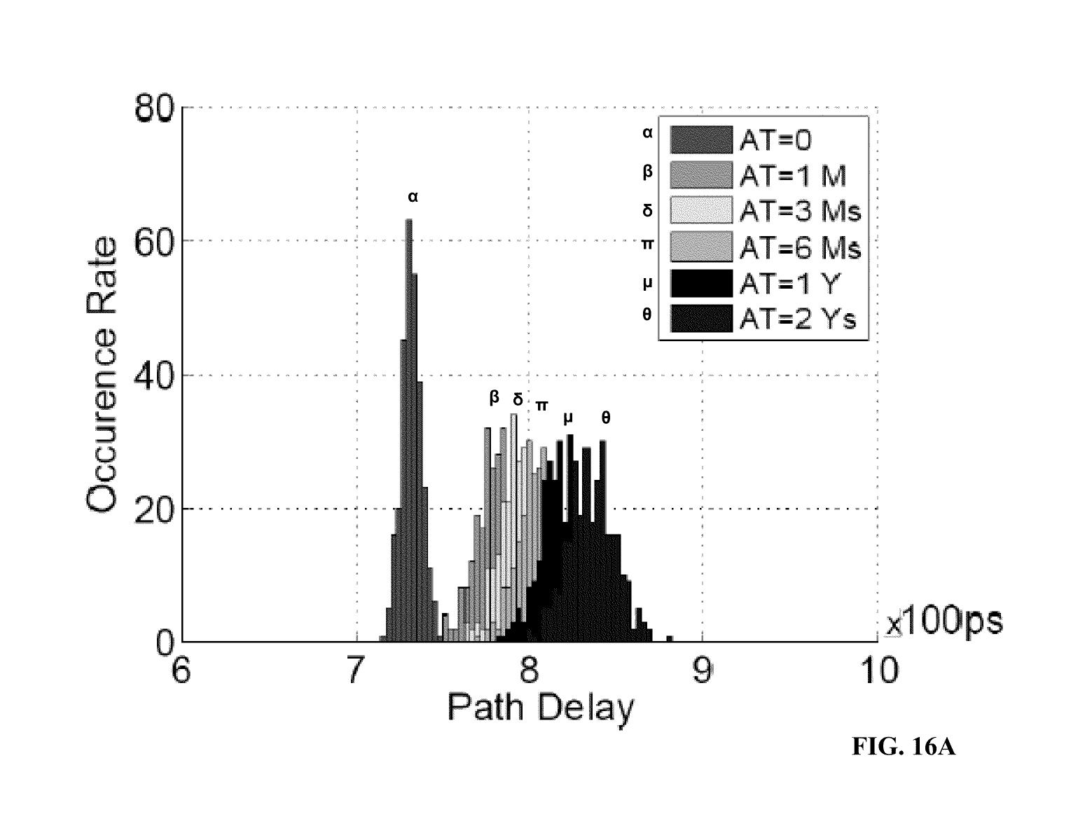

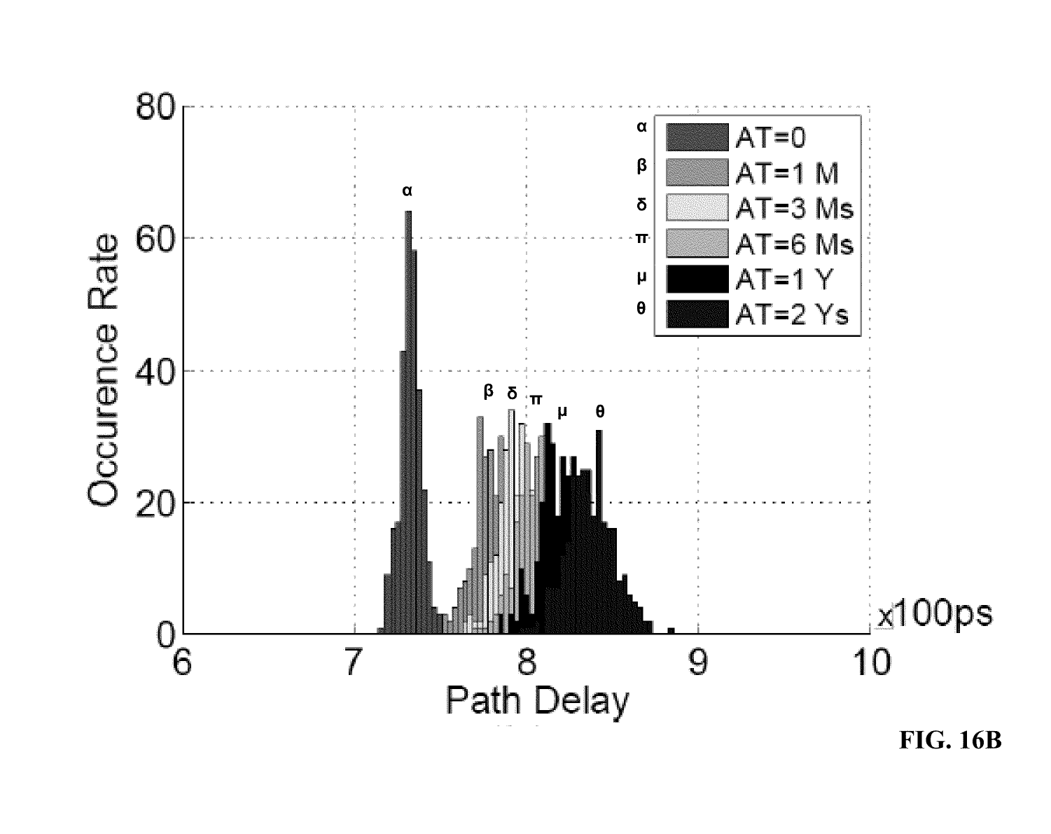

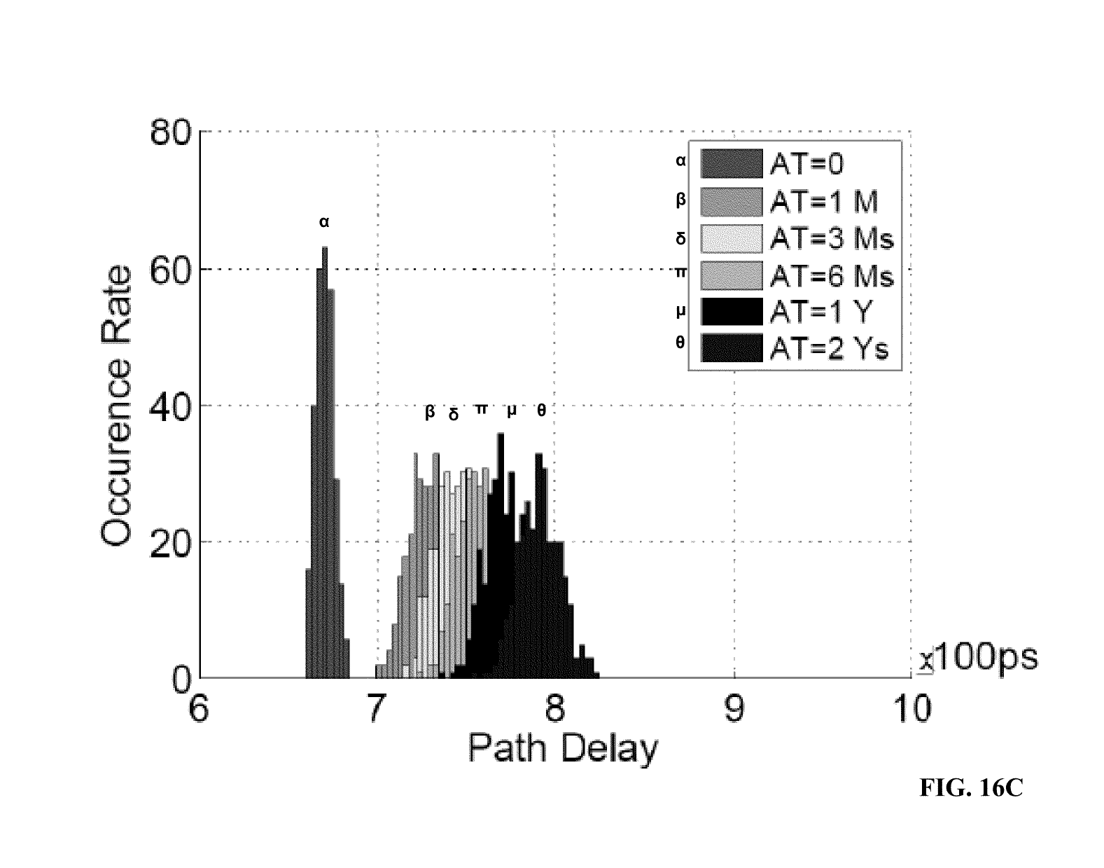

Analysis using SOA: First, 300 Monte Carlo simulations were run using PV0 at 25° C. (MCS1). The maximum aging time is 2 years. Here, SOA was used to process the path delay information. 3 paths (P₁, P₂ and P₅₁) were selected to show the results of SOA. FIGS. 16(a), 16(b), and 16(c) illustrate path delay distribution of the 3 paths from 300 ICs used for different aging times. For each path, the range of the path delay at AT=‘0’ is the fingerprint of the non-used ICs. If the path delay of the CUA is out of that range, there is a high probability that IC is a recovered one. From the path delay distributions illustrated in such figures, it can be appreciated that the delay distribution of each path in recovered ICs can shift to the right, relative to the distribution of delays in non-used ICs. Without wishing to be bound by theory and/or simulation, this is because path delay in recovered ICs can increase due to aging. The longer the ICs have been used, the more path delay degradation they may have experienced. In addition, it can be appreciated that the path delay variation increases as the aging time increases. Without wishing to be bound by theory and/or simulation, it is believed that ICs with different process variations age at different speeds, and the path delay variations increase the aging time increases.

FIG. 16(a) illustrates the distribution of path P₁'s delay, and it can be appreciated that the smallest delay of P₁ in recovered ICs used for 1 month is smaller than the largest delay in non-used ICs. Therefore, the detection rate of recovered ICs used for 1 month can be less than 100% (98.3%) when the fingerprint generated by SOA from path Pᵢ is utilized. However, the detection rate of recovered ICs used for 3 months or longer is 100%, which demonstrates that it is easier to detect recovered ICs that have been used for longer amounts of time. If path P₂ is utilized to detect recovered ICs, the detection rate of ICs used for 1 month (95.7%) is slightly less than when using path Pᵢ. However, if path P₅₁ is used, which has the fastest aging rate among the 100 paths, the detection rate is 100% even if the ICs are only used for one month. P₅₁ is the most effective path for identifying recovered ICs in this benchmark. From the foregoing analysis, it can be appreciated that different paths generate different fingerprints due to their different aging speeds, which makes SOA slightly less effective.

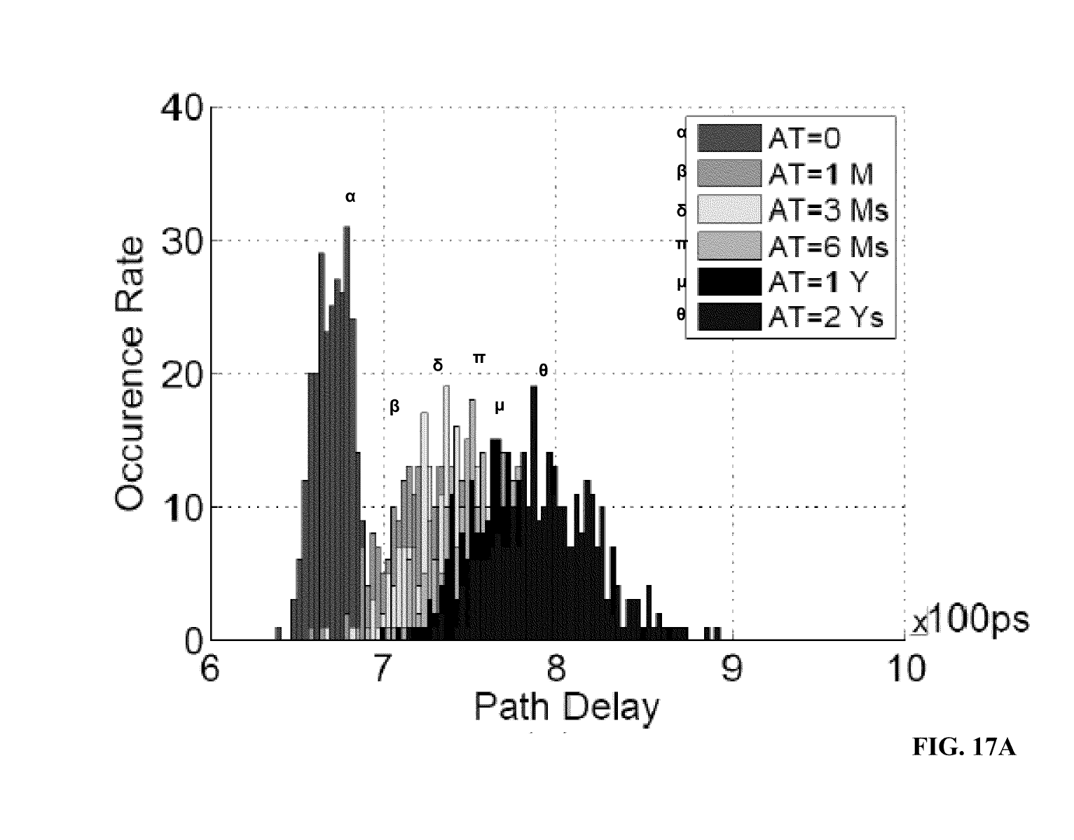

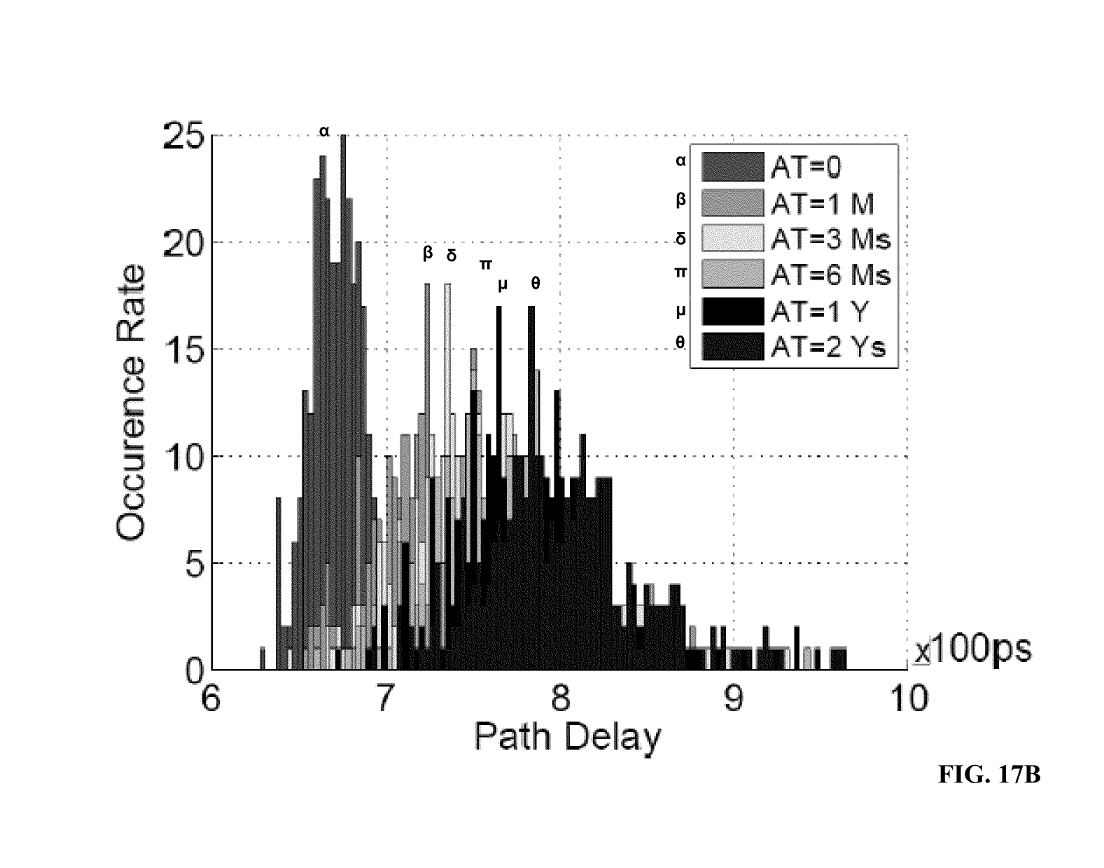

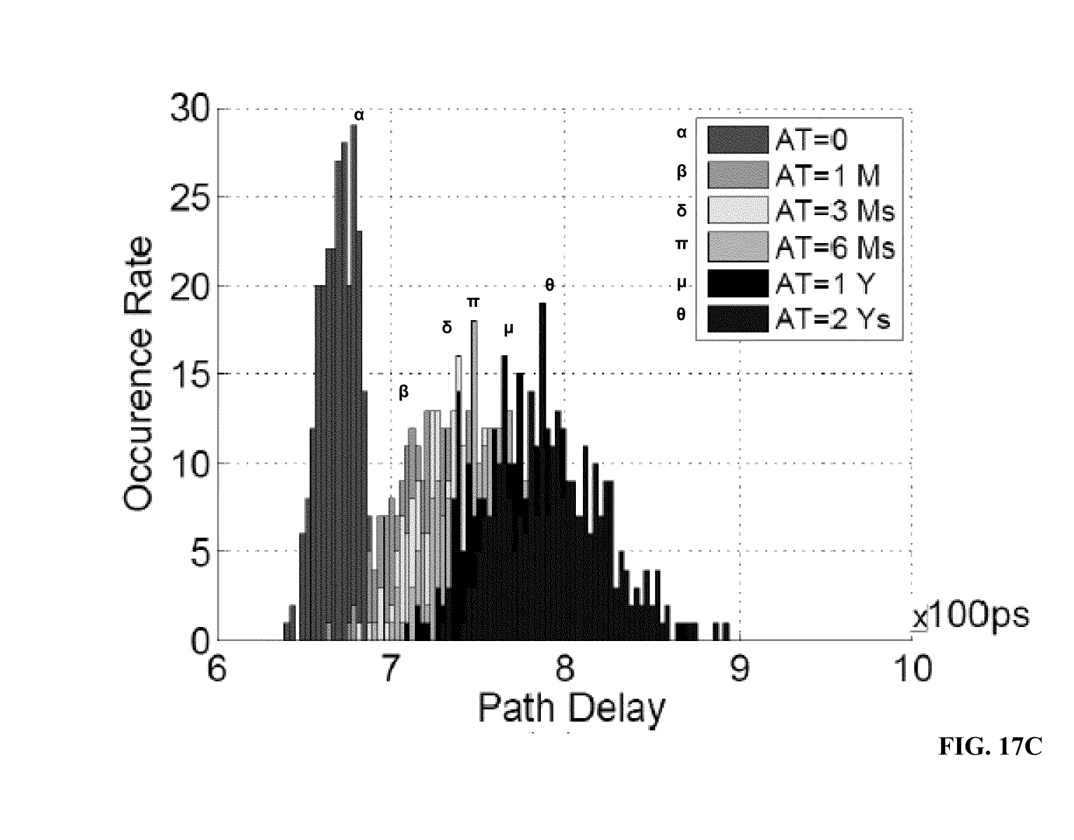

FIGS. 17(a) and 17(b) illustrate the delay distribution of path P₅₁ across 300 Monte Carlo simulations at a temperature of 25° C. with PV1 (MCS2) and PV2 (MCS3). FIGS. 16(c), 17(a), and 17(b) present the delay distribution of the same path (P₅₁) in ICs with different process variations. By comparing these figures, it can be appreciated that the larger the process variations are, the larger the path delay variations in non-used ICs may be, which makes it more difficult to detect recovered ICs. Even when using the most effective path P₅₁, the detection rates of ICs used for 1 month with PV1 and PV2 drop from 100% with PV0 to 78.0% and 50.7%, respectively. A 100% detection rate could be achieved if the ICs were used for 1 year or longer with PV1, or longer than 2 years with PV2.

In one implementation, 300 Monte Carlo simulations were also run with ±10° C. temperature variation and PV1 (MCS4) as shown in FIG. 17(c). It shows the delay distribution of path P₅₁ and the detection rate of ICs used for 1 month using it is 67.7%. Comparing FIG. 17(c) and FIG. 17(a), it can be appreciated that the larger the temperature variation is, the larger the path delay variation is, which makes it more difficult to detect recovered ICs.

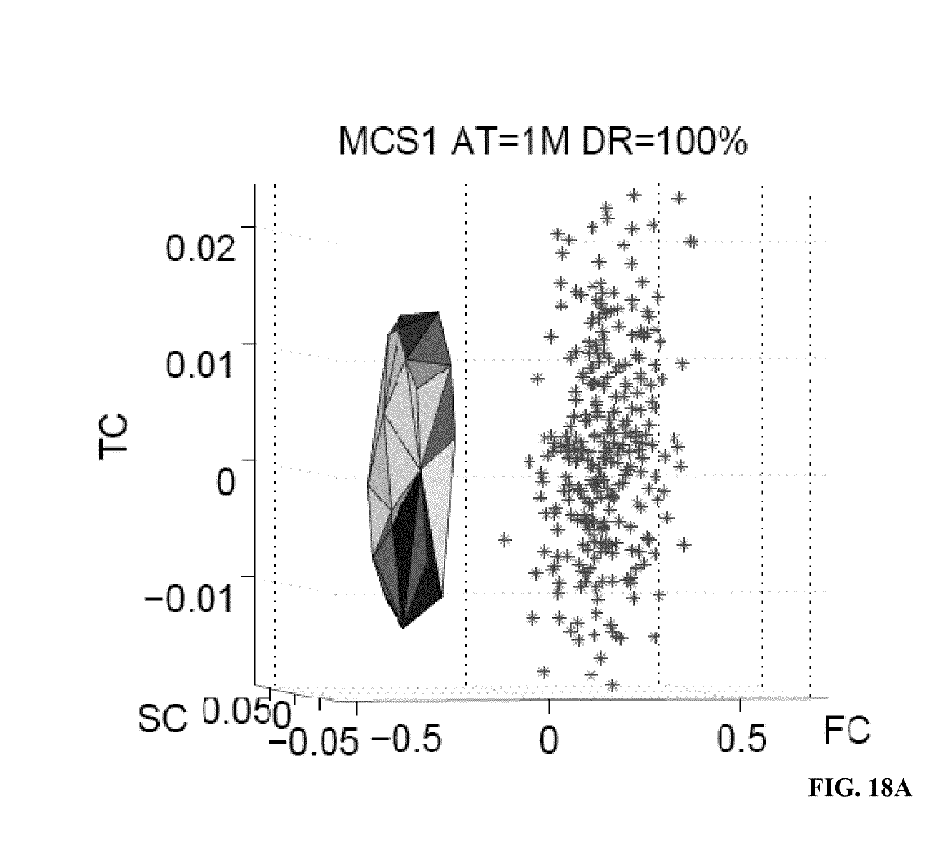

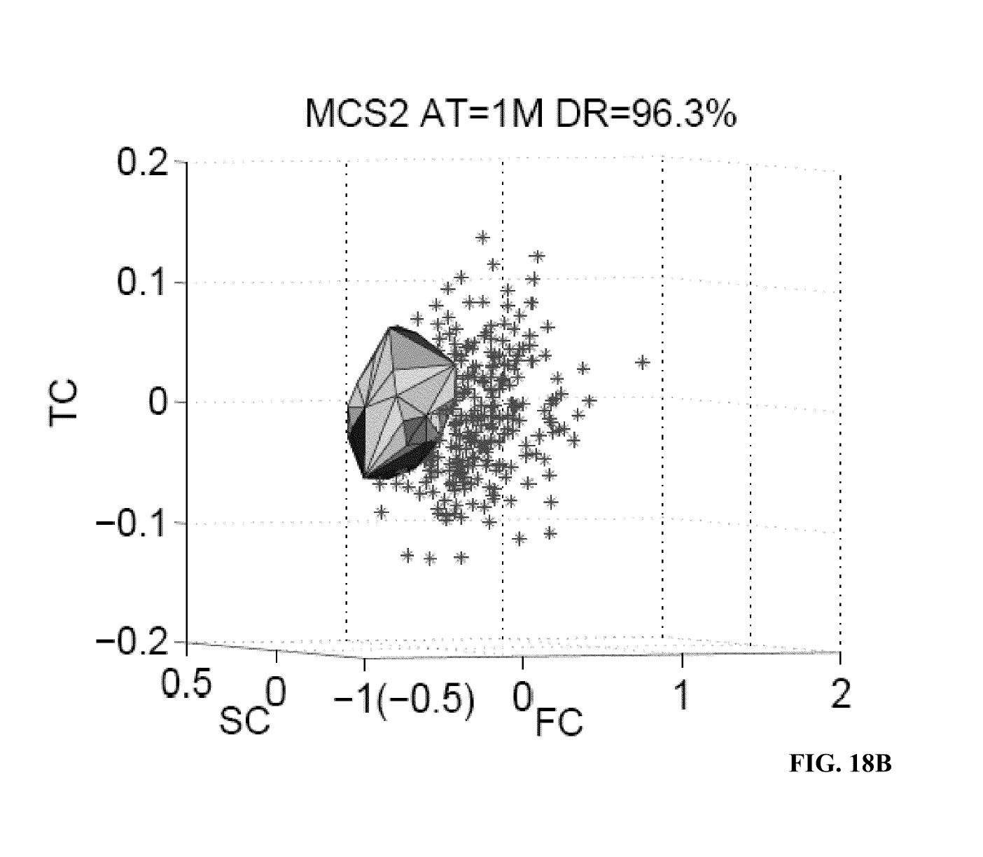

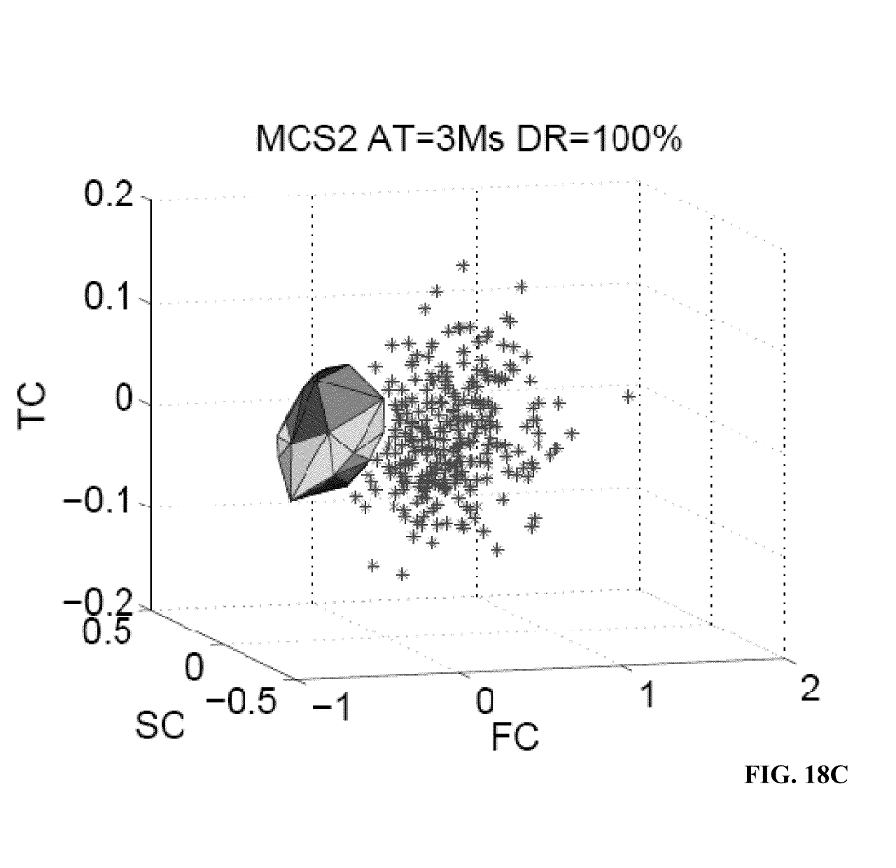

Analysis using PCA: A similar analysis is done using PCA for different PVs in MCS. FIG. 18(a) shows the PCA results of the 100 paths in s38417 with 300 chips in MCS1. FC denotes the first component from PCA, SC represents the second component, TC is the third component, and DR denotes the detection rate. The convex is built up from non-used IC data, and represents the fingerprint for non-used ICs. The red asterisks represent chips used for 1 month. From the figure, it can be appreciated that the 300 used ICs were completely separated from the signature of the non-used ICs. Thus, the detection rate using path delay fingerprints generated by PCA is 100% for recovered ICs used for 1 month. For a recovered IC used for a longer time, the detection rate also can be about 100%.

The path delay information from the remaining three sets of MCSs were also analyzed by PCA. FIG. 18(b) illustrates the analysis results of non-fresh chips and recovered ICs used for one (1) month in MCS2. From the 3-dimensional figure, it can be appreciated that some of the recovered ICs are close to the fingerprint of non-used ICs. The detection rate is 96.3%, which is much higher than using SOA. Comparing FIGS. 18(a) and 18(b), it can be appreciated that (i) the convex hull built up from non-used ICs in MCS2 is much larger than that in MCS1 (note that the convex hull in MCS1 looks larger than MCS2 due to its small scale of axes), and (ii) the recovered ICs in MCS2 are closer to non-used ICs than those in MCS1, which makes the detection rate in MCS2 less than that in MCS1. The path delay information of 300 ICs used for 3 months in MCS2 were also processed, and the results are shown in FIG. 18(c). Comparing FIGS. 18(b) and 18(c), it can be appreciated that the longer the chips have been used, the farther they can be from the fingerprint of non-used ICs. The detection rate of recovered ICs used for 3 months or longer with PV1 at 25° C. is 100%.

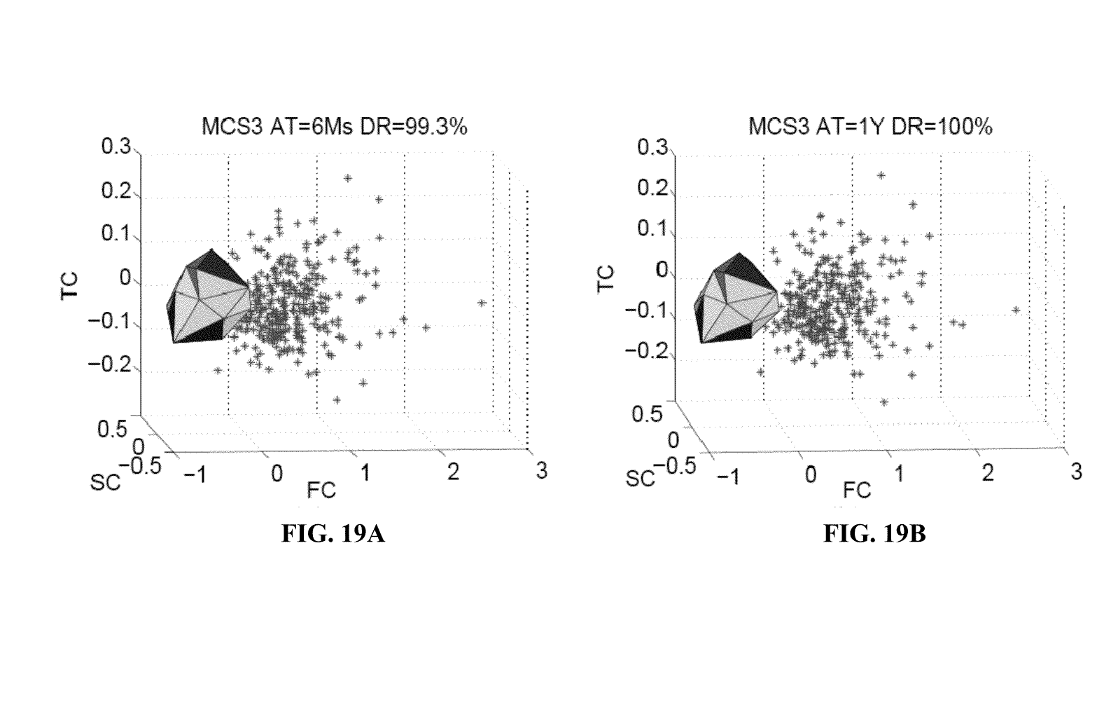

FIG. 19 illustrates the PCA results of ICs in MCS3 with PV2 in accordance with one or more aspects described herein. The detection rate of recovered ICs used for one month, 3 months, 6 months, and 1 year are 72.7%, 89.3%, 99.3%, and 100%, respectively. The figures of PCA results of recovered ICs used for 1 month and 3 months are not shown here since the detection rates are so far from 100%. FIGS. 19(a) and 19(b) illustrate the non-used ICs' fingerprint and the recovered ICs used for 6 months and 1 year, respectively. The recovered ICs used for longer times are easier to detect, as seen by comparing FIGS. 19(a) and 19(b). In another aspect, ICs in MCS1, MCS2 and MCS3 were simulated at the same temperature but under different process variation rates as shown in Table II. Comparing the detection rates in these simulations, it can be appreciated that it is more difficult to detect recovered ICs which have higher levels of process variations. The 99.3% detection rate of ICs used for 6 months and the 100% detection rate of ICs used for 1 year in MCS3 shows the efficacy of the disclosed technique. In certain scenarios, variation PV2 can be a significantly high variation compared to what may expected in certain practical scenarios (e.g., PV1).

TABLE IV
RECOVERED IC DETECTION RATES FOR s38417.

| | SOA | | | | PCA | | | |
|---|---|---|---|---|---|---|---|---|
| | 1 M | 3 M | 6 M | 1 Y | 1 M | 3 M | 6 M | 1 Y |
| MCS1 | 100% | 100% | 100% | 100% | 100% | 100% | 100% | 100% |
| MCS2 | 78% | 96.7% | 99.7% | 100% | 96.3% | 100% | 100% | 100% |
| MCS3 | 50.7% | 76.3% | 85.3% | 95.6% | 72.7% | 89.3% | 99.3% | 100% |
| MCS4 | 67.7% | 93.3% | 98% | 100% | 90.6% | 100% | 100% | 100% |

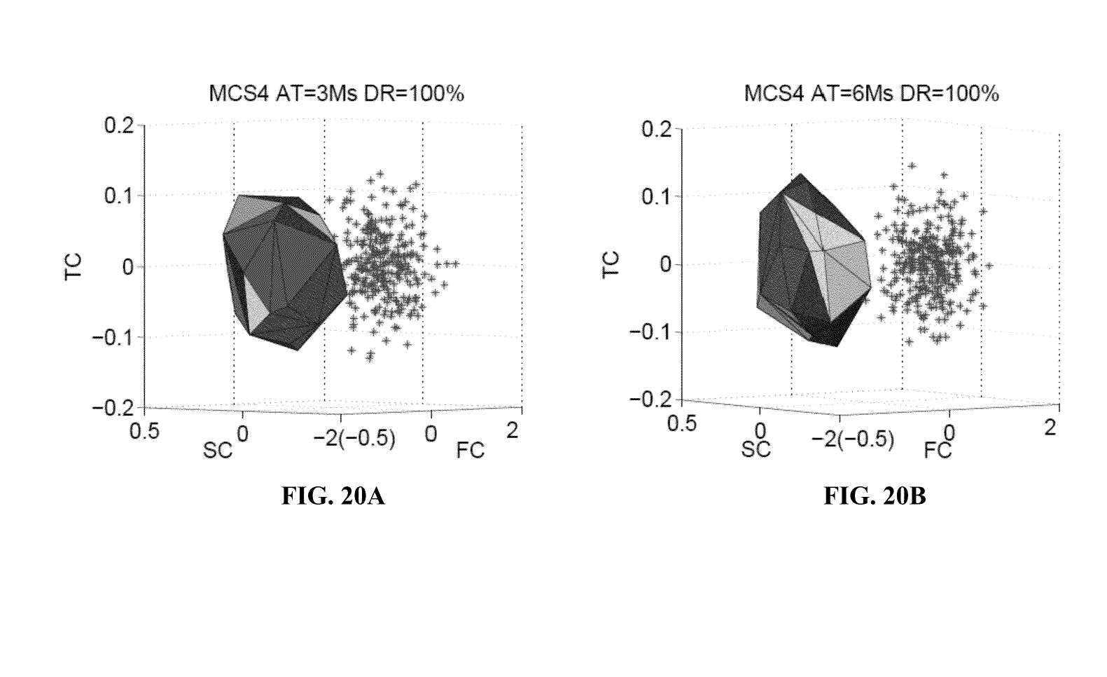

The detection rate of ICs used for 1 month, 3 months, and 6 months in MCS4 with ±10° C. temperature variation are 90.6%, 100%, and 100%, respectively. In one aspect, the fingerprint of non-used ICs and the detected recovered ICs used for 3 months and 6 months are illustrated in FIG. 20. Comparing FIGS. 20(a) and 18(c), it can be appreciated that the recovered ICs used for 3 months in MCS4 are closer to the fingerprint than recovered ICs used for 3 months in MCS2. Without wishing to be bound by theory or simulation, this phenomenon can demonstrate that temperature variations can increase the path delay variations in non-used ICs and make it more difficult to detect recovered ICs. However, the 100% detection rates of ICs used for 6 months in MCS4 demonstrates the efficacy of the disclosed methodology when process and temperature variations can be incorporated in the disclosed technique.

FIGS. 17 through 20 presented some detailed results relating to using this technique on s38417 with SOA and PCA. Table IV, however, illustrates such results in addition to some other results obtained using both statistical analysis approaches. It can be readily appreciated that PCA can be more effective than SOA at identifying ICs used for shorter periods of time.

b) Exemplary Benchmark Analysis

In addition to s38417, the ISCAS'89 benchmarks s9234 and s13027 were also simulated to demonstrate the efficiency of this technique on different designs. The process variation and temperature variation rates used in MCS4 were applied to these two benchmarks. The aging stress causing NBTI and HCl degradation in these benchmarks comes from random workloads. In one aspect, 300 MCS were run for each benchmark for a maximum 2 years of aging. The path selection method was also applied to these benchmarks, and 100 paths from each benchmark were used to run statistical data analysis using PCA.

Table V illustrates the recovered IC detection rate for all three benchmarks under MCS4 for up to a year of aging. The detection rate for ICs used for 3 months in the benchmarks s9234 and s13207 is 100%, which matches the results obtained from s38417. These exemplary results convey that the disclosed exemplary method for detection of a recovered IC using a path delay fingerprint generated by PCA can be effective, even in different designs that have large process and temperature variations.

TABLE V
RECOVERED IC DETETION RATES - BENCHMARK
COMPARISON UNDER MCS4.

| Benchmark | 1 M | 3 M | 6 M | 1 Y |
|---|---|---|---|---|
| s9234 | 88% | 100% | 100% | 100% |
| s13207 | 89.6% | 100% | 100% | 100% |
| s38417 | 90.6% | 100% | 100% | 100% |

### I. Exemplary Identification Utilizing Leakage Current Fingerprint

There can be four main sources of leakage current in a CMOS transistor: reverse-biased junction leakage current; gate-induced drain leakage; gate direct-tunneling leakage; and sub-threshold (e.g., weak inversion) leakage. In one aspect, the sub-threshold leakage current, I_{SUB}, can be substantially larger than the other leakage current components. In certain embodiments, I_{SUB} (shown in Eq. (1)) can be utilized to represent leakage current:

$${I}_{SUB} = \frac{W}{L} μ {v}_{T}^{2} {C}_{sth} {e}^{\frac{{v}_{GS} - {v}_{th} + {nv}_{DS}}{{nv}_{T}}} ( 1 - {e}^{- \frac{- {V}_{DS}}{{v}_{T}}} ) \qquad ( 1 )$$

Here, W and L represent width and length of a transistor; μ represents carrier mobility; vT=kT/q can be the thermal voltage at temperature T; Cₛₜₕ denotes the summation of the depletion region capacitance and the interface trap capacitance per unit area of the MOS gate; and h represents the drain-induced barrier lowering coefficient. The parameter n (a real number) represents the slope shape factor. From Eq. (1), it can be appreciated that the leakage current I_{SUB} is a function of the temperature, supply voltage, device size, and process parameters. Among such parameters, threshold voltage (Vth) can affect the value of leakage current significantly. In one aspect, in view that aging effects can change a threshold voltage of the I_{SUB}, the leakage current can be significantly impacted.

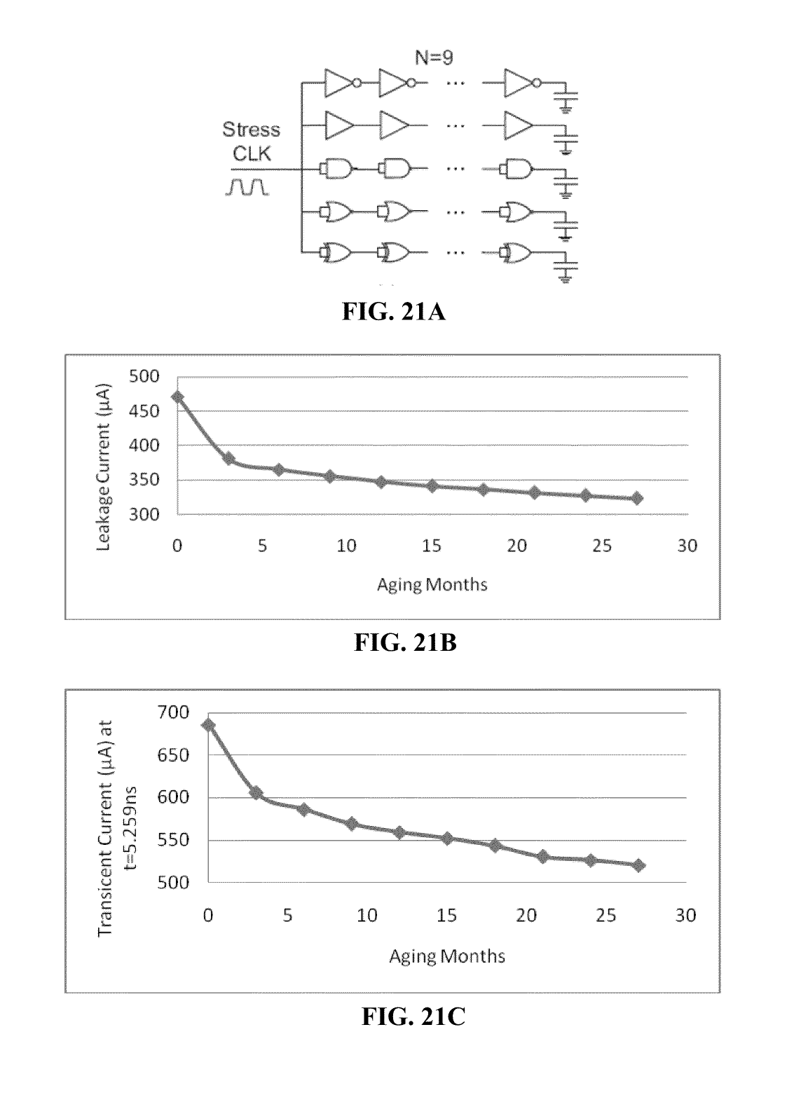

In one embodiment, to assess the effects of aging on leakage current, a circuit can be constructed and simulated using Synopsys 90 nm technology. In one aspect, a simulation can be performed using HSPICE MOSRA with combined NBTI and HCl aging effects at room temperature (25° C.). In one aspect, the circuit can be small and can comprise five 9-stage chains having different gates, as shown in FIG. 21(a). In another aspect, the circuit can be submitted to a DC stress (e.g., zero-frequency stress). FIG. 21(b) illustrates the leakage current degradation of the circuit after being submitted to such stress for under 27 months. From FIG. 21(b), it can be appreciated that aging effects present a significant impact on leakage current, resulting in almost 30% degradation.

Since recovered ICs may have been used for a long time before they were re-sold into the market, and thus have experienced aging, the leakage current of recovered ICs will be different from the leakage current of non-used ICs. Therefore, recovered ICs can be detected utilizing a leakage current signature. It should be appreciated that there are several parameters impacting the leakage current of a chipset, such as process variations and temperature. Accordingly, in one aspect, it can be necessary to separate the effects of process and temperature variations, for example, from effects of aging on leakage current.

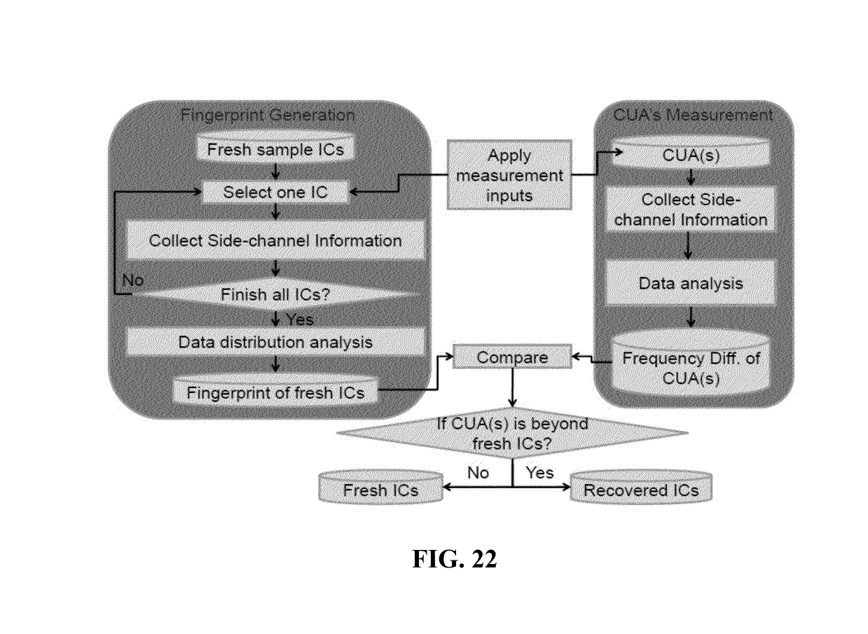

A general measurement and signature analysis flow is proposed in FIG. 22 illustrates an exemplary methodology for detecting IC recovery in accordance with one or more aspects of the disclosure. As illustrated, the exemplary methodology can comprise a method for fingerprint generation, the method comprising selecting a non-used IC from a set of one or more non-used ICs, the set can be utilized as samples representing the impact of process variations. For the selected non-used IC, side-channel information can be collected in response to application of measurement inputs into the selected non-used IC. In certain embodiments, as illustrated, side-channel information can be collected for each non-used IC in the set of one or more ICs. In another aspect, statistics data analysis of side-channel information can be generated. Such information can permit identification of one or more circuits under authentication (CUA). It should be appreciated that the side-channel information can comprise path delay, leakage current, and transient current. In one embodiment, leakage current can be utilized to generate a fingerprint for non-used IC(s). In addition or in the alternative, a plurality of IC parameters can be used to identify recovered ICs using the exemplary methodology described herein. The plurality of IC parameters can comprise the relationship between the maximum frequency and dynamic current in the integrated circuit.

### J. Exemplary Identification Using Transient Current Fingerprint

An exemplary methodology for detecting recovered ICs using switching current can be similar to the exemplary methodology illustrated in FIG. 22, which exploits leakage current. One difference between such methodologies can be that the signature of the ICs can be generated using switching current instead of leakage current. It should be appreciated that the reason that switching current can be utilized to detect recovered ICs is that the switching current can be affected by threshold voltage changes, such changes originating from aging. In one implementation, the exemplary IC circuit illustrated in FIG. 21(a) can be simulated to assess the impact of aging on switching current under similar (e.g., the same) stress conditions as in other simulations described herein. FIG. 21(c) illustrates degradation of switching current (e.g., as measured at 5.259 ns) of the benchmark under a 27-month stress. From FIG. 21(c), it can be appreciated that the switching current can degrades significantly due to aging effects. Therefore, switching current can be utilized to create a fingerprint for detection of a recovered ICs. In one aspect, the exemplary methodology shown in FIG. 22 can be utilized to separate the impact of aging on switching current from other circuit parameters.

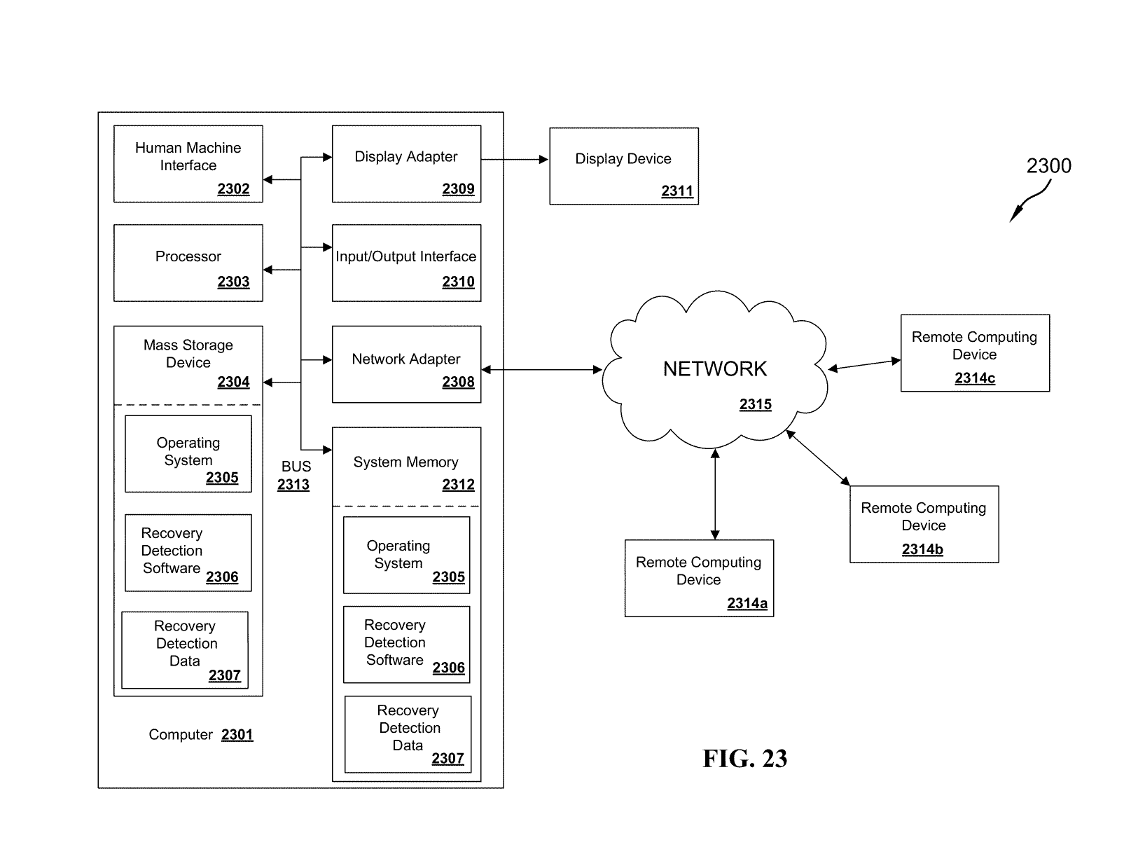

FIG. 23 illustrates a block diagram of an exemplary computing environment 2300 that enables various features of the subject disclosure and performance (e.g., execution) of the various methods disclosed herein. Exemplary computing environment 2300 is only an example of the several computing environments suitable for implementation of the various aspects of the subject disclosure and is not intended to suggest any limitation as to the scope of use or functionality of operating environment architecture. Neither should the computing environment be interpreted as having any dependency or requirement relating to any one or combination of components or units illustrated in the exemplary computing environment.

The various embodiments of the subject disclosure can be operational with numerous other general purpose or special purpose computing system environments or configurations. Examples of well known computing systems, environments, and/or configurations that can be suitable for use with the systems and methods comprise, but are not limited to, personal computers, server computers, laptop devices or handheld devices, and multiprocessor systems. Additional examples comprise wearable devices, mobile devices, set top boxes, programmable consumer electronics, network PCs, minicomputers, mainframe computers, distributed computing environments that comprise any of the above systems or devices, and the like.

The processing effected in the disclosed systems and methods can be performed by software components. The disclosed systems and methods can be described in the general context of computer-executable instructions, such as program modules, being executed by one or more computers or other computing devices. Generally, program modules comprise computer code, routines, programs, objects, components, data structures, etc. that perform particular tasks or implement particular abstract data types. The disclosed methods also can be practiced in grid-based and distributed computing environments where tasks are performed by remote processing devices that are linked through a communications network. In a distributed computing environment, program modules can be located in both local and remote computer storage media including memory storage devices.

Further, one skilled in the art will appreciate that the systems and methods disclosed herein can be implemented via a general-purpose computing device in the form of a computer 2301. The components of the computer 2301 can comprise one or more processors 2303, or processing units 2303, a system memory 2312, and a system bus 2313 that couples various system components including the processor 2303 to the system memory 2312. In the case of multiple processing units 2303, the system can utilize parallel computing. In certain implementations, computer 2301 can embody or can comprise one or more of analysis component 410. In other implementations, computer 2301 embodies a design platform for performing various simulations.

In general, a processor 2303 or a processing unit 2303 refers to any computing processing unit or processing device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally or alternatively, a processor 2303 or processing unit 2303 can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Processors or processing units referred to herein can exploit nano-scale architectures such as, molecular and quantum-dot based transistors, switches and gates, in order to optimize space usage or enhance performance of the computing devices that can implement the various aspects of the subject disclosure. Processor 2303 or processing unit 2303 also can be implemented as a combination of computing processing units.

The system bus 2313 represents one or more of several possible types of bus structures, including a memory bus or memory controller, a peripheral bus, an accelerated graphics port, and a processor or local bus using any of a variety of bus architectures. By way of example, such architectures can comprise an Industry Standard Architecture (ISA) bus, a Micro Channel Architecture (MCA) bus, an Enhanced ISA (EISA) bus, a Video Electronics Standards Association (VESA) local bus, an Accelerated Graphics Port (AGP) bus, and a Peripheral Component Interconnects (PCI), a PCI-Express bus, a Personal Computer Memory Card Industry Association (PCMCIA), Universal Serial Bus (USB) and the like. The bus 2313, and all buses specified in this description also can be implemented over a wired or wireless network connection and each of the subsystems, including the processor 2303, a mass storage device 2304, an operating system 2305, recovery detection software 2306, IC recovery detection data 2307 (also referred to as recovery detection data 2307), a network adapter 2308, system memory 2312, an Input/Output Interface 2310, a display adapter 2309, a display device 2311, and a human machine interface 2302, can be contained within one or more remote computing devices 2314a,b,c at physically separate locations, connected through buses of this form, in effect implementing a fully distributed system. In one aspect, recovery detection software 2306 can comprise various components or units that implement analysis (e.g., simple outlier analysis, PCA, or advanced outlier analysis) for detection of recovered ICs in accordance with aspects described herein. Such components or units can be embodied in computer-executable instructions, or programming code instructions, and executed by processor 2303. While recovery detection data 2307 is illustrated as part of mass storage device 2304, it should be appreciated that in other environments, recovery detection data 2307 can reside within system memory 2312 or a memory functionally coupled to a remote device (e.g., remote computing device 2314a). Data related to design and simulation of an IC, such as design of a true random number generator described herein, also can reside within mass storage device 2304 or system memory 2312.

The computer 2301 typically comprises a variety of computer readable media. Exemplary readable media can be any available media that is accessible by the computer 2301 and comprises, for example and not meant to be limiting, both volatile and non-volatile media, removable and non-removable media. The system memory 2312 comprises computer readable media in the form of volatile memory, such as random access memory (RAM), and/or non-volatile memory, such as read only memory (ROM). The system memory 2312 typically contains data and/or program modules such as operating system 2305 and IC recovery detection software 2306 (also referred to as recovery detection software 2306) that are accessible to and/or are presently operated on by the processing unit 2303. System memory 2312 also can include software for design and simulation of integrated; for instance, software for design on true random number generators can reside in system memory 2312. Operating system 2305 can comprise OSs such as Windows operating system, Unix, Linux, Symbian, Android, iOS, Chromium, and substantially any operating system for wireless computing devices or tethered computing devices.

In another aspect, the computer 2301 also can comprise other removable/non-removable, volatile/non-volatile computer storage media. By way of example, FIG. 23 illustrates a mass storage device 2304 which can provide non-volatile storage of computer code, computer readable instructions, data structures, program modules, and other data for the computer 2301. For example and not meant to be limiting, a mass storage device 2304 can be a hard disk, a removable magnetic disk, a removable optical disk, magnetic cassettes or other magnetic storage devices, flash memory cards, CD-ROM, digital versatile disks (DVD) or other optical storage, random access memories (RAM), read only memories (ROM), electrically erasable programmable read-only memory (EEPROM), and the like.

Optionally, any number of program modules can be stored on the mass storage device 2304, including by way of example, an operating system 2305, and recovery detection software 2306. Each of the operating system 2305 and recovery detection software 2306 (or some combination thereof) can comprise elements of the programming and the recovery detection software 2306. Data and code (e.g., computer-executable instruction(s)) can be retained as part of recovery detection software 2306 and can be stored on the mass storage device 2304. Recovery detection software 2306, and related data and code, can be stored in any of one or more databases known in the art. Examples of such databases comprise, DB2®, Microsoft® Access, Microsoft® SQL Server, Oracle®, mySQL, PostgreSQL, and the like. Other examples of databases include membase databases and flat file databases. The databases can be centralized or distributed across multiple systems.

In another aspect, the user can enter commands and information into the computer 2301 via an input device (not shown). Examples of such input devices comprise, but are not limited to, a camera; a keyboard; a pointing device (e.g., a “mouse”); a microphone; a joystick; a scanner (e.g., barcode scanner); a reader device such as a radiofrequency identification (RFID) readers or magnetic stripe readers; gesture-based input devices such as tactile input devices (e.g., touch screens, gloves and other body coverings or wearable devices), speech recognition devices, or natural interfaces; and the like. These and other input devices can be connected to the processing unit 2303 via a human machine interface 2302 that is coupled to the system bus 2313, but can be connected by other interface and bus structures, such as a parallel port, game port, an IEEE 1394 Port (also known as a Firewire port), a serial port, or a universal serial bus (USB).

In yet another aspect, a display device 2311 also can be connected to the system bus 2313 via an interface, such as a display adapter 2309. It is contemplated that the computer 2301 can have more than one display adapter 2309 and the computer 2301 can have more than one display device 2311. For example, a display device can be a monitor, an LCD (Liquid Crystal Display), or a projector. In addition to the display device 2311, other output peripheral devices can comprise components such as speakers (not shown) and a printer (not shown) which can be connected to the computer 2301 via Input/Output Interface 2310. Any step and/or result of the methods can be output in any form to an output device. Such output can be any form of visual representation, including, but not limited to, textual, graphical, animation, audio, tactile, and the like.

The computer 2301 can operate in a networked environment using logical connections to one or more remote computing devices 2314a,b,c. By way of example, a remote computing device can be a personal computer, portable computer, a mobile telephone, a server, a router, a network computer, a peer device or other common network node, and so on. Logical connections between the computer 2301 and a remote computing device 2314a,b,c can be made via a local area network (LAN) and a general wide area network (WAN). Such network connections can be through a network adapter 2308. A network adapter 2308 can be implemented in both wired and wireless environments. Such networking environments are conventional and commonplace in offices, enterprise-wide computer networks, intranets, and the Internet 2315. Networking environments generally can be embodied in wireline networks or wireless networks (e.g., cellular networks, facility-based networks, etc.).

As an illustration, application programs and other executable program components such as the operating system 2305 are illustrated herein as discrete blocks, although it is recognized that such programs and components reside at various times in different storage components of the computing device 2301, and are executed by the data processor(s) of the computer. An implementation of recovery detection software 2306 can be stored on or transmitted across some form of computer readable media. Any of the disclosed methods can be performed by computer readable instructions embodied on computer readable media. Computer readable media can be any available media that can be accessed by a computer. By way of example and not meant to be limiting, computer-readable media can comprise “computer storage media,” or “computer-readable storage media,” and “communications media.” “Computer storage media” comprise volatile and non-volatile, removable and non-removable media implemented in any methods or technology for storage of information such as computer readable instructions, data structures, program modules, or other data. Exemplary computer storage media comprises, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computer.

As described herein, in one aspect, the disclosure relates to a DR sensor to detect recovered ICs. The aging difference between a Reference RO and a Stressed RO in the DR sensor can permit identification of a fully recovered IC. In another aspect, results of chipset simulation incorporating different process and temperature variations can illustrate and demonstrate the efficacy of the DR sensor for detection of recovered ICs. Experimental results in an exemplary device comprising the DR sensor also can demonstrate that the disclosed DR sensor can detect a recovered IC. The devices and methodology described herein can be applied to ICs that have been operated in the field for a predetermined periods, including short periods of time (e.g., one month).

In another aspect, as described herein, the disclosure related to a methodology for detection or identification of a recovered IC based at least on path-delay fingerprinting. A path-delay signature associated with a recovered ICs can be different from a path-delay signature associated with a non-used ICs due to component aging. With no additional hardware circuitry required, the disclosed methodology can be implemented without incurring area overhead and/or consuming excess power with respect to the power consumed to perform a conventional quality assurance test in an IC. Results from simulation of different benchmarks with different process and temperature variations can demonstrate that the disclosed methodology is effective to detect, or identify, a recovered IC.

Various exemplary features and aspects described herein can comprise, broadly, at least two sets of techniques. For example, (1) using the shift in the circuit parameters. As another example, (2) using embedded sensors having at least the following aspects: Detection Using the Shift in Circuit Parameters (No area overhead, No constraint posed to the circuit layout, Novel statistical analysis); and Detection Using Embedded Sensors (novel CDR sensor structure to identify recycled ICs from fresh ones; the proposed structure is very effective to detect used ICs with a very small area overhead; easy to adopt in the current design flow resistant to various attacks, such as modeling, removal and tampering).

In one aspect, the disclosure can comprise an (i) implementation of this technique on FPGAs, (ii) implementation on designs with various clock gating and power switching techniques impacting the workload, and (iii) further improvement of detection rates for chips used for very short periods of time.

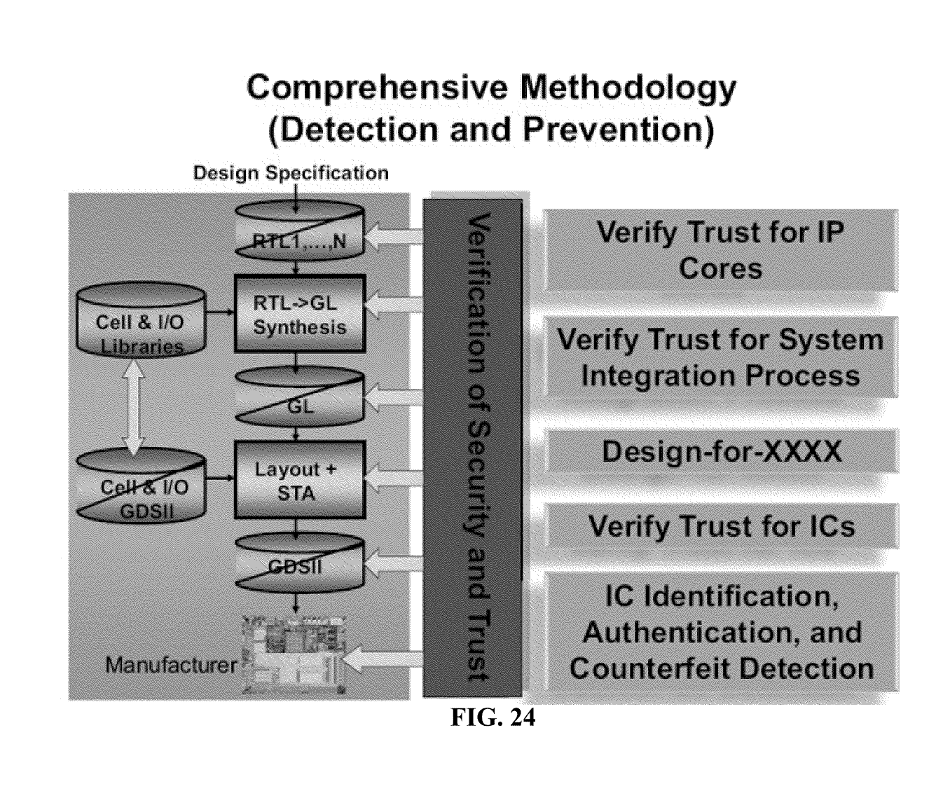

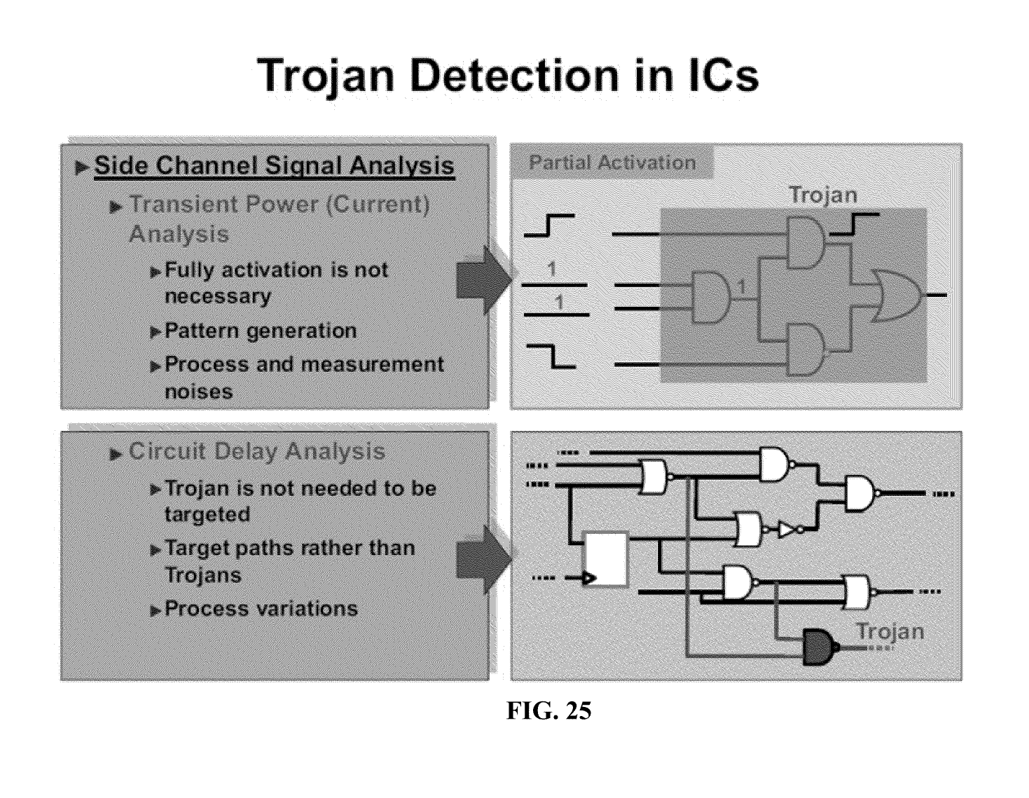

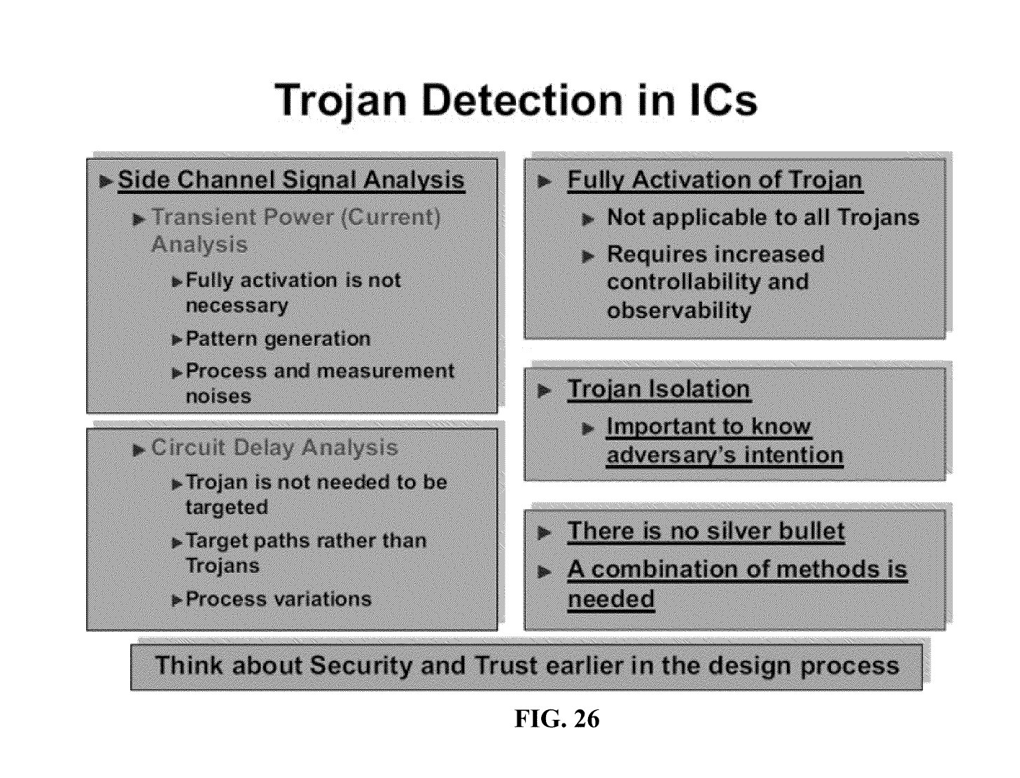

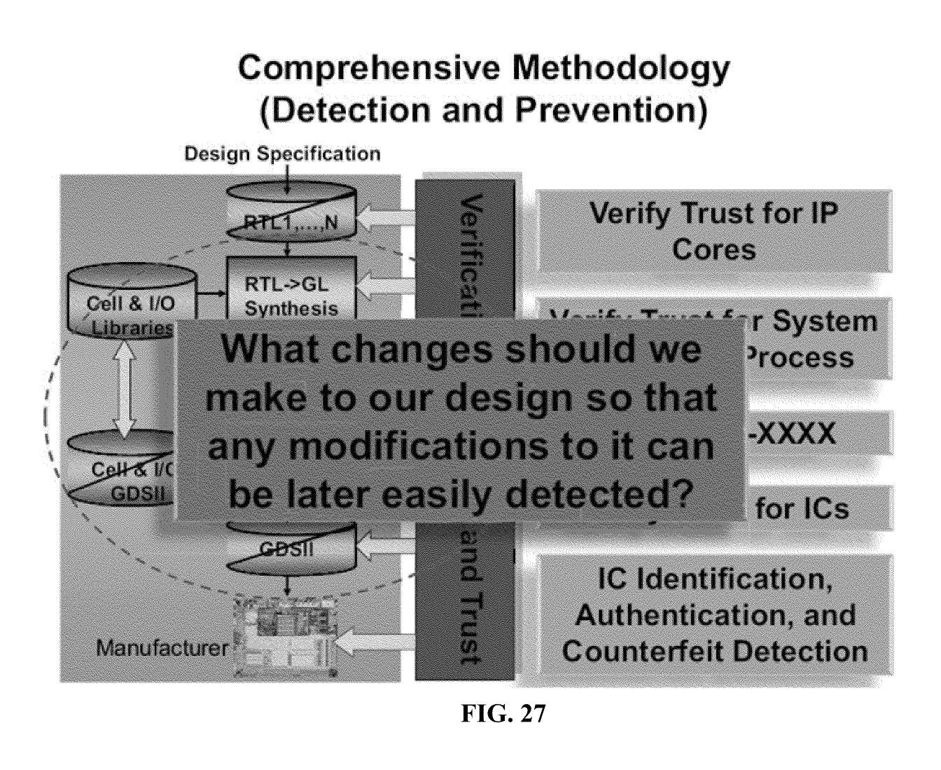

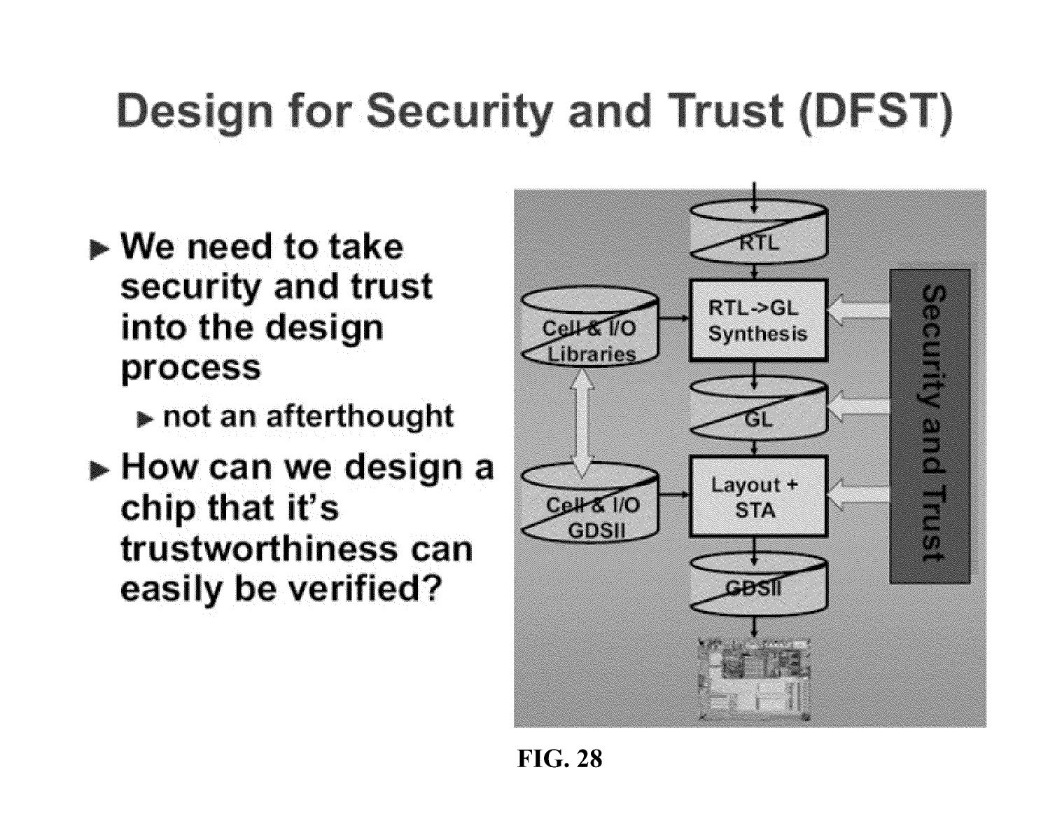

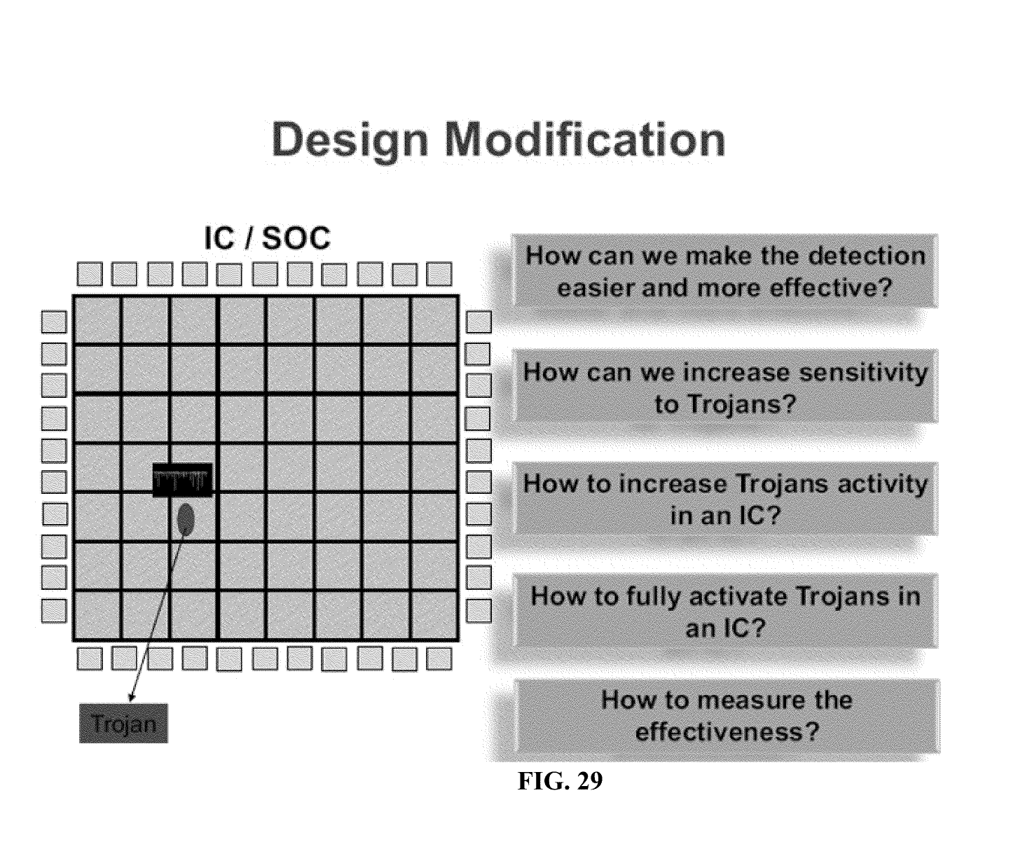

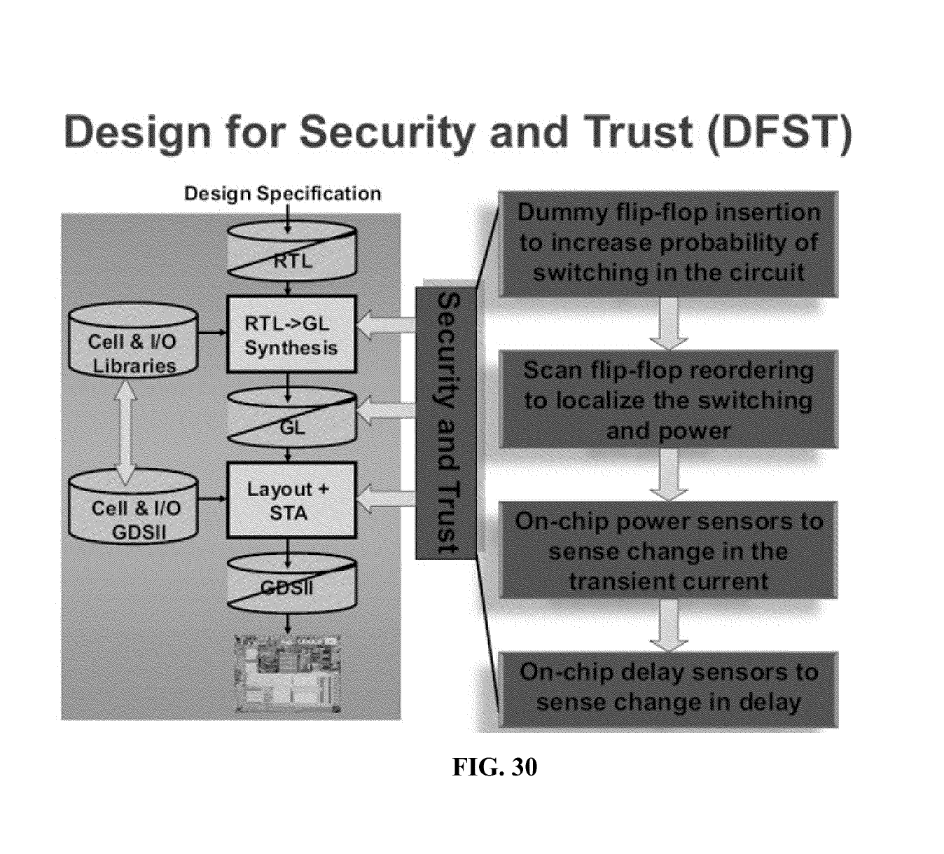

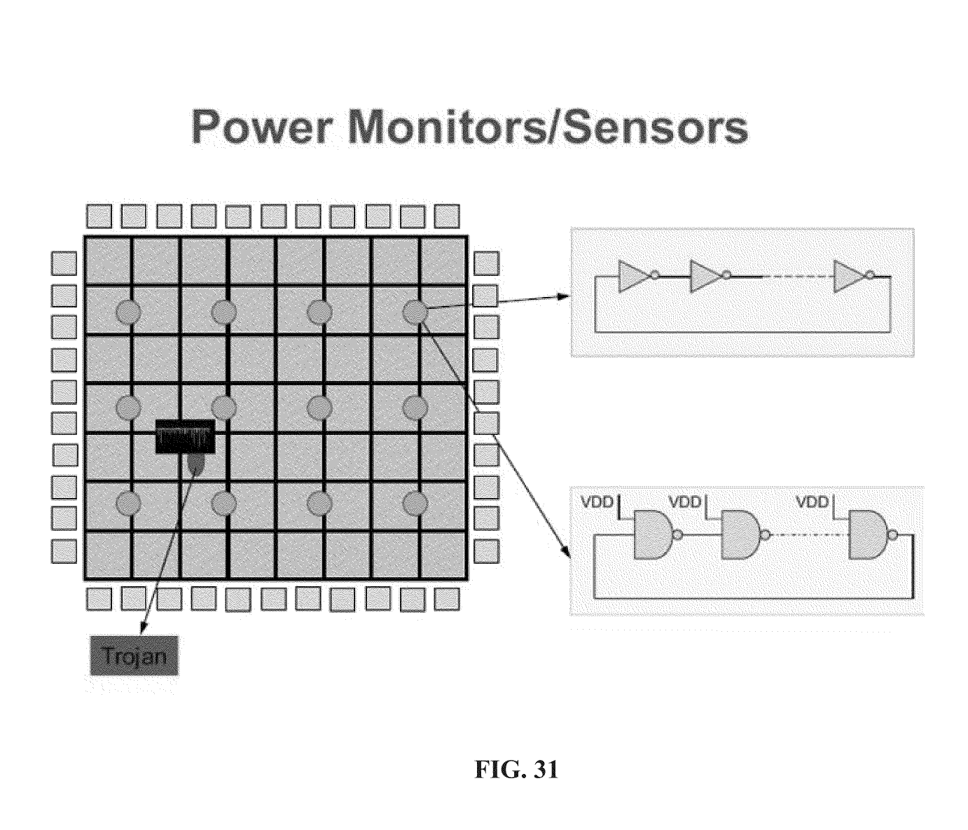

FIGS. 24-40 illustrate exemplary methodologies for detection of IC trojans in accordance with aspects described herein. Generally, trust can be verified at different stages including but not limited to IP cores, system integration processes, ICs, and the like. For example, dummy flip-flops can be inserted to increase probability of switching in the circuit. Flip-flop reordering can be scanned to localize switching and power. On chip power sensors can sense changes in the transient circuit. On-chip delay sensors can sense changes in delay. Various analysis techniques can be used such as simple outlier analysis, principle component analysis, advanced outlier analysis, circuit delay analysis, transient power analysis, and the like. Various components can be utilized such as ring oscillators, power monitors, and power sensors. These figures are described in more detail as follows. FIG. 24 illustrates exemplary methods for comprehensive Trojan detection and prevention. FIG. 25 illustrates exemplary Trojan detection methods using side channel analysis and circuit delay analysis. FIG. 26 illustrates exemplary Trojan detection methods using Trojan activation and Trojan isolation techniques. FIG. 27 illustrates exemplary challenges of IC Identification, IC authentication, and counterfeit IC detection. FIG. 28 illustrates exemplary design for security and trust (DFST) during IC design. FIG. 29 illustrates exemplary design modification methods for Trojan detection and prevention. FIG. 30 illustrates exemplary Trojan detection methods using dummy flip-flop, scan flip-flop reordering, on-chip power sensor, and on-chip delay sensor. FIG. 31 illustrates exemplary impact of a Trojan on a neighboring ring oscillator. For example, the following equation is also indicative of such impact:

$${t}_{d \_ gate} = \frac{{V}_{DD} {C}_{load}}{\frac{μ {C}_{ox}}{2} \cdot \frac{W}{L} {( {V}_{GS} - {V}_{TH} )}^{2} ( 1 + λ {V}_{DS} )}$$

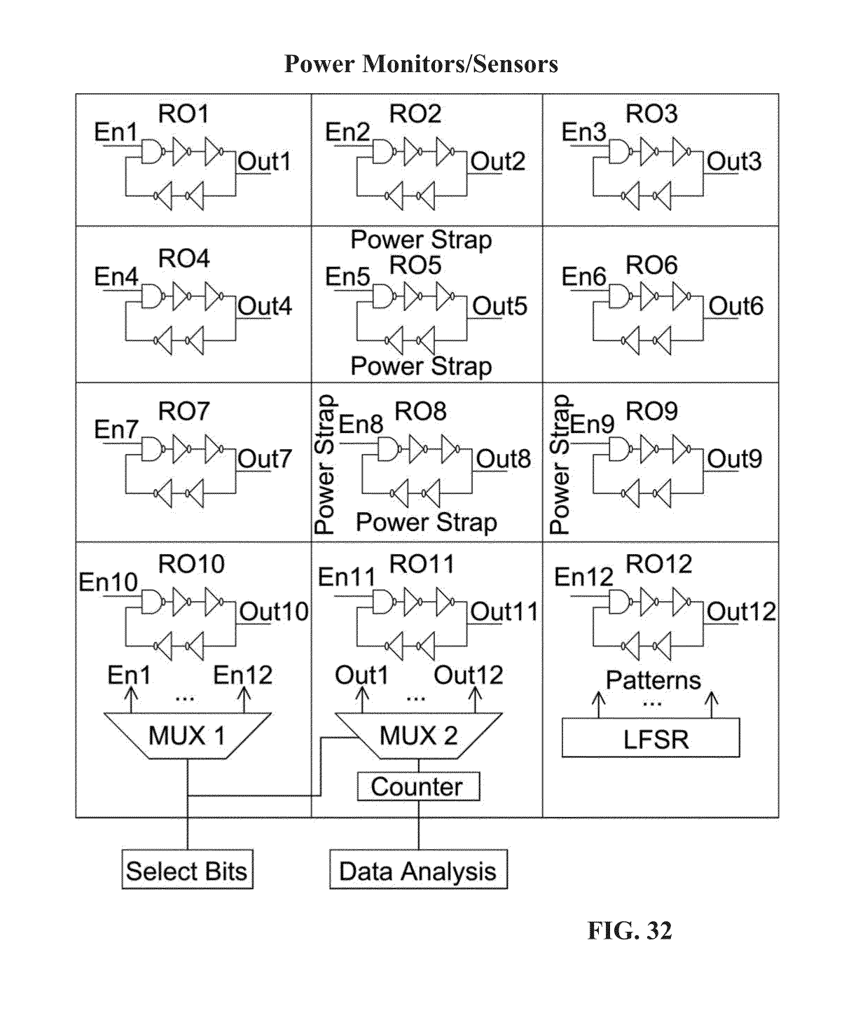

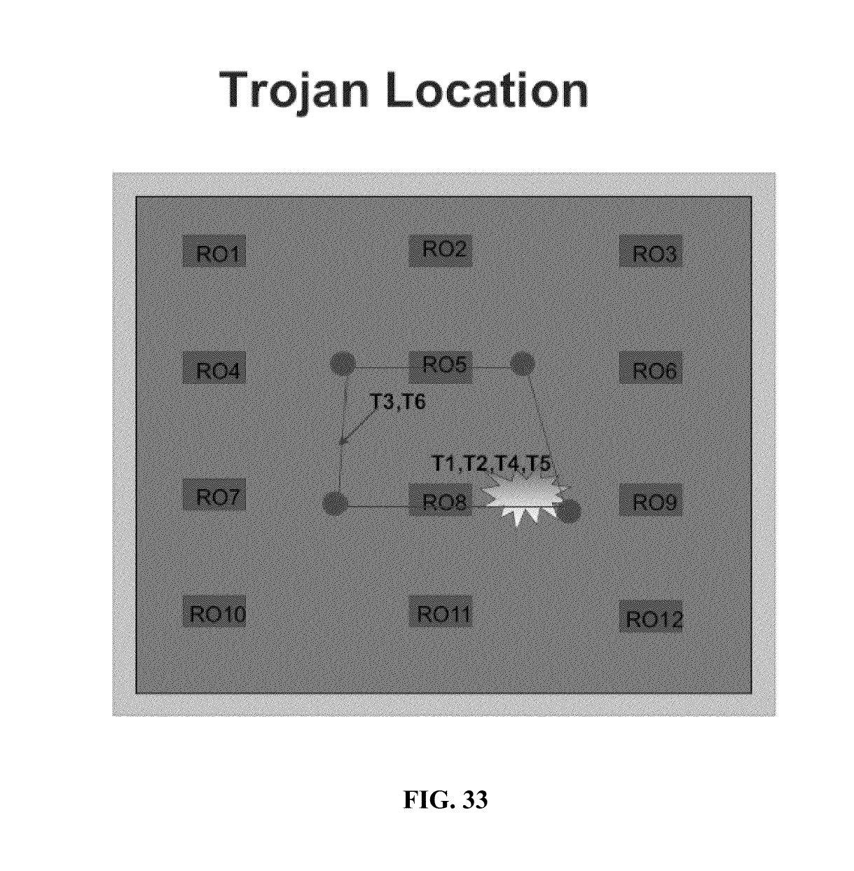

FIG. 32 illustrates exemplary structures of ring oscillator network as power monitors for Trojan detection. FIG. 33 illustrates exemplary locations of six Trojans inserted into s9234 in an exemplary simulation.

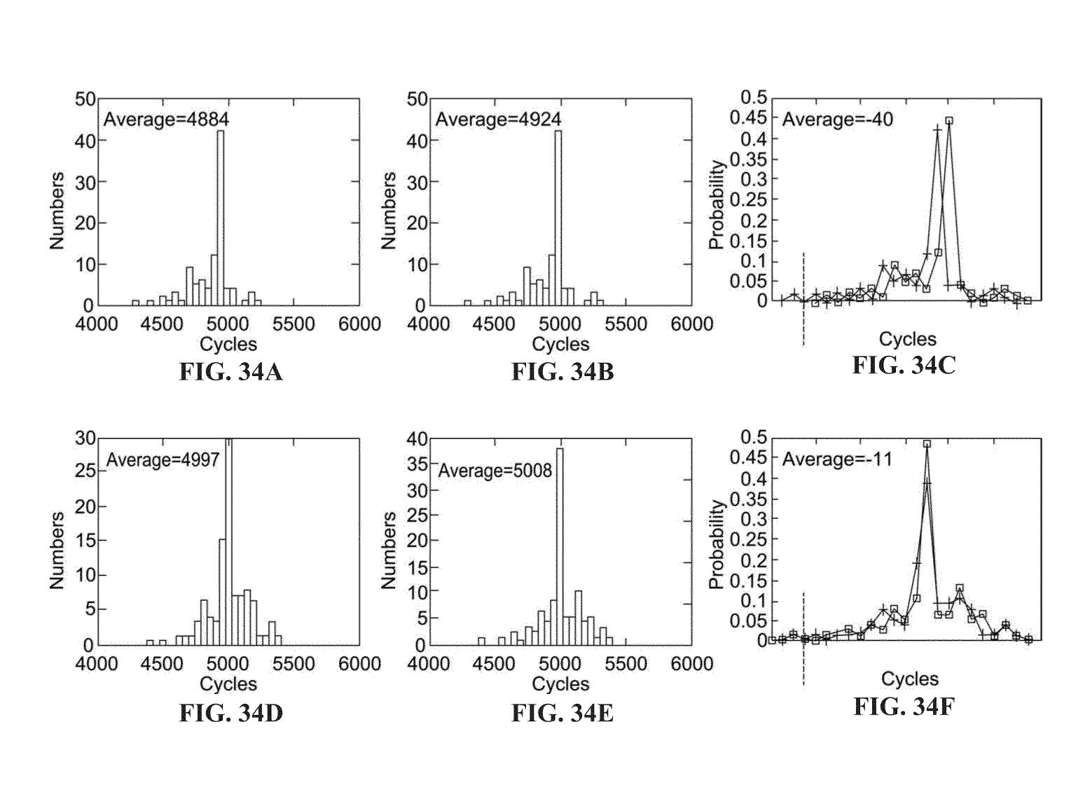

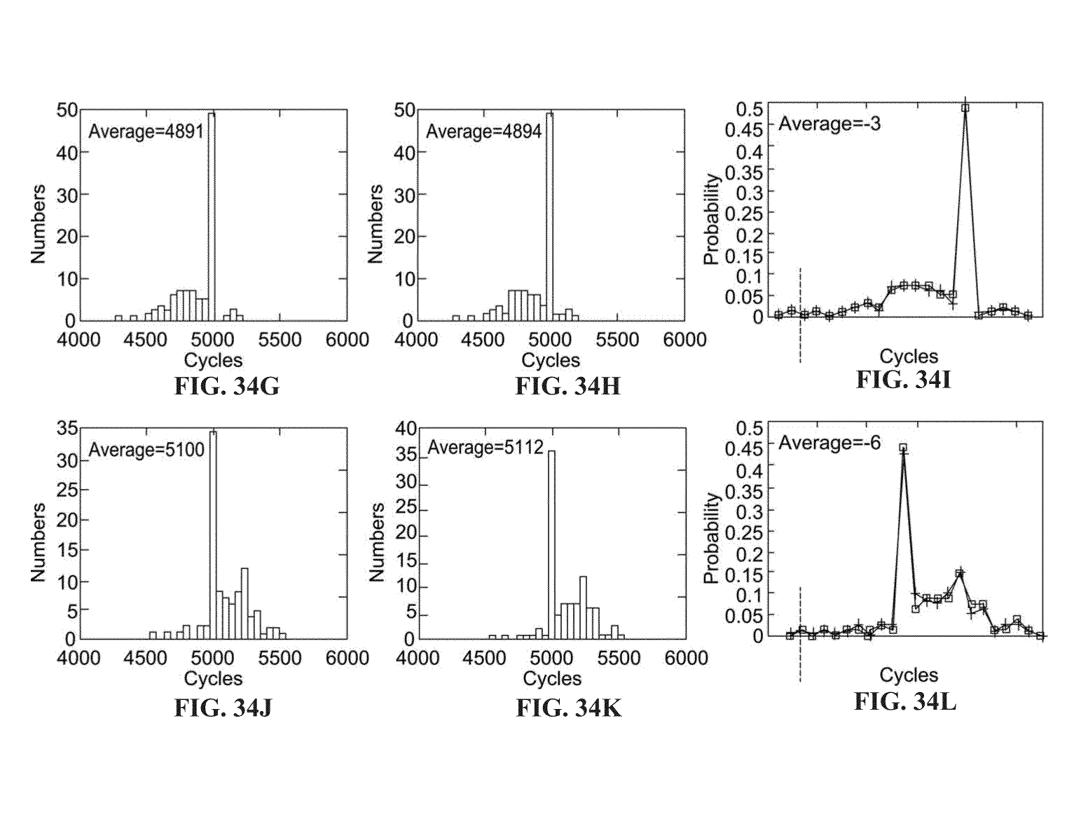

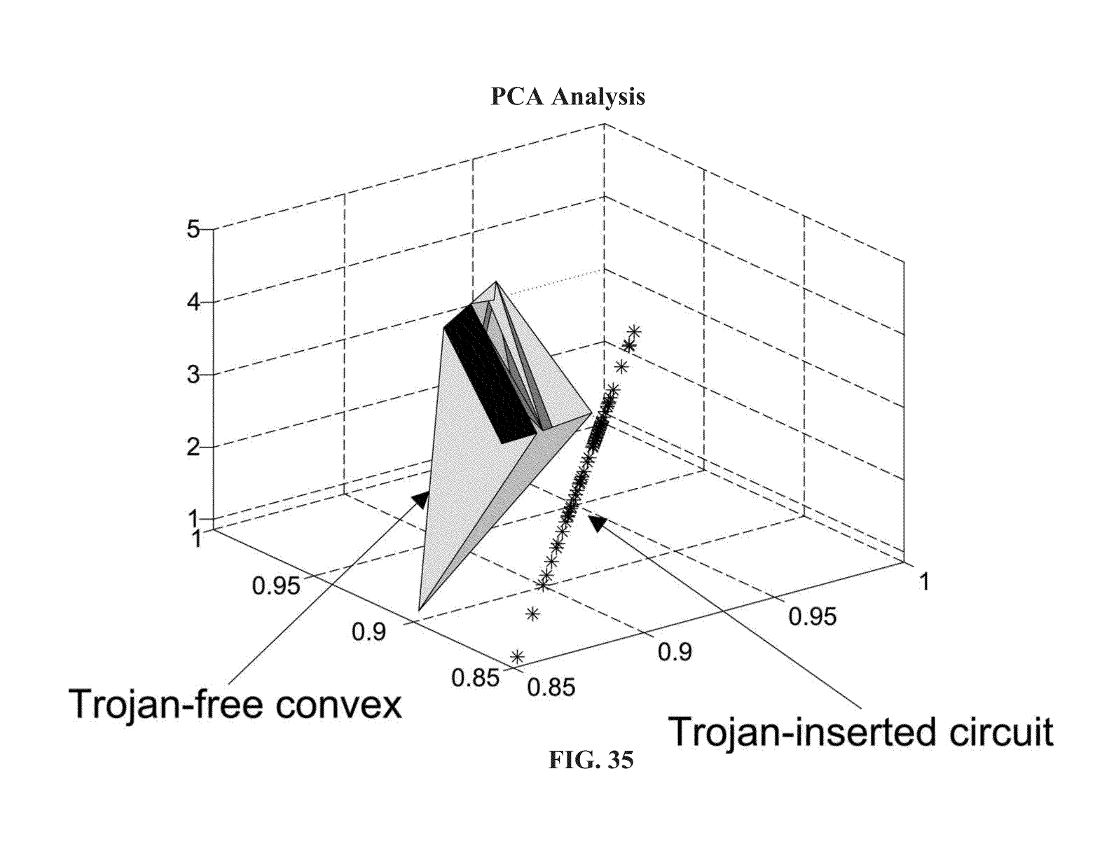

FIGS. 34A-34L illustrate an exemplary oscillation cycle distribution of ring oscillators with Monte Carlo simulation when Trojan T5 is inserted in s9234. FIG. 34A illustrates an exemplary oscillation cycle distribution of ring oscillator RO8 with Monte Carlo simulation when Trojan T5 is inserted in s9234. FIG. 34B illustrates an exemplary oscillation cycle distribution of ring oscillator RO8 with Monte Carlo simulation without Trojan T5. FIG. 34C illustrates an exemplary cycle count distribution of ring oscillator RO8 with Monte Carlo simulation when Trojan T5 is inserted in s9234. FIG. 34D illustrates an exemplary oscillation cycle distribution of ring oscillator RO5 with Monte Carlo simulation when Trojan T5 is inserted in s9234. FIG. 34E illustrates an exemplary oscillation cycle distribution of ring oscillator RO5 with Monte Carlo simulation without Trojan T5. FIG. 34F illustrates an exemplary cycle count distribution of ring oscillator RO5 with Monte Carlo simulation when Trojan T5 is inserted in s9234. FIG. 34G illustrates an exemplary oscillation cycle distribution of ring oscillator RO1 with Monte Carlo simulation when Trojan T5 is inserted in s9234. FIG. 34H illustrates an exemplary oscillation cycle distribution of ring oscillator RO1 with Monte Carlo simulation without Trojan T5. FIG. 34I illustrates an exemplary cycle count distribution of ring oscillator RO1 with Monte Carlo simulation when Trojan T5 is inserted in s9234. FIG. 34J illustrates an exemplary oscillation cycle distribution of ring oscillator RO12 with Monte Carlo simulation when Trojan T5 is inserted in s9234. FIG. 34K illustrates an exemplary oscillation cycle distribution of ring oscillator RO12 with Monte Carlo simulation without Trojan T5. FIG. 34L illustrates an exemplary cycle count distribution of ring oscillator RO12 with Monte Carlo simulation when Trojan T5 is inserted in s9234. FIG. 35 illustrates an exemplary power signature using principal component analysis for Trojan-free ICs and Trojan-inserted ICs with Trojan T5.

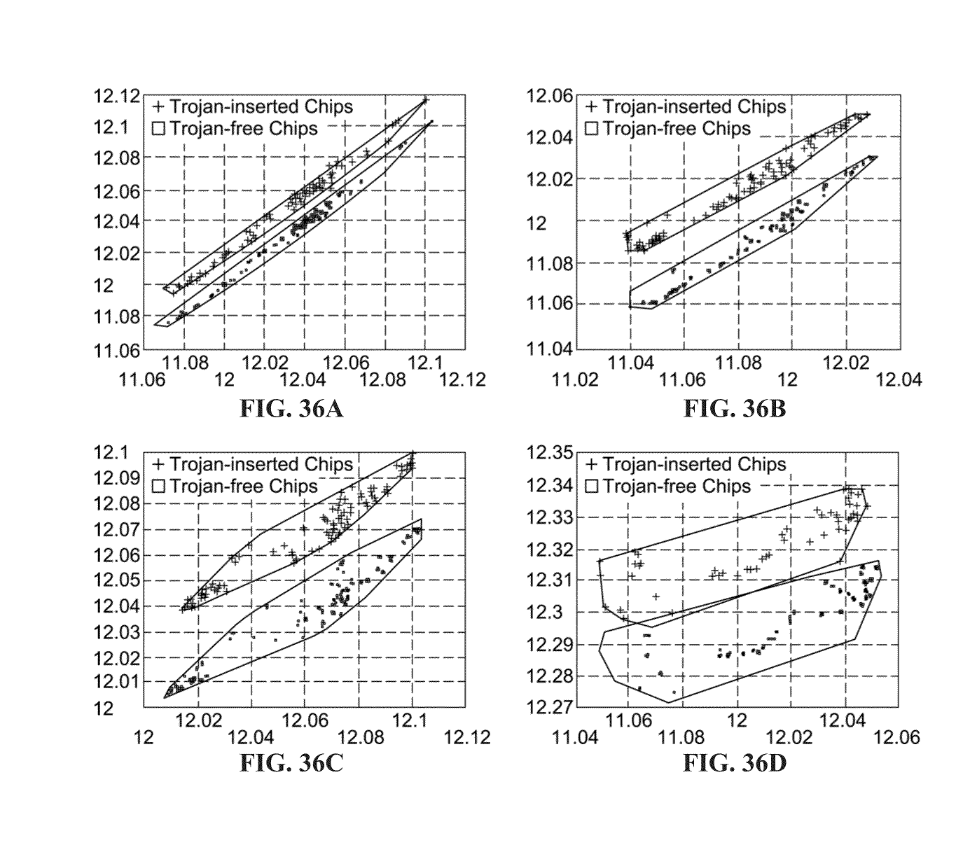

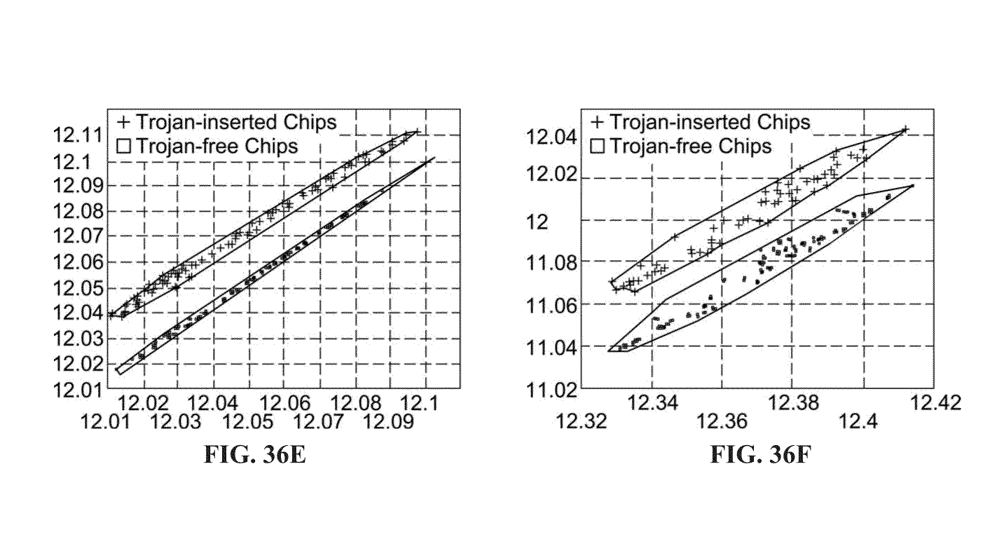

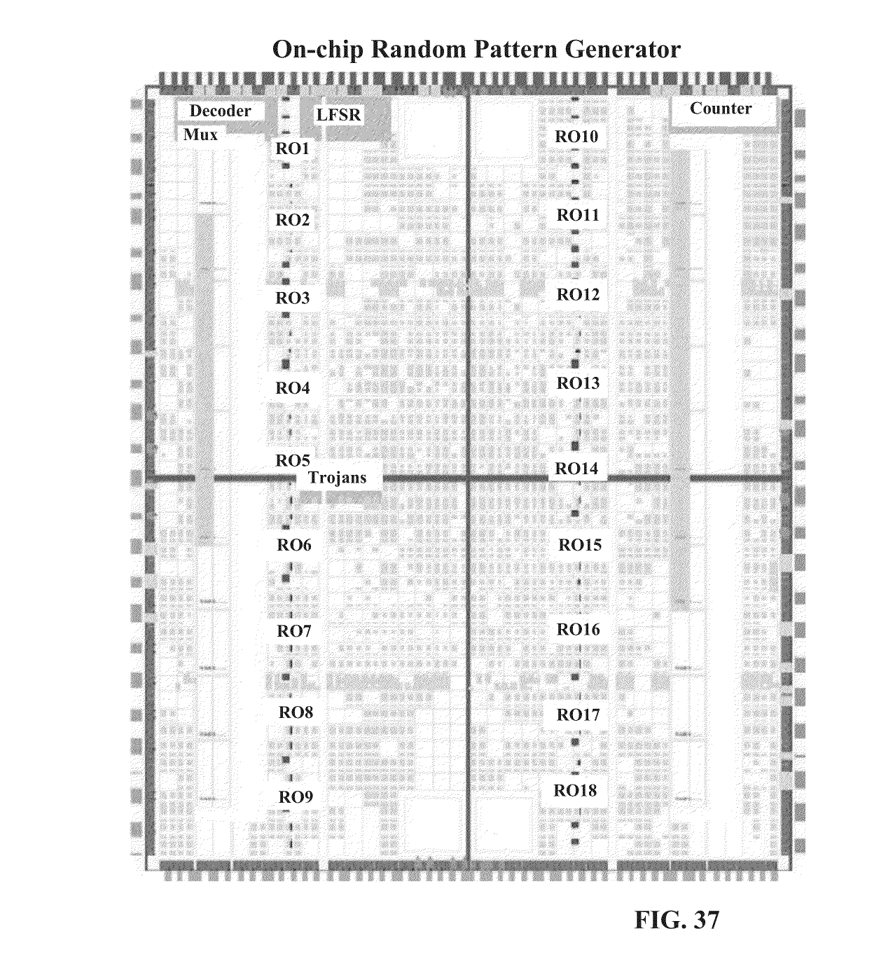

FIGS. 36A-36F illustrate exemplary power signatures with advanced outlier data analysis from IC simulation. In one aspect, such illustrations can be based on the formulas X=Sigma Cᵢs/Cᵣ₁ and Y=Sigma Cᵢs/Cᵣ₂. FIG. 36A illustrates an exemplary power signature with advanced outlier data analysis from IC simulation for T1. FIG. 36B illustrates an exemplary power signature with advanced outlier data analysis from IC simulation for T2. FIG. 36C illustrates an exemplary power signature with advanced outlier data analysis from IC simulation for T3. FIG. 36D illustrates an exemplary power signature with advanced outlier data analysis from IC simulation for T4. FIG. 36E illustrates an exemplary power signature with advanced outlier data analysis from IC simulation for T5. FIG. 36F illustrates an exemplary power signature with advanced outlier data analysis from IC simulation for T6. FIG. 37 illustrates an exemplary AES layout after the placement on FPGA.

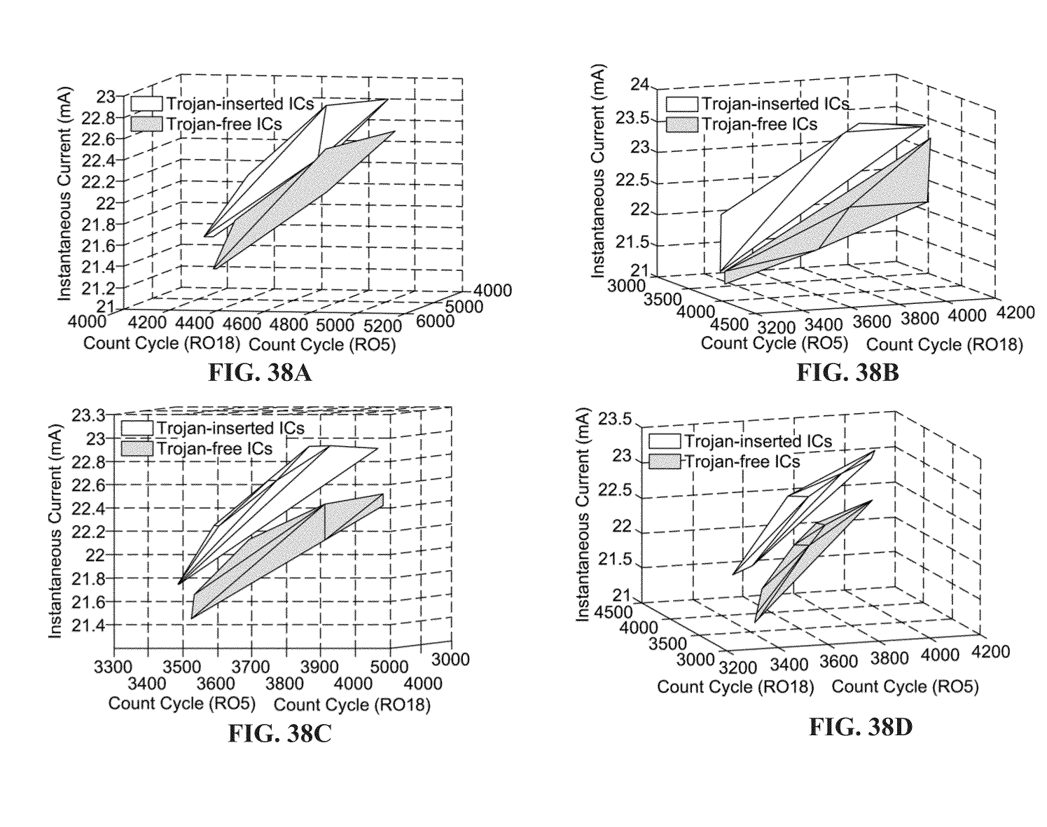

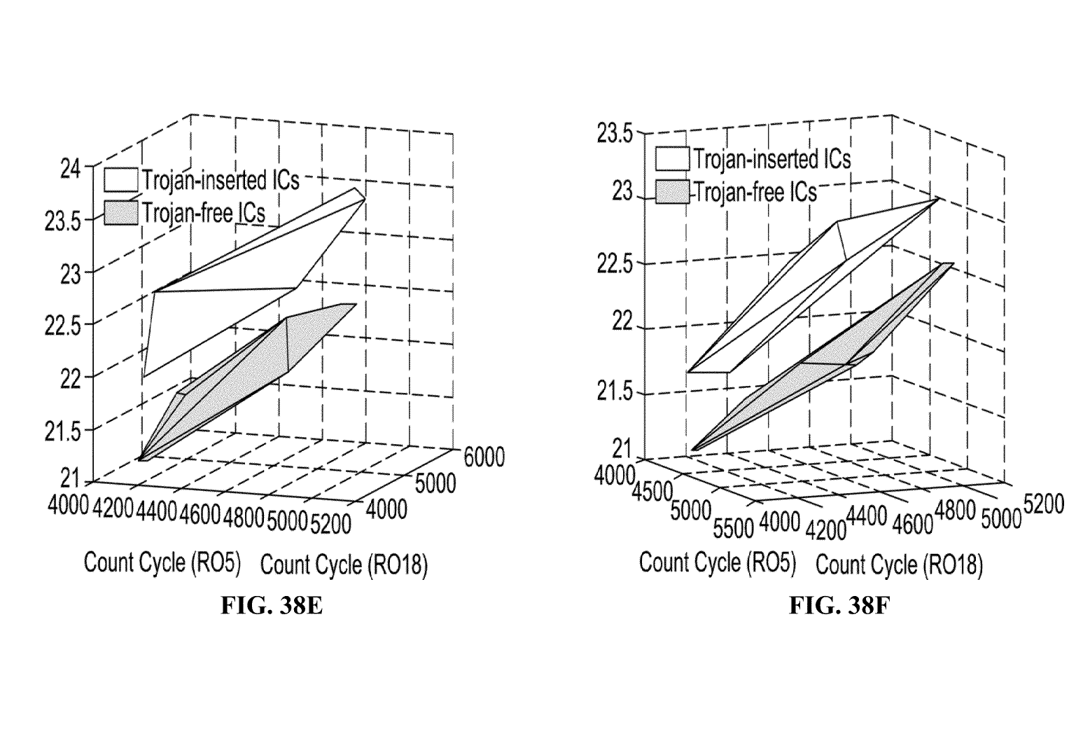

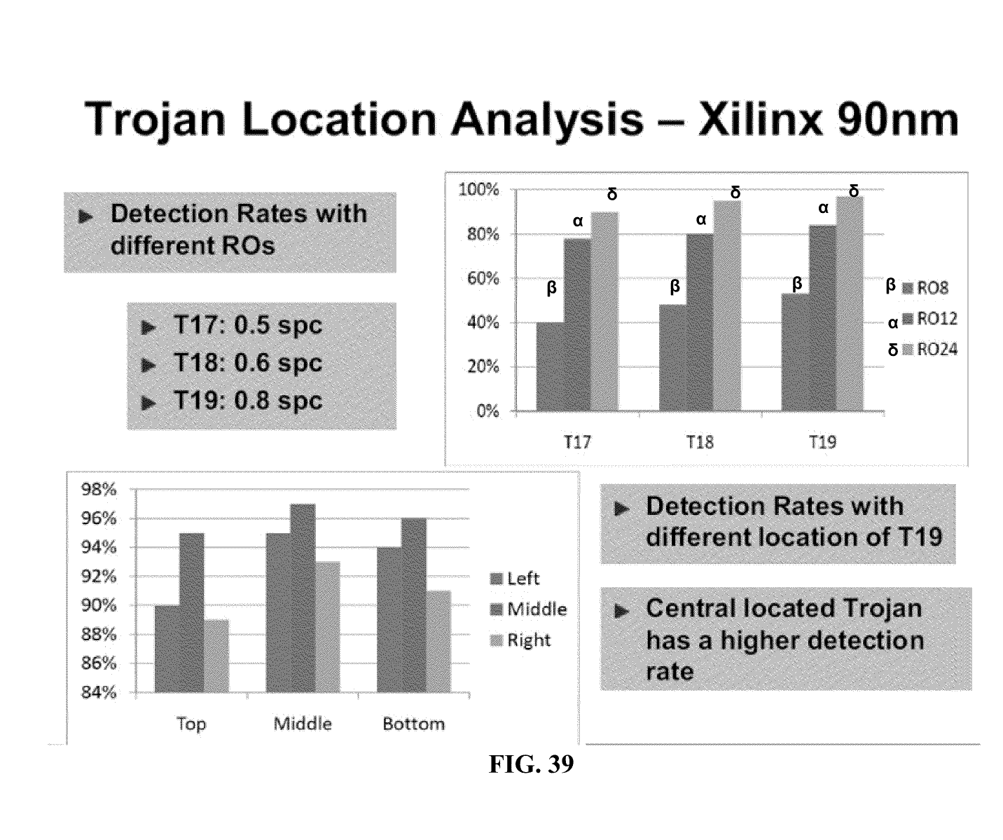

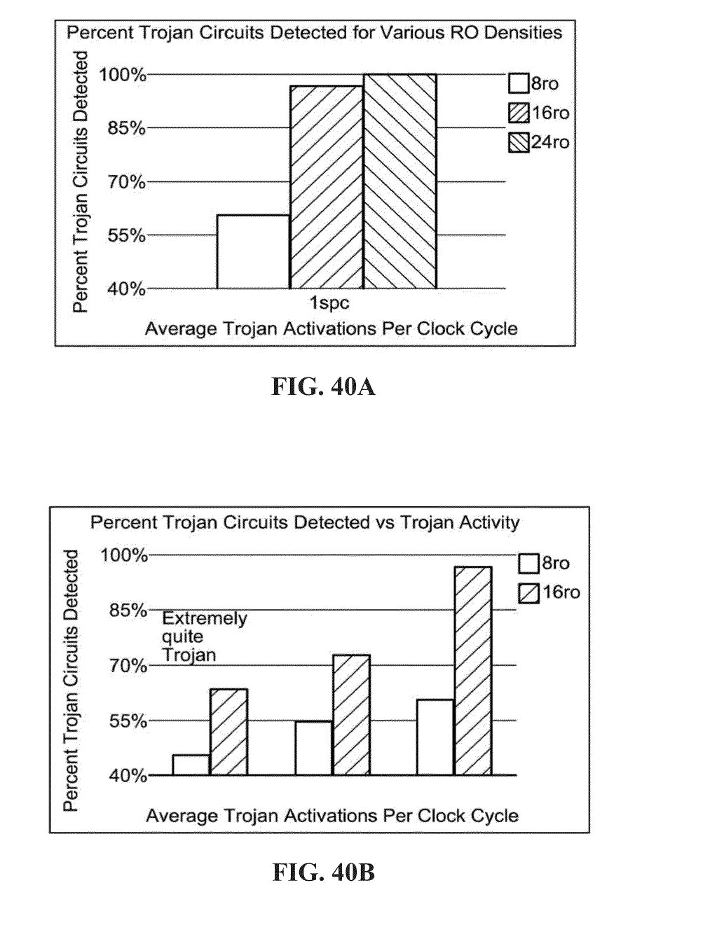

FIGS. 38A-38F illustrate exemplary power signatures with advanced outlier data analysis from FPGA implementation. The exemplary analysis was performed on 12 Trojan-free FPGAs and 12 Trojan-inserted FPGAs. Trojan detection coverage was as follows: 0.06% for T11, 0.15% for T12, 0.23% for T13, 0.33% for T14, 0.41% for T15, and 0.50% for T16. Also an assumption was made that golden ICs are available. FIG. 38A illustrates an exemplary power signature with advanced outlier data analysis from FPGA implementation for T11. FIG. 38B illustrates an exemplary power signature with advanced outlier data analysis from FPGA implementation for T12. FIG. 38C illustrates an exemplary power signature with advanced outlier data analysis from FPGA implementation for T13. FIG. 38D illustrates an exemplary power signature with advanced outlier data analysis from FPGA implementation for T14. FIG. 38E illustrates an exemplary power signature with advanced outlier data analysis from FPGA implementation for T15. FIG. 38F illustrates an exemplary power signature with advanced outlier data analysis from FPGA implementation for T16. FIG. 39 illustrates exemplary Trojan location analysis with advanced outlier data analysis from Xilinx 90 nm FPGA. FIG. 40A illustrates exemplary Trojan location analysis with advanced outlier data analysis from Xilinx 45 nm FPGA. For example, FIG. 40A shows the percentage of Trojans detected for various RO densities. This data can be used for analyzing the impact of increasing the number of ROs in the circuit. FIG. 40B further illustrates exemplary Trojan location analysis with advanced outlier data analysis from Xilinx 45 nm FPGA. For example, FIG. 40B shows the percentage of Trojan circuits detected versus Trojan Activity. This data can be used of analyzing detection capability for different Trojans.

While the systems, devices, apparatuses, protocols, processes, and methods have been described in connection with exemplary embodiments and specific illustrations, it is not intended that the scope be limited to the particular embodiments set forth, as the embodiments herein are intended in all respects to be illustrative rather than restrictive.

Unless otherwise expressly stated, it is in no way intended that any protocol, procedure, process, or method set forth herein be construed as requiring that its acts or steps be performed in a specific order. Accordingly, in the subject specification, where description of a process or method does not actually recite an order to be followed by its acts or steps or it is not otherwise specifically recited in the claims or descriptions of the subject disclosure that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification or annexed drawings, or the like.

It will be apparent to those skilled in the art that various modifications and variations can be made in the subject disclosure without departing from the scope or spirit of the subject disclosure. Other embodiments of the subject disclosure will be apparent to those skilled in the art from consideration of the specification and practice of the subject disclosure as disclosed herein. It is intended that the specification and examples be considered as non-limiting illustrations only, with a true scope and spirit of the subject disclosure being indicated by the following claims.

What is claimed is:

1. An apparatus for detection of integrated circuit (IC) recovery, the apparatus comprising:
a first sensor embedded in an IC;
a second sensor embedded in the IC;
a selector unit configured to select one of the first sensor or the second sensor; and
a monitor unit configured to receive output signal from the first sensor and the second sensor and to supply the output signal to an analysis unit.

2. The apparatus of claim 1, wherein the analysis unit is configured to receive the output signal and, based at least in part on the output signal, determine that the IC is a recovered IC.

3. The apparatus of claim 1, wherein the first sensor comprises a ring oscillator (RO).

4. The apparatus of claim 1, wherein the second sensor comprises a ring oscillator (RO).

5. The apparatus of claim 1, wherein the first sensor comprises a reference ring oscillator and the second sensor comprises a stressed ring oscillator.

6. The apparatus of claim 1, wherein the first sensor comprises a buffer chain.

7. The apparatus of claim 1, wherein the second sensor comprises a buffer chain.

8. The apparatus of claim 1, wherein the first sensor comprises a first buffer chain and the second sensor is a second buffer chain.

9. The apparatus of claim 1, wherein the first sensor comprises a flip-flop chain.

10. The apparatus of claim 1, wherein the second sensor comprises a flip-flop chain.

11. The apparatus of claim 1, wherein the first sensor comprises a first flip-flop chain and the second sensor comprises a second flip-flop chain.

12. The apparatus of claim 1, wherein the first sensor comprises an aging sensor.

13. The apparatus of claim 1, wherein the second sensor comprises an aging sensor.

14. The apparatus of claim 1, wherein the first sensor comprises a first aging sensor and the second sensor comprises a second aging sensor.

15. The apparatus of claim 1, wherein the selector unit comprises a multiplexer.

16. The apparatus of claim 1, wherein the monitor unit comprises a counter.

17. The apparatus of claim 1, wherein the monitor unit comprises a digital-to-digital converter.
